(19) United States
(12) Patent Application Publication
(10) Pub. No.: US 2004/0104395 A1
(43) Pub. Date: Jun. 3, 2004

(54) Light-emitting device, method of fabricating the same, and OHMIC electrode structure for semiconductor device

(75) Inventors: Kazunori Hagimoto, Annaka-shi (JP); Nobuhiko Noto, Annaka-shi (JP)

Correspondence Address: Ronald R. Snider, P.O. Box 27613, Washington, DC, 20038-7613, US

(73) Assignee: Shin-Etsu Handotai Co., Ltd., Tokyo (JP)

(21) Appl. No.: 10/718,789

(22) Filed: Nov. 24, 2003

(30) Foreign Application Priority Data
Nov. 28, 2002 (JP) 2002-345645
Dec. 25, 2002 (JP) 2002-375211
Jan. 31, 2003 (JP) 2003-023379
Jan. 31, 2003 (JP) 2003-023432
Jan. 31, 2003 (JP) 2003-025147
Jan. 31, 2003 (JP) 2003-025094
Aug. 29, 2003 (JP) 2003-307049

(51) Int. Cl. H01L 27/15; H01L 31/12

(52) U.S. Cl. 257/79

(57) ABSTRACT

A light-emitting device which uses a reflective metal layer, and thereby has a large light extraction efficiency and a small wavelength dependence is disclosed. The device uses one main surface of a light-emitting layer portion as a light extraction surface, and has a device substrate bonded on other main surface of the light-emitting layer portion. The device also has an Ag-base metal layer disposed between the device substrate and the light-emitting layer portion, wherein the Ag-base reflective metal layer has Ag as a major component over the entire portion thereof, and is intended for reflecting the light from the light-emitting layer portion back towards the light extraction surface side.

### RELATED APPLICATIONS

This application claims the priorities of Japanese Patent Applications No. 2002-345645 filed on Nov. 28, 2002, No. 2002-375211 filed on Dec. 25, 2002, No. 2003-023379 filed on Jan. 31, 2003, No. 2003-023432 filed on Jan. 31, 2003, No. 2003-025147 filed on Jan. 31, 2003, No. 2003-025094 filed on Jan. 31, 2003 and No. 2003-307049 filed on Aug. 29, 2003.

### BACKGROUND OF THE INVENTION

1. Field of the Invention

This invention relates to a light-emitting device, a method of fabricating the same, and an ohmic electrode structure for semiconductor device.

2. Description of Related Art

(First Invention)

Materials and device structures adopted to light-emitting devices such as light-emitting diode and semiconductor laser have almost reached theoretical limits of the internal photo-electric conversion efficiency after years of progress. For the purpose of obtaining the device of still higher luminance, it is therefore essential to raise the light extraction efficiency from the device. For an exemplary case of a light-emitting device having a light-emitting layer portion composed of an AlGaInP alloy, a double heterostructure, in which a thin AlGaInP (or GaInP) active layer is sandwiched by an n-type AlGaInP cladding layer and a p-type AlGaInP cladding layer, both of which having a larger band gap energy than that of the active layer, is adopted to thereby attain a high-luminance device, of which emission wavelength ranging over green to red regions. This type of AlGaInP double heterostructure can be formed on a GaAs single-crystal substrate by epitaxially growing the individual layers comprising AlGaInP alloy, based on lattice matching property between AlGaInP alloy and GaAs. For the purpose of using this structure as a light-emitting device, the GaAs single-crystal substrate often remains unremoved in the device. This is, however, disadvantageous in obtaining a sufficient level of light extraction efficiency due to absorption of the emitted light by the GaAs substrate, because AlGaInP alloy composing the light-emitting layer portion has a band gap energy larger than that of the GaAs substrate. One method for solving this problem is proposed (in Japanese Laid-Open Patent Publication No. 7-66455, for example), in which a reflective layer, composed of a semiconductor multi-layered film, is interposed between the substrate and light-emitting layer portion. It is, however, not so expectable in principle to dramatically raise the light extraction efficiency, because the improvement relies upon difference in the refractive indices between the stacked semiconductor layers, and this allows only an incident light having a limited range of angle of incidence to be reflected.

Various patent publications, including Japanese Laid-Open Patent Publication No. 2001-339100, disclose a technique by which the GaAs substrate used for the layer growth is finally removed, and instead a reinforcing conductive substrate is bonded to the separation surface while placing an Au layer, which also serves as a reflective layer, in between. The Au layer is advantageous in having a large reflectivity and a small dependence of reflectivity on the angle of incidence.

Investigations by the present inventors, however, revealed that the Au layer used as the reflective layer was unsuccessful in attaining a sufficient level of reflective effect, depending on emission wavelength of the light-emitting layer portion, and could attain only a limited range of improvement in the light extraction efficiency against our expectations.

(Second Invention)

There is known a technique by which the GaAs substrate used for the layer growth is finally removed, and instead a reinforcing conductive substrate is bonded to the separation surface while placing an Au layer, which also serves as a reflective layer, in between. The Au layer is advantageous in having a large reflectivity and a small dependence of reflectivity on the angle of incidence. It is, however, revealed that the Au layer used as the reflective layer is unsuccessful in attaining a sufficient level of reflective effect, depending on emission wavelength of the light-emitting layer portion, and can attain only a limited range of improvement in the light extraction efficiency against expectations. This is because Au has a strong absorption in the visible light range of 670 nm or shorter, and so that the reflectivity will seriously be lowered when the light-emitting layer portion has a peak emission wavelength in 670 nm or shorter range. The total emission intensity will thus tend to lower, the emission spectrum will be somewhat different from that theoretically expected due to the absorption, and emission color tone will tend to vary. Another technique of using Ag for the reflective metal layer is proposed in Japanese Laid-Open Patent Publication No. 11-191641.

In the light-emitting device disclosed in Japanese Laid-Open Patent Publication No. 11-191641, the compound semiconductor layer, on which the Ag-base reflective metal layer is formed, including the light-emitting layer portion, is composed of a nitride-base Group III-V compound semiconductor. For the purpose of ensuring ohmic contact with the Ag-base reflective metal layer, it is therefore necessary to form, on the compound semiconductor layer, an ohmic-contact-forming, single-element metal layer which comprises any one of Ni, Co, Mg and Sb. A problem, however, resides in that all of these single-element metals of Ni, Co, Mg and Sb cannot always ensure a desirable reflectivity with respect to blue-to-green light.

(Third Invention)

Various patent publications, including Japanese Laid-Open Patent Publication No. 2001-339100, disclose a technique by which the GaAs substrate used for the layer growth is finally removed, and instead a reinforcing conductive substrate is bonded to the separation surface while placing an Au layer, which also serves as a reflective layer, in between. The Au layer is advantageous in having a large reflectivity and a small dependence of reflectivity on the angle of incidence.

This method was, however, likely to cause separation of the Au layer, which serves as the reflective layer, and the light-emitting layer portion during bonding of the both, and cause lowering in the reflectivity. This problem will become more pronounced when there is a larger tendency of a metallurgical reaction between the device substrate (especially Si substrate) and the Au layer during the annealing for bonding.

(Fourth Invention)

Various patent publications, including Japanese Laid-Open Patent Publication No. 2001-339100, disclose a technique by which the GaAs substrate used for the layer growth is finally removed, and instead a reinforcing conductive substrate is bonded to the separation surface while placing an Au layer, which also serves as a reflective layer, in between. The Au layer is advantageous in having a large reflectivity and a small dependence of reflectivity on the angle of incidence.

Our investigations, however, revealed that the Au layer used as the reflective layer is unsuccessful in attaining a sufficient level of reflective effect, depending on emission wavelength of the light-emitting layer portion, and can attain only a limited range of improvement in the light extraction efficiency against expectations.

(Fifth Invention)

Various patent publications, including Japanese Laid-Open Patent Publication No. 2001-339100, disclose a technique by which the GaAs substrate used for the layer growth is finally removed, and instead a reinforcing conductive substrate is bonded to the separation surface while placing an Au layer, which also serves as a reflective layer, in between. The Au layer is advantageous in having a large reflectivity and a small dependence of reflectivity on the angle of incidence.

It is however difficult, by the above-described method, to secure a desirable level of bonding strength between the Au layer, which serves as the reflective layer, and the light-emitting layer portion during the bonding, and this inevitably results in nonconformities such as the separation, or in lowering in the reflectivity ascribable to difficulty in achieving a desirable bonding status. An approach of elevating the annealing temperature during the bonding with the aim of raising the bonding strength may, however, make the metallurgical reaction of the light-emitting layer or conductive substrate (especially Si substrate) with the Au layer more likely to proceed. This may degrade conditions of the obtained reflective surface, and make it more likely to result in lowered reflectivity.

(Sixth Invention)

Various patent publications, including Japanese Laid-Open Patent Publication No. 2001-339100, disclose a technique by which the GaAs substrate used for the layer growth is finally removed, and instead a reinforcing conductive substrate is bonded to the separation surface while placing an Au layer, which also serves as a reflective layer, in between. The Au layer is advantageous in having a large reflectivity and a small dependence of reflectivity on the angle of incidence.

The above-described method is, however, disadvantageous in that it is likely to cause the separation or lowering in the reflectivity during the bonding of the Au layer, which serves as the reflective layer, and the light-emitting layer portion.

### SUMMARY OF THE INVENTION

A subject of the first invention is to provide a light-emitting device using a reflective metal layer, capable of ensuring a large light extraction efficiency, and a small wavelength dependence of the light extraction efficiency.

A subject of the second invention is to provide a light-emitting device capable of ensuring a desirable ohmic contact between AlGaInP or InGaAlN and an Ag-base reflective layer, and of further raising the light extraction efficiency with respect to blue-to-green light, and to provide an ohmic electrode structure for semiconductor devices, containing an electrode layer composed of an Ag-base metal, and capable of forming a desirable ohmic contact in various semiconductor devices including light-emitting devices at low cost.

A subject of the third invention is to provide a light-emitting device having a structure in which a light-emitting layer portion and a device substrate are bonded while placing a metal layer in between, and a method for fabricating the same, both of which being capable of effectively preventing a metallurgical reaction between the device substrate and the metal layer from proceeding during annealing for bonding, and of thus making it less causative of non-conformities such as lowering in the bonding strength and reflectivity due to the reaction.

A subject of the fourth invention is to provide a light-emitting device using a reflective metal layer and a method of fabricating the same, both of which being capable of ensuring a large light extraction efficiency and a small wavelength dependence of the light extraction efficiency.

A subject of the fifth invention is to provide a light-emitting device having a structure in which a light-emitting layer portion and a device substrate are bonded while placing a metal layer having an Au-base layer in between, and a method for fabricating the same, both of which being capable of ensuring a sufficient level of the bonding strength even under low annealing temperatures during the bonding, and of keeping desirable conditions of the obtained reflective surface.

A subject of the sixth invention is to provide a light-emitting device having a structure in which a light-emitting layer portion and a Si substrate are bonded while placing a metal layer in between, and a method of fabricating the same, both of which being less causative of lowering in the bonding strength and reflectivity.

(First Invention)

To solve the aforementioned subject, a light-emitting device of the first invention is such as comprising:

a compound semiconductor layer having a light-emitting layer portion, being configured so that one main surface of which serves as a light extraction surface;

a device substrate bonded on the other main surface side of the compound semiconductor layer;

and an Ag-base metal layer interposed between the device substrate and the compound semiconductor layer, including an Ag-base reflective metal layer having Ag as a major component over the entire portion thereof, and being intended for reflecting the light from the light-emitting layer portion back towards the light extraction surface side It is to be noted that the “major component” in the context of this patent specification means a component having a largest ratio of content by mass.

The Ag-base reflective metal layer is far less expensive as compared with a reflective metal layer composed of an Au-base metal, and has only a small wavelength dependence of the reflectivity, showing a desirable reflectivity over the almost entire wavelength range of the visible light (350 nm to 700 nm). This makes it possible to achieve a large light extraction efficiency irrespective of emission wavelength of the device. It is also advantageous that the Ag-base metal is less likely to cause lowering in the reflectivity due to oxide film formation when compared with a metal such as Al. Because the entire portion of the metal layer is composed of the Ag-base metal, it is no more necessary in the first invention to interpose an expensive noble metal such as Au, and thereby the device as a whole is producible at low costs.

FIG. 4 shows reflectivity of mirror-polished surfaces of various metals, where plot “▪” represents reflectivity of Ag, plot “Δ” of Au, plot “♦” of Al (comparative example), and plot “x” of AgPdCu alloy. Reflectivity of Ag with respect to the visible light is especially large in a wavelength range from 350 nm to 700 nm (and longer wavelength in the infrared region), and particularly in 380 nm to 700 nm.

On the other hand, Au is a colored metal, and as is obvious from the reflectivity shown in FIG. 4, shows a strong absorption in the visible light region of 670 nm or shorter (particularly strong in 650 nm or shorter region, and still more stronger in 600 nm or shorter region), and so that the reflectivity will seriously be lowered when the light-emitting layer portion has a peak emission wavelength in 670 nm or shorter range. The emission intensity will thus tend to lower, the emission spectrum will be somewhat different from that theoretically expected due to the absorption, and emission color tone will tend to vary. In contrast to this, Ag adopted in the first invention shows an excellent reflectivity also in the visible light region of 670 nm or shorter. In other words, adoption of the first invention can realize a light extraction efficiency far larger than that expected from Au, when the light-emitting layer portion has a peak emission wavelength in 670 nm or shorter range (particularly in 650 nm or shorter, and more particularly 600 nm or shorter).

Although Al shows no absorption peak in FIG. 4, the reflectivity thereof in the visible light region is suppressed to a slightly lower level (e.g., 85 to 92%) due to formation of oxide film. On the contrary, Ag adopted in the first invention is less likely to produce the oxide film, and is therefore more successful in achieving a reflectivity higher than that of Al in the visible light region. More specifically, Ag shows a larger reflectivity than Al shows in a wavelength region of 400 nm or longer (particularly 450 nm or longer).

It is to be noted that the reflectivity of Al shown in FIG. 4 is measured for the Al surface which is mirror-finished by mechanical polishing and chemical polishing to thereby suppress formation of the surface oxide film, and actual measurement may give values still lower than those shown in FIG. 4 due to formation of a thick oxide film. For example, Ag is expressed in FIG. 4 as having a reflectivity smaller than that of Al in a short wavelength region from 350 nm to 400 nm, but is far less likely to produce the oxide film as compared with Al. Actual formation of the Ag-base reflective metal layer as the reflective metal layer on the light-emitting layer portion is thus successful in achieving the reflectivity superior to that of Al also in this wavelength region. Also in this wavelength region, Ag has a larger reflectivity than Au has.

In conclusion, it can be said that the Ag-base reflective metal layer can ensure an especially remarkable improving effect of the light extraction efficiency as compared with Al and Au, when the light-emitting layer portion has a peak emission wavelength within a range from 350 nm to 670 nm (more preferably 400 nm to 670 nm, and still more preferably 450 nm to 600 nm), both ends inclusive. The light-emitting layer portion having the above-described peak emission wavelength can be configured as having a double heterostructure in which a first-conductivity-type cladding layer, an active layer and a second-conductivity-type cladding layer, all of these layers being composed of (AlₓGa₁₋ₓ)_{y}In_{1-y}P (where, 0≦x≦1 and 0≦y≦1) or InₓGa_{y}Al_{1-x-y}N (where, 0≦x≦1, 0≦y≦1 and x+y≦1), are stacked in this order.

In the light-emitting device of the first invention, it is allowable to dispose a light-emitting-layer-portion-side, Ag-base contact layer having Ag as a major component, so as to be arranged in a discrete manner on the main surface of the Ag-base reflective metal layer, between the Ag-base reflective metal layer and the compound semiconductor layer. The Ag-base reflective metal layer composes a part of current supply route towards to the light-emitting layer portion. Direct bonding of the Ag-base reflective metal layer to the light-emitting layer portion composed of a compound semiconductor may, however, undesirably lower the emission efficiency due to increased series resistance based on the contact resistance. For the case where the Ag-base reflective metal layer is used, a contact layer used on the light-emitting-layer-portion side may be composed of an Ag-base material, rather than the conventional Au-base material. Bonding of the Ag-base reflective metal layer to the light-emitting layer portion while placing the Ag-base contact layer in between is successful in reducing the contact resistance, and moreover in reducing costs for formation of the contact layer as compared with the case where the Au-base contact layer is used. It is, however, necessary for the Ag-base contact layer to be added with a relatively large amount of alloying components required for ensuring a desirable contact, and this slightly lowers the reflectivity. One solution for this problem is to form the light-emitting-layer-side, Ag-base contact layer in a discrete manner on the main surface of the Ag-base reflective metal layer, and this is successful in ensuring a large reflectivity ascribable to the Ag-base reflective metal layer, in the non-forming region of the light-emitting-layer-portion-side, Ag-base contact layer. The light-emitting-layer-portion-side, Ag-base contact layer can specifically be composed of an AgGeNi contact layer, and an especially large reducing effect on the contact resistance can be attained when the compound semiconductor layer is composed of an n-type Group III-V compound semiconductor (aforementioned (AlₓGa₁₋ₓ)_{y}In_{1-y}P (where, 0≦x≦1 and 0≦y≦1) or InₓGa_{y}Al_{1-x-y}N (where, 0≦x≦1, 0≦y≦1 and x+y≦1)). A preferable composition of the AgGeNi contact layer can be expressed as Ge of 1% to 20% by mass, Ni of 1% to 20% by mass, and Ag accounts for the residual portion. The composition within the above ranges can ensure a sufficient effect of reducing the contact resistance.

For the purpose of fully enhancing the light extraction efficiency, the ratio of formation area of the light-emitting-layer-portion-side, Ag-base contact layer to the Ag-base reflective metal layer (i.e., a value obtained by dividing the formation area of the light-emitting-layer-portion-side, Ag-base contact layer by the total area of the Ag-base reflective metal layer) preferably falls within a range from 1% to 25%, both ends inclusive. The ratio of formation area of the light-emitting-layer-portion-side, Ag-base contact layer less than 1% will fail in obtaining a sufficient suppressive effect on the contact resistance, and exceeding 25% will result in a lowered reflection intensity.

The Ag-base reflective metal layer is successful in further raising the reflectivity thereof in the non-formation region of the light-emitting-layer-portion-side, Ag-base contact layer, if the ratio of Ag content of the Ag-base reflective metal layer is set higher than that of the light-emitting-layer-portion-side, Ag-base contact layer. This also makes it possible to carry out the bonding of a first Ag-base metal layer and a second Ag-base metal layer at lower temperatures in the fabrication method of the first invention described later, to simplify the fabrication process, and to reduce the cost. More specifically, by adjusting the ratio of Ag content to 95% by mass or above for both of the first Ag-base metal layer and the second Ag-base metal layer, together composing the Ag-base reflective metal layer, it is made possible to lower the lower limit of the adjustable range of diffusion annealing temperature, whereat the first Ag-base metal layer and the second Ag-base metal are bonded, to as low as 100° C. or around. In this case, the diffusion annealing temperature is set at an appropriate level at 100° C. or above. The aforementioned effect will more be enhanced if the Ag-base reflective metal layer (more specifically, the first Ag-base metal layer and the second Ag-base metal layer) is composed of pure Ag (where, inevitable contamination to as much as 1% by mass permissible). On the other hand, it is also allowable to compose the Ag-base reflective metal layer using a Pd-containing Ag alloy. The Pd-containing Ag alloy is excellent in sulfurization resistance and oxidation resistance, and is therefore effective in preventing degradation of the reflectivity induced by sulfurization or oxidation.

The device substrate configured as a conductive substrate allows it to serve as a part of conduction path for driving the light-emitting device, and this simplifies the device structure. Available examples of the conductive substrate not only include metal layer composed of Al, Cu or alloys thereof, but also include conductive semiconductor substrate. It is particularly advantageous to use an inexpensive Si substrate (polysilicon substrate or single-crystal substrate), where the former is more inexpensive.

For the case where the conductive semiconductor substrate is used as the device substrate, it is allowable to form a substrate-side, Ag-base contact layer having Ag as a major component, between the device substrate and the Ag-base reflective metal layer. This is successful in reducing the contact resistance between the substrate and the Ag-base reflective metal layer, and in reducing the cost because the Au-base contact layer is no more necessary. The substrate-side, Ag-base contact layer is specifically configured as an AgSb contact layer or an AgSn contact layer, both of which are particularly successful in enhancing the reducing effect on the contact resistance when a Si substrate (in particular of n-type) is used as the device substrate. A specific composition of the AgSb contact layer relates to Sb in an amount of 0.1% by mass to 20% by mass, both ends inclusive, where the residual portion accounts for Ag.

An experimental result showing effectiveness of the AgSb contact layer as the contact layer with respect to the Si substrate will be explained below. An Sb-doped, n-type single crystal substrate was used as the Si substrate, on the main surface thereof, an electrode of 354 μm thick, composed of an Ag-1% by mass Sb alloy, was formed by vacuum evaporation, and the product was annealed for alloying at 880° C. for 3 minutes. Thus produced test sample was subjected to Hall measurement to thereby evaluate I-V characteristic (measurement current: 19.9 mA). Result was shown in FIG. 3. The graph shows an I-V characteristic with an excellent linearity, and a sheet resistance of the electrode as low as 0.35 Ω/□, indicating that an ohmic electrode was successfully obtained.

It is also allowable to use, for example, an Sb-doped Si substrate having a sheet resistance of less than 0.01 Ω/□. This sort of Si substrate is successful in achieving the ohmic contact without forming the substrate-side, Ag-base contact layer, and consequently without carrying out the annealing for alloying between the Ag-base reflective metal layer and the Si substrate.

Specific examples of method of forming the metal layer include vapor-phase film forming processes such as vacuum evaporation and sputtering, and electrochemical film forming processes such as electroless plating and electrolytic plating.

A method of fabricating a light-emitting device of the first invention is proposed to fabricate the aforementioned light-emitting device of the first invention, and comprises the steps of:

forming an Ag-base metal layer having Ag as a major component on at least either of the main surface of the compound semiconductor layer having a light-emitting layer portion, the main surface being opposite to that planned for becoming the light extraction surface, and the main surface of the device substrate, the main surface being planned to be disposed on the light-emitting-layer-portion side; and

forming a stack of the device substrate and the compound semiconductor layer while placing the Ag-base metal layer in between, and annealing the stack to thereby bond the device substrate with the compound semiconductor layer while placing the Ag-base metal layer in between. This makes it possible to readily fabricate the light-emitting device of the first invention.

The method of the first invention may further comprise the steps of:

forming a first Ag-base metal layer, having Ag as a major component, on the bonding-side main surface of the compound semiconductor layer having the light-emitting layer portion, the bonding-side main surface being defined as the main surface opposite to that planned for becoming the light extraction surface;

forming a second Ag-base metal layer, having Ag as a major component, on the bonding-side main surface of the device substrate, the bonding-side main surface being defined as the main surface which is planned to be disposed on the light-emitting-layer-portion side; and

bonding the first Ag-base metal layer and the second Ag-base metal layer under a close contact through diffusion annealing, to thereby form the Ag-base reflective metal layer.

In this method, the Ag-base metal layers are dividedly formed on the compound semiconductor layer side and the device substrate side, and then subjected to the diffusion annealing under a close contact, to thereby bond and unite them into the Ag-base reflective metal layer. The Ag-base metal layers can be united with each other at relatively low temperatures. The method is therefore successful in readily fabricating the light-emitting device of the first invention with a high quality. As described in the above, by adjusting the ratio of Ag content to 95% by mass or above for both of the first Ag-base metal layer and the second Ag-base metal layer, together composing the Ag-base reflective metal layer, it is made possible to lower the lower limit of the adjustable range of diffusion annealing temperature, whereat the first Ag-base metal layer and the second Ag-base metal are bonded, to as low as 100° C. or around. In this case, the diffusion annealing temperature is set at an appropriate level at 100° C. or above. The aforementioned effect will more be enhanced if the Ag-base reflective metal layer (more specifically, the first Ag-base metal layer and the second Ag-base metal layer) is composed of pure Ag (where, inevitable contamination to as much as 1% by mass permissible).

For the case where the compound semiconductor layer is formed using (AlₓGa₁₋ₓ)_{y}In_{1-y}P (where, 0≦x≦1 and 0≦y≦1), it is allowable to form an AgGeNi contact layer on the bonding-side main surface of the compound semiconductor layer, and to form the first Ag-base metal layer so as to cover the AgGeNi contact layer. In this case, the reducing effect of the contact resistance can be enhanced if the annealing for alloying between the AgGeNi contact layer and the compound semiconductor layer is carried out within a range from 350° C. to 550° C.

It is also allowable to form an AgSb contact layer on the bonding-side main surface of the device substrate which comprises a Si substrate, and to form the second Ag-base metal layer so as to cover the AgSb contact layer. In this case, the reducing effect of the contact resistance can be enhanced if the annealing for alloying between the AgSb contact layer and the Si substrate is carried out, for example, within a range from 800° C. to 950° C.

Temperature of the diffusion annealing is adjustable within a range as wide as from 100° C. or higher and lower than 840° C., if both of the first Ag-base metal layer and the second Ag-base metal layer have a ratio of Ag content of 95% by mass or above. The temperature lower than 100° C. may result in only an insufficient bonding strength. On the other hand, the temperature of 840° C. or above undesirably allows an eutectic reaction to proceed between the Si substrate and Ag, and thereby seriously ruins the reflectivity of the Ag-base reflective metal layer.

(Second Invention)

To solve the aforementioned subject, a light-emitting device of the second invention is such as comprising:

a light-emitting layer portion being composed of a first compound semiconductor, having an emission peak wavelength of 450 to 580 nm, and having a light extraction surface on the main surface side thereof;

an Ag-base contact layer formed on the main back surface of the light-emitting layer portion, or formed on the main back surface of an auxiliary compound semiconductor layer composed of a second compound semiconductor, which is transparent with respect to emission light flux and is electrically coupled to the main back surface of the light-emitting layer portion, the Ag-base contact layer comprising an alloyed layer originated from an Ag-base contact metal, having Ag as a major component, and the compound semiconductor composing the main back surface of the compound semiconductor layer; and

an Ag-base reflective metal layer, composed of a metal having Ag as a major component, for reflecting light from the light-emitting layer portion back towards the light extraction surface side, and being formed so as to cover the Ag-base contact layer.

According to the configuration of the light-emitting device of the second invention, the Ag-base contact layer is formed on the main back surface of the compound semiconductor layer on which the Ag-base reflective metal layer is to be disposed, in a form of Ag-base contact layer produced by alloying between the compound semiconductor layer and the Ag-base contact metal, and the Ag-base reflective metal layer is formed so as to cover it. Alloying of a dopant element for forming the ohmic contact with the compound semiconductor, together with Ag, is successful in dramatically raising the ohmic contact property with the Ag-base reflective metal layer. The contact layer herein is formed as an alloy layer having a large ratio of Ag content, and this is successful in further raising the light extraction efficiency with respect to light emission having a peak emission wavelength ranging from 450 nm to 580 nm, that is, blue to green light as compared with the case where the contact layer is composed of a single-component metal such as Ni, Co, Mg or Sb.

The Ag-base reflective metal layer is far less expensive as compared with a reflective metal layer composed of an Au-base metal, and has only a small wavelength dependence of the reflectivity, showing a desirable reflectivity over the almost entire wavelength range of the visible light (350 nm to 700 nm). This makes it possible to achieve a large light extraction efficiency irrespective of emission wavelength of the device. It is also advantageous that the Ag-base metal is less likely to cause lowering in the reflectivity due to oxide film formation also with respect to blue-to-green light emission when compared with a metal such as Al. FIG. 4 shows reflectivity of mirror-polished surfaces of various metals, where plot “▪” represents reflectivity of Ag, plot “Δ” of Au, plot “♦” of Al (comparative example), and plot “x” of AgPdCu alloy. Reflectivity of Ag with respect to the visible light is especially large in a wavelength range from 350 nm to 700 nm (and longer wavelength in the infrared region), and particularly in 380 nm to 700 nm. It is therefore a matter of course that the second invention is successful in achieving a desirable reflectivity also in the blue-to-green light wavelength region ranging from 450 nm to 580 nm, both ends inclusive.

On the other hand, Au is a colored metal, and as is obvious from the reflectivity shown in FIG. 4, shows a strong absorption in the visible light region of 670 nm or shorter (particularly strong in 650 nm or shorter region, and still more stronger in 600 nm or shorter region), and so that the reflectivity will seriously be lowered when the light-emitting layer portion has a peak emission wavelength in 670 nm or shorter range. As a consequence, the emission intensity will naturally tend to lower with respect to blue or green light emission having a peak wavelength within a range from 450 nm to 580 nm, the emission spectrum will be somewhat different from that theoretically expected due to the absorption, and emission color tone will tend to vary. In contrast to this, Ag adopted in the second invention shows an excellent reflectivity also in the visible light region of 670 nm or shorter. In other words, adoption of the Ag-base reflective metal layer can realize a light extraction efficiency far larger than that expected from Au, with respect to blue to green light emission.

Although Al shows no absorption peak in FIG. 4, the reflectivity thereof in the visible light region is suppressed to a slightly lower level (e.g., 85 to 92%) due to formation of oxide film. On the contrary, Ag adopted in the second invention is less likely to produce the oxide film, and is therefore more successful in achieving a reflectivity higher than that of Al in the visible light region. More specifically, Ag shows a larger reflectivity than Al shows in the wavelength region of 400 nm or longer, particularly in the blue-to-green wavelength region ranging from 450 nm to 580 nm, both ends inclusive.

It is to be noted that the reflectivity of Al shown in FIG. 4 is measured for the Al surface which is mirror-finished by mechanical polishing and chemical polishing to thereby suppress formation of the surface oxide film, and actual measurement may give values still lower than those shown in FIG. 4 due to formation of a thick oxide film. For example, Ag is expressed in FIG. 4 as having a reflectivity smaller than that of Al in a short wavelength region from 350 nm to 400 nm, but is far less likely to produce the oxide film as compared with Al. Actual formation of the Ag-base reflective metal layer as the reflective metal layer on the light-emitting layer portion is thus successful in achieving the reflectivity superior to that of Al also in this wavelength region. Also in this wavelength region, Ag has a larger reflectivity than Au has.

In conclusion, it can be said that the Ag-base contact layer and the Ag-base reflective metal layer can ensure an especially remarkable improving effect of the light extraction efficiency as compared with Al and Au, when the light-emitting layer portion has a peak emission wavelength within a range from 350 nm to 670 nm (more preferably 400 nm to 670 nm, and still more preferably 450 nm to 600 nm), both ends inclusive. The light-emitting layer portion having the above-described peak emission wavelength can be configured as having a double heterostructure in which a first-conductivity-type cladding layer, an active layer and a second-conductivity-type cladding layer, all of these layers being composed of (AlₓGa₁₋ₓ)_{y}In_{1-y}P (where, 0≦x≦1 and 0≦y≦1) or InₓGa_{y}Al_{1-x-y}N (where, 0≦x≦1, 0≦y≦1 and x+y≦1), are stacked in this order.

The Ag-base contact layer and the Ag-base reflective metal layer may be formed directly on the main back surface of the light-emitting layer portion, or on the main back surface of the auxiliary compound semiconductor layer composed of the second compound semiconductor electrically coupled to the main back surface of the light-emitting layer portion. The auxiliary compound semiconductor layer herein must be transparent with respect to the light from the light-emitting layer portion, so as to allow the light from the light-emitting layer portion to reach the Ag-base reflective metal layer. In this case, it is preferable to adopt, as the second compound semiconductor composing the auxiliary compound semiconductor layer, a compound semiconductor having a band gap energy larger than that of the first compound semiconductor composing the light-emitting layer portion, or a compound semiconductor of indirect transition type.

Although the auxiliary compound semiconductor may be configured as an epitaxially-grown layer, a problem arises in that it takes a long time to grow the layer to a thickness required for allowing it to function as a reinforcing layer for the light emitting layer portion. On the contrary, the auxiliary compound semiconductor layer configured as a transparent conductive substrate bonded to the compound semiconductor layer for composing the light-emitting layer portion is successful in raising efficiency and simplicity of the manufacturing process. The Ag-base reflective metal layer in this case functions so as to reflect the light from the light-emitting layer portion back towards the light extraction surface side trough the transparent conductive substrate.

The Ag-base contact metal used for forming the Ag-base contact layer may be an AgGeNi contact metal having Ag as a major component.

An ohmic electrode structure for semiconductor device according to the second invention comprises:

an Ag-base contact layer (also referred to as AgGeNi contact layer, hereinafter) formed on the surface of a device main body composed of a Group III-V compound semiconductor, and comprising an alloyed layer originated from an AgGeNi contact metal having Ag as a major component and including also Ni and Ge, and the Group III-V compound semiconductor; and

an electrode layer formed so as to cover the Ag-base contact layer, and being composed of an Ag-base metal having Ag as a major component.

When the compound semiconductor layer is formed using a Group III-V compound semiconductor (e.g., aforementioned (AlₓGa₁₋ₓ)_{y}In_{1-y}P (where, 0≦x≦1 and 0≦y≦1) or InₓGa_{y}Al_{1-x-y}N (where, 0≦x≦1, 0≦y−1 and x+y≦1)), the AgGeNi contact metal is successful in far better ohmic contact as compared with the ohmic-contact-forming metals comprising a single-component Ni, Co, Mg or Sb disclosed in the Japanese Laid-Open Patent Publication No. 11-191641, and is also successful in achieving an excellent adhesiveness with the Ag-base reflective metal layer. A specific composition of the AgGeNi contact metal can be expressed as Ge of 0.1% to 25% by mass, Ni of 0.1% to 20% by mass, and Ag accounts for the residual portion. Any composition out of these ranges may result in only an insufficient effect of reducing the contact resistance.

The ohmic electrode structure for semiconductor device according to the second invention is applicable not only to the reflective metal layer of the light-emitting device, but also to electrodes of other semiconductor devices such as MESFET, HEMT and HBT. The electrode structure using Ag is economical because Ag is inexpensive as compared with generally-used, Au-base electrodes, and can ensure ohmic contact property comparable enough to that attainable by the Au-base electrodes.

In the light-emitting device of the second invention, it is preferable to dispose the Ag-base contact layer in a discrete manner on the main surface of the Ag-base reflective metal layer, between the Ag-base reflective metal layer and the transparent conductive substrate. The Ag-base reflective metal layer composes a part of current supply route towards to the light-emitting layer portion. Direct bonding of the Ag-base reflective metal layer to the light-emitting layer portion composed of a compound semiconductor may, however, undesirably lower the emission efficiency due to increased series resistance based on the contact resistance. For the case where the Ag-base reflective metal layer is used, a contact layer used on the light-emitting-layer-portion side may be composed of an Ag-base material, rather than the conventional Au-base material. Bonding of the Ag-base reflective metal layer to the light-emitting layer portion while placing the Ag-base contact layer in between is successful in reducing the contact resistance, and moreover in reducing costs for formation of the contact layer as compared with the case where the Au-base contact layer is used. It is, however, necessary for the Ag-base contact layer to be added with a relatively large amount of alloying components required for ensuring a desirable contact, and this inevitably lowers the reflectivity. One solution for this problem is to form the Ag-base contact layer in a discrete manner on the main surface of the Ag-base reflective metal layer, and this is successful in ensuring a large reflectivity ascribable to the Ag-base reflective metal layer, in the non-forming region of the Ag-base contact layer.

For the purpose of fully enhancing the light extraction efficiency, the ratio of formation area of the Ag-base contact layer to the Ag-base reflective metal layer (i.e., a value obtained by dividing the formation area of the Ag-base contact layer by the total area of the Ag-base reflective metal layer) preferably falls within a range from 1% to 25%, both ends inclusive. The ratio of formation area of the Ag-base contact layer less than 1% will fail in obtaining a sufficient suppressive effect on the contact resistance, and exceeding 25% will result in a lowered reflection intensity.

The Ag-base reflective metal layer is successful in further raising the reflectivity thereof in the non-formation region of the Ag-base contact layer, if the ratio of Ag content of the Ag-base reflective metal layer is set higher than that of the Ag-base contact layer. The aforementioned effect will more be enhanced if the Ag-base reflective metal layer (more specifically, the first Ag-base metal layer and the second Ag-base metal layer) is composed of a metal having an Ag content of 95% by mass or more, and more specifically pure Ag (where, inevitable contamination to as much as 1% by mass permissible). On the other hand, it is also allowable to compose the Ag-base reflective metal layer using a Pd-containing Ag alloy. The Pd-containing Ag alloy is excellent in sulfurization resistance and oxidation resistance, and is therefore effective in preventing degradation (degradation in the reflectivity when it is used as the reflective layer, and increase in the contact resistance when used as the electrode connected with other electrical terminals) induced by sulfurization or oxidation.

For the case where the compound semiconductor layer is formed using (AlₓGaₗ₋ₓ)_{y}In_{1-y}P (where, 0≦x≦1 and 0≦y≦1), it is preferable to form the AgGeNi contact layer on the bonding-side main surface of the compound semiconductor layer, and to form the first Ag-base metal layer so as to cover the AgGeNi contact layer. In this case, the reducing effect of the contact resistance can be enhanced if the annealing for alloying between the AgGeNi contact layer and the compound semiconductor layer is carried out, for example, within a range from 350° C. to 660° C.

(Third Invention)

To solve the aforementioned subject, a light-emitting device of the third invention is such as comprising:

a compound semiconductor layer having a light-emitting layer portion, being configured so that a first main surface of which serves as a light extraction surface; and

a device substrate bonded on a second main surface side of the compound semiconductor layer while placing a main metal layer in between, the main metal layer having a reflective surface for reflecting light from the light-emitting layer portion back towards the light extraction surface side; further comprising:

a diffusion-blocking layer interposed between the device substrate and the main metal layer, being composed of a conductive material, and provided for blocking diffusion of any device-substrate-derived components towards the main metal layer. It is to be noted that “main metal layer” in the context of this patent specification means a metal layer disposed between the compound semiconductor layer and the diffusion-blocking layer, composing the reflective surface, and having a role of bonding the compound semiconductor layer and the diffusion-blocking layer. It is therefore understood that the metal layer does not belong to the main metal layer when the diffusion-blocking layer is configured as the metal layer. It is also defined that the light-emitting-layer-portion side contact metal layer, described later, does not belong to the main metal layer.

In the configuration of the light-emitting device of the third invention, component diffusion, which tends to proceed from the device substrate towards the main metal layer during the bonding of the device substrate and the compound semiconductor layer while placing the main metal layer in between, is blocked by the diffusion-blocking layer, so that the main metal layer is successfully prevented from being denatured due to reaction (e.g., metallurgical reaction such as eutectic reaction) with the components of the device substrate. This effectively suppresses nonconformities such as lowering in the reflectivity of the reflective surface formed by the main metal layer, and lowering in the bonding strength between the main metal layer and the compound semiconductor layer. This makes it less likely to cause lowering in the production yield of the light-emitting device due to these non-conformities.

Between the diffusion-blocking layer and the device substrate, it is allowable to interpose the substrate-side contact metal layer for reducing the contact resistance. This successfully reduces the contact resistance between the diffusion-blocking layer composed of a conductive material and the device substrate, effectively suppresses an excessive increase in the series resistance, and consequently in the forward voltage.

The third invention is particularly effective when the main metal layer is composed of an Au-base layer having Au as a major component, at least in a portion including the interface with the diffusion-blocking layer, and the device substrate is a Si substrate. The Si substrate can readily attain, by doping, a sufficient level of conductivity required for the light-emitting device, and is inexpensive. What is better, Si and Au are likely to proceed eutectic reaction at relatively low temperatures (eutectic reaction temperature of an Au-Si binary system is 363° C., which may further be lowered under the presence of any other alloying components), and Si in the substrate side is likely to diffuse towards the Au-base-layer side during the annealing for bonding. This undesirably disturbs the reflective surface of the main metal layer due to eutectic reaction between the Au-base layer in the main metal layer and Si composing the device substrate, and is highly causative of lowering in the reflectivity. In contrast to this, according to the third invention, the diffusion-blocking layer disposed between the Au-base layer and the Si substrate can suppress the Si diffusion towards the Au-base layer, and can effectively prevent the reflectivity of the reflective surface of the main metal layer from lowering.

For the case where the Au-base layer and the Si substrate are used, the diffusion-blocking metal layer may be configured as a metal layer for blocking diffusion, having either Ti or Ni as a major component. A metal having Ti or Ni as a major component is particularly excellent in the suppressive effect on the Si diffusion towards the Au-base layer, and is thus applicable to the third invention in a desirable manner. The thickness of the metal layer for blocking diffusion preferably falls within a range from 1 nm to 10 μm, both ends inclusive. The thickness smaller than 1 nm will result in only an insufficient suppressive effect on the diffusion, and the thickness exceeding 10 μm will result in unnecessary rise in the production cost due to saturation of the suppressive effect. Although the metal layer for blocking diffusion may specifically be composed of pure Ti or pure Ni for industrial use, any sub-components may be included so far as the suppressive effect on the Si diffusion towards the Au-base layer is not ruined. For example, Pd added in an appropriate amount can raise the corrosion resistance of the metal having Ti or Ni as a major component. It is also allowable to use an alloy of Ti and Ni.

When the device substrate is an n-type Si substrate, it is preferable to interpose a substrate-side contact metal layer between the diffusion-blocking layer and the Si substrate, being composed of an AuSb alloy or an AuSn alloy, in order to reduce the contact resistance between the Si substrate and the diffusion-blocking layer. In this case, the suppressive effect on the contact resistance can be raised if the annealing for alloying is proceeded within a temperature range from 100° C. to 500° C.

In the third invention, the Au-base layer can compose the reflective layer. The Au-base layer, which is chemically stable and less likely to cause lowering in the reflectivity due to oxidation or the like, is desirable as a material for composing the reflective layer. In particular for the case where the Si substrate is used, eutectic reaction which possibly proceeds between Au in the Au-base layer composing the reflective surface and Si in the Si substrate may be highly causative of lowering in the reflectivity. The diffusion-blocking layer disposed between the Si substrate and the Au-base layer, as in the third invention, is successful in much effectively suppressing this sort of nonconformity, and this makes it possible to produce the reflective surface having a desirable reflectivity using the Au-base layer without problems. For the case where the reflective surface is produced using the au-base layer, it is allowable to dispose a light-emitting-layer-portion-side contact metal layer having Au as a major component, so as to be arranged in a discrete manner on the main surface of the Au-base layer, between the Ag-base layer and the compound semiconductor layer. The Au-base layer composes a part of current supply route towards to the light-emitting layer portion. Direct bonding of the Au-base layer to the light-emitting layer portion composed of a compound semiconductor may, however, undesirably lower the emission efficiency due to increased series resistance based on the contact resistance. In contrast to this, bonding of the Au-base layer to the light-emitting layer portion while placing the Au-base contact metal layer in between is successful in reducing the contact resistance. It is, however, necessary for the Au-base contact metal layer to be added with a relatively large amount of alloying components required for ensuring a desirable contact, and this slightly lowers the reflectivity. One solution for this problem is to form the light-emitting-layer-portion-side contact metal layer in a discrete manner on the main surface of the Au-base layer, and this is successful in ensuring a large reflectivity ascribable to the Au-base layer, in the non-forming region of the light-emitting-layer-portion-side contact metal layer.

The light-emitting-layer-portion-side contact metal layer can specifically be composed of an AuGeNi contact metal layer, and an especially large reducing effect on the contact resistance can be attained when the adjacent compound semiconductor layer is composed of an n-type Group II-V compound semiconductor (e.g., aforementioned (AlₓGa₁₋ₓ)_{y}In_{1-y}P (where, 0≦x≦1 and 0≦y≦1)). In this case, it is allowable to form the AuGeNi contact metal layer on the bonding-side main surface of the compound semiconductor layer, and to form the Au-base layer so as to cover the AuGeNi contact metal layer.

For the purpose of fully enhancing the light extraction efficiency, the ratio of formation area of the light-emitting-layer-portion-side contact metal layer to the Au-base layer (i.e., a value obtained by dividing the formation area of the light-emitting-layer-portion-side contact metal layer by the total area of the Au-base layer) preferably falls within a range from 1% to 25%, both ends inclusive. The ratio of formation area of the light-emitting-layer-portion-side contact metal layer less than 1% will fail in obtaining a sufficient suppressive effect on the contact resistance, and exceeding 25% will result in a lowered reflection intensity. The Au-base layer is successful in further raising the reflectivity thereof in the non-formation region of the light-emitting-layer-portion-side contact metal layer, if the ratio of Au content of the Au-base layer is set higher than that of the light-emitting-layer-portion-side contact metal layer.

In the light-emitting device of the third invention, it is also allowable to form the reflective surface using the Ag-base layer having Ag as a major component, disposed between the Au-base layer and the compound semiconductor layer. The Ag-base layer is less expensive as compared with the Au-base layer, and has only a small wavelength dependence of the reflectivity, because the Ag-base layer shows a desirable reflectivity over the almost entire wavelength range of the visible light (350 nm to 700 nm). This makes it possible to achieve a large light extraction efficiency irrespective of emission wavelength of the device. It is also advantageous that the Ag-base layer is less likely to cause lowering in the reflectivity due to oxide film formation when compared with a metal such as Al.

For the case where the Ag-base layer is used for forming the reflective surface, it is allowable to dispose, as the light-emitting-layer-portion-side contact metal layer, an Ag-base contact metal layer having Ag as a major component in a discrete manner on the main surface of the Ag-base layer, between the Ag-base layer and the compound semiconductor layer. When the compound semiconductor layer is composed of an n-type Group II-V compound semiconductor (e.g., aforementioned (AlₓGa₁₋ₓ)_{y}In_{1-y}P (where, 0≦x≦1 and 0≦y≦1)), an especially large reducing effect on the contact resistance can be attained by composing the Ag-base contact metal layer adjacent thereto with an AgGeNi contact metal layer. The ratio of formation area of the light-emitting-layer-portion-side, Ag-base contact metal layer with respect to the Ag-base layer preferably falls within a range from 1% to 25%, both ends inclusive, similarly to the aforementioned case of the Au-base contact metal layer.

Next, a method of fabricating a light-emitting device of the third invention is such as fabricating a light-emitting device which comprises:

a compound semiconductor layer having a light-emitting layer portion, being configured so that a first main surface of which serves as a light extraction surface; and

a device substrate bonded on a second main surface side of the compound semiconductor layer while placing a main metal layer in between, the main metal layer having a reflective surface for reflecting light from the light-emitting layer portion back towards the light extraction surface side;

and the method comprises the steps of:

forming a diffusion-blocking layer on the main surface of the device substrate on the side the compound semiconductor layer is to be bonded, being composed of a conductive material and planned for blocking diffusion of any device-substrate-derived components towards the main metal layer;

forming the main metal layer on at least either one of the second main surface of the compound semiconductor layer, and the main surface of the diffusion-blocking layer formed on the device substrate; and

bonding the device substrate and the compound semiconductor layer while placing the diffusion-blocking layer and the main metal layer in between.

According to the method of the third invention, component diffusion, which tends to proceed from the device substrate towards the main metal layer during the bonding of the device substrate and the compound semiconductor layer while placing the main metal layer in between, is blocked by the diffusion-blocking layer, so that the main metal layer is successfully prevented from being denatured due to reaction with the components of the device substrate. This effectively suppresses nonconformities such as lowering in the reflectivity of the reflective surface formed by the main metal layer, and lowering in the bonding strength between the main metal layer and the compound semiconductor layer. This makes it less likely to cause lowering in the production yield of the light-emitting device due to these nonconformities. In this case, the device substrate and the compound semiconductor layer can be bonded by stacking them while placing the diffusion-blocking layer and the main metal layer in between, and by annealing the stack. Despite the above-described components are more likely to diffuse during the annealing, interposition of the diffusion-blocking layer makes it possible to effectively suppress the nonconformities ascribable to the diffusion.

The method of fabricating a light-emitting device of the third invention may arbitrarily be added with the following features:

(1) the substrate-side contact metal layer for reducing the contact resistance between the device substrate and the diffusion-blocking layer is formed on the main surface of the device substrate, and the diffusion-blocking layer is then formed on the substrate-side contact metal layer;

(2) at least a portion of the main metal layer, including the interface with the diffusion-blocking layer, is configured as the Au-base layer having Au as a major component, and a Si substrate is used as the device substrate;

(3) the diffusion-blocking layer is configured as a metal layer for blocking diffusion, having either Ti or Ni as a major component;

(4) the diffusion-blocking layer is formed to a thickness of 1 nm to 10 μm, both ends inclusive; and

(5) the device substrate is an n-type Si substrate, and the substrate-side contact metal layer, composed of an AuSb alloy or an AuSn alloy, and is intended for reducing the contact resistance between the Si substrate and the diffusion-blocking layer is interposed between the diffusion-blocking layer and the Si substrate.

Effects and operations of addition of any of these features have already been explained in connection with the light-emitting device of the third invention, so that the explanation will not be repeated.

Next, in a method of fabricating a light-emitting device of the third invention, it is allowable to:

dispose a first Au-base layer planned for becoming the main metal layer and having Au as a major component, on the bonding-side main surface of the compound semiconductor layer having a light-emitting layer portion, the bonding-side main surface being defined as the main surface opposite to that planned for becoming the light extraction surface;

to dispose a second Au-base layer planned for becoming the main metal layer and having Au as a major component, on a bonding-side main surface of the device substrate, the bonding-side main surface being defined as the main surface planned to be disposed on the light-emitting-layer-portion side; and

to bond the first Au-base layer and the second Au-base layer under close contact.

According to the method of third invention, the first and second Au-base layers are dividedly formed on the compound semiconductor layer side and the device substrate side, and are then bonded with each other under a close contact. Because the Au-base layers can readily be united with each other at relatively low temperatures, only a low annealing temperature during the bonding is enough to obtain a sufficient level of bonding strength, and this facilitates the production of the reflective surface of the metal reflective layer including the Au-base layer, so as to have a desirable condition.

The annealing for bonding herein can be carried out at as low as 80° C. or above, if both of the first Au-base layer and the second Au-base layer have a ratio of Au content of 95% by mass or above. By adjusting the ratio of Au content to 95% by mass or above for both of the first Au-base layer and the second Au-base layer, the lower limit of a settable range of the annealing temperature in the bonding of the first and second Au-base layers can be lowered to as low as 80° C. or around. This makes it possible to further facilitate the bonding between the device substrate and the compound semiconductor layer, and to further raise the bonding strength. The aforementioned effect will more be enhanced if the Au-base layers (more specifically, the first Au-base layer and the second Au-base layer) are composed of pure Au (where, inevitable contamination to as much as 1% by mass permissible). Temperature of the annealing for bonding is more preferably set to 100° C. or above.

The effect of lowering the temperature of annealing for bonding in the above-described method, despite the Au-base layers are used, will become more pronounced when the Si substrate is used as the device substrate. Although the Si substrate can react with Au at a low eutectic reaction temperature, mutual bonding between the Au-base layers can proceed at an annealing temperature for bonding still lower than the eutectic reaction temperature, and can ensure a desirable reflectivity and bonding strength. As a combined effect of disposing the diffusion-blocking layer, the lowering of the annealing temperature for bonding is also successful in effectively suppressing the Si diffusion towards the Au-base layer (the second Au-base layer in a direct meaning), and in making the reflective surface formed by the finally-obtained main metal layer have a desirable reflectivity. This effect will become more pronounced when the reflective surface is composed of the first Au-base layer, that is, the reflective surface per ce is configured as the Au-base layer. For the case where the Si substrate is used, and both of the first Au-base layer and the second Au-base layer have a ratio of Au content of 95% by mass or above, the temperature of the annealing for bonding is preferably set to as low as 360° C. or below. The temperature of the annealing for bonding exceeding 360° C. results in an excessive alloying between the compound semiconductor layer and Au, and this seriously degrades the reflectivity of the metal layer.

For the case where the Si substrate is used as the device substrate, it is allowable to form a substrate-side contact metal layer on the bonding-side main surface of the Si substrate, to form the second Au-base layer so as to cover the substrate-side contact metal layer, and to carry out the annealing for alloying of the substrate-side contact metal layer and the Si substrate. When an n-type Si substrate is used, the substrate-side contact metal layer may be composed of an AuSb alloy or an AuSn alloy. In this case, the suppressive effect on the contact resistance can be raised if the annealing for alloying between the substrate-side contact metal layer and the Si substrate is proceeded within a temperature range from 100° C. to 500° C.

The light-emitting-layer-portion-side contact metal layer is preferably composed of an AuGeNi contact metal layer, when the adjacent compound semiconductor layer is composed of an n-type Group II-V compound semiconductor (e.g., aforementioned (AlₓGa₁ x)_{y}In_{1-y} P (where, 0≦x≦1 and 0≦y≦1)). In this case, it is allowable to form the AuGeNi contact metal layer on the bonding-side main surface of the compound semiconductor layer, and to form the aforementioned first Au-base layer so as to cover the AuGeNi contact metal layer. The suppressive effect on the contact resistance can be raised if the annealing for alloying between the AuGeNi contact metal layer and the compound semiconductor layer is proceeded typically within a temperature range from 350° C. to 500° C. On the other hand, the light-emitting-layer-portion-side contact metal layer can be formed as an AgGeNi contact metal layer when the Ag-base layer is used for forming the reflective surface. The suppressive effect on the contact resistance herein can be enhanced if the annealing for alloying between the AgGeNi contact metal layer and the compound semiconductor layer is proceeded typically within a temperature range from 350° C. to 500° C.

(Fourth Invention)

To solve the aforementioned subject, a light-emitting device of the fourth invention comprises:

a compound semiconductor layer having a light-emitting layer portion, being configured so that one main surface of which serves as a light extraction surface;

a device substrate bonded on the other main surface side of the light-emitting layer portion;

and a reflective metal layer interposed between the device substrate and the light-emitting layer portion, having any one of Ag, Ru, Rh, Re, Os, Ir and Pt as a major component, and being intended for reflecting the light from the light-emitting layer portion back towards the light extraction surface side.

The reflective metal layer having any of the above-described metal elements as a major component has only a small wavelength dependence of the reflectivity as compared with the reflective metal layer composed of the Au-base metal, and thus can realize an excellent light extraction efficiency irrespective of emission wavelength of the device. More specifically, Ag, Ru, Rh, Re, Os, Ir and Pt adoptable in the fourth invention can ensure a large reflectivity over the almost entire wavelength range of the visible light (350 nm to 700 nm), and by virtue of their properties as noble metals, they are less causative of lowering in the reflectivity due to oxide film formation as compared with other metals such as Al.

It is particularly preferable to configure the reflective metal layer as the Ag-base reflective metal layer having Ag as a major component. Ag is relatively inexpensive, and shows a desirable reflectivity almost over the entire range of the visible light region (350 nm to 700 nm). This makes it possible to reduce the wavelength dependence of the reflected light, and to enhance the reflectivity.

As described in the above, Au is a colored metal, and as is obvious from the reflection spectrum shown in FIG. 4, shows a strong absorption in the visible light region of 670 nm or shorter (particularly strong in 650 nm or shorter region, and still more stronger in 600 nm or shorter region), and so that the reflectivity will seriously be lowered when the light-emitting layer portion has a peak emission wavelength in 670 nm or shorter range. The total emission intensity will thus tend to lower, the emission spectrum will be somewhat different from that theoretically expected due to the absorption, and emission color tone will tend to vary. In contrast to this, Ag, Ru, Rh, Re, Os, Ir and Pt adopted in the fourth invention show an excellent reflectivity also in the visible light region of 670 nm or shorter. In other words, adoption of the fourth invention can realize a light extraction efficiency far larger than that expected from Au, when the light-emitting layer portion has a peak emission wavelength in 670 nm or shorter range (particularly in 650 nm or shorter, and more particularly 600 nm or shorter).

Although Al shows no absorption peak as shown in the reflection spectrum in FIG. 4, the reflectivity thereof in the visible light region is suppressed to a slightly lower level (e.g., 85 to 92%) due to formation of oxide film. On the contrary, the metals adopted in the fourth invention are noble metals and are less likely to produce the oxide film, and are therefore more successful in achieving a reflectivity higher than that of Al in the visible light region. More specifically, as found in FIG. 4, Ag shows a larger reflectivity than Al shows in a wavelength region of 400 nm or longer (particularly 450 nm or longer).

It is to be noted that the reflection spectrum of Al shown in FIG. 4 is measured for the Al surface which is mirror-finished by mechanical polishing and chemical polishing to thereby suppress formation of the surface oxide film, and actual measurement may give values still lower than those shown in FIG. 4 due to formation of a thick oxide film. For example, Ag is expressed in FIG. 4 as having a reflectivity smaller than that of Al in a short wavelength region from 350 nm to 400 nm, but is far less likely to produce the oxide film as compared with Al. Actual formation of the Ag-base reflective metal layer as the reflective metal layer on the light-emitting layer portion is thus successful in achieving the reflectivity superior to that of Al also in this wavelength region. Also in this wavelength region, Ag has a larger reflectivity than Au has.

In conclusion, it can be said that the Ag-base reflective metal layer can ensure an especially remarkable improving effect of the light extraction efficiency as compared with Al and Au, when the light-emitting layer portion has a peak emission wavelength within a range from 350 nm to 670 nm (more preferably 400 nm to 650 nm, and still more preferably 450 nm to 600 nm), both ends inclusive. The Ag-base reflective metal layer shows a desirable reflectivity typically also for blue to green light emission, that is, for the light having a peak wavelength of 450 nm to 580 nm. In other words, adoption of the Ag-base reflective metal layer makes it possible to distinctively improve the light emission efficiency with respect to the blue to green light when the light-emitting layer portion has a peak emission wavelength of 350 nm to 670 nm.

The light-emitting layer portion having the above-described peak emission wavelength can be configured as having a double heterostructure in which a first-conductivity-type cladding layer, an active layer and a second-conductivity-type cladding layer, all of these layers being composed of (AlₓGa₁₋ₓ)_{y}In_{1-y}P (where, 0≦x≦1 and 0≦y≦1) or InₓGa_{y}Al_{1-x-y}N (where, 0≦x≦1, 0≦y≦1 and x+y≦1), are stacked in this order (where, the reflective metal layer to be applied is not limited to that of Ag-base, but may also be those configured as having any of Ru, Rh, Re Os, Ir and Pt as a major component).

The light-emitting layer portion having the above-described configuration is convenient for obtaining light emission having a peak emission wavelength ranging from 450 nm to 580 nm, that is, blue to green light. Adoption of the light-emitting layer portion together with the Ag-base reflective metal layer can successfully realize blue to green light-emitting devices having an extremely large emission efficiency.

The reflective metal layer composes a part of current supply route towards to the light-emitting layer portion. For the case where the reflective metal layer is configured as the Ag-base reflective metal layer, direct bonding thereof to the light-emitting layer portion composed of a compound semiconductor may, however, undesirably lower the emission efficiency due to increased series resistance based on the contact resistance. It is therefore preferable, in view of reducing the contact resistance, to bond the Ag-base reflective metal layer to the light-emitting layer portion while placing the Ag-base contact layer having Ag as a major component in between. The Ag-base contact layer is, however, inferior to the Ag-base reflective metal layer in the reflectivity due to alloying with the compound semiconductor layer. One solution for this problem is to form the Ag-base contact layer in a discrete manner on the main surface of the Ag-base reflective metal layer, and this is successful in ensuring a large reflectivity ascribable to the Ag-base reflective metal layer, in the non-forming region of the contact layer.

It is also allowable to use an Au-base contact layer having Au as a major component (e.g., AuGeNi contact layer) in place of the Ag-base contact layer. No matter how the aforementioned Ag-base contact layer undesirably causes the alloying, the reflectivity thereof is still far larger than that of the Au-base contact layer with respect to the blue-to-green light, and more specifically, the light having a peak emission wavelength within a range from 450 nm t 580 nm. The light extraction efficiency with respect to the blue-to-green light can further be improved by adopting the Ag-base contact layer. The Ag-base contact layer is also advantageous in that it is less expensive as compared with the Au-base contact layer.

For the purpose of fully enhancing the light extraction efficiency, the ratio of formation area of the Ag-base contact layer (or Au-base contact layer) to the Ag-base reflective metal layer (i.e., a value obtained by dividing the formation area of the contact layer by the total area of the Ag-base reflective metal layer) preferably falls within a range from 1% to 25%, both ends inclusive. The ratio of formation area of the contact layer less than 1% will fail in obtaining a sufficient suppressive effect on the contact resistance, and exceeding 25% will result in a lowered reflection intensity.

The reflectivity of the Ag-base reflective metal layer will further be enhanced if the ratio of Ag content of the Ag-base reflective metal layer is set larger than that of the Ag-base contact layer. The aforementioned effect will more be enhanced if the Ag-base reflective metal layer is composed of a metal having an Ag content of 95% by mass or more, and more specifically pure Ag (where, inevitable contamination to as much as 1% by mass permissible). On the other hand, it is also allowable to compose the Ag-base reflective metal layer using a Pd-containing Ag alloy. The Pd-containing Ag alloy is excellent in sulfurization resistance and oxidation resistance, and is therefore effective in preventing degradation of the reflectivity induced by sulfurization or oxidation. It can also raise the bonding strength with the metal layer for bonding described later.

The Ag-base contact layer can more readily form a desirable ohmic contact if it is composed of an AgGeNi alloy having Ag as a major component and also including Ni and Ge. The Ag-base contact layer composed of the AgGeNi alloy shows a large adhesiveness with the Ag-base reflective metal layer. A specific composition of the AgGeNi alloy preferably adoptable in the fourth invention is expressed as Ge of 0.1% to 25% by mass, Ni of 0.1% to 20% by mass, and Ag accounts for the residual portion. Any composition out of these ranges may result in only an insufficient effect of reducing the contact resistance.

For the case where the device substrate and the light-emitting layer portion are bonded while placing the reflective metal layer in between, allowable procedures therefor may be such that the reflective metal layer is preliminarily formed on the device substrate side, and the light-emitting layer portion is bonded to the reflective metal layer; or such that the reflective metal layer is preliminarily formed on the light-emitting-layer-portion side, and the device substrate is then bonded thereto. It is still also allowable to form the first metal layer including the reflective metal layer on the light-emitting-layer-portion side, and the second metal layer formed preliminarily formed on the device substrate is bonded thereto.

Adoption of a method in which the Ag-base reflective metal layer composing the reflective metal layer is bonded to the light-emitting layer portion may sometimes causes reduction in the gloss of the surface of the Ag-base reflective metal layer before bonding due to oxidation or sulfurization, or causes coloring, both of which may result in lowering of the reflection intensity. As one measure, bonding of the Ag-base reflective metal layer with the light-emitting layer portion while placing a protective metal layer in contact with the Ag-base reflective metal layer will be successful in effectively preventing the Ag-base reflective metal layer from being oxidized or sulfurized. By forming the protective metal layer to an appropriate thinness, a desirable reflection characteristic with respect to the light from the light-emitting layer portion, attributable to features (large reflection intensity and small wavelength dependence) of the Ag-base metal, is obtained despite the interposition of the protective metal layer. This effect can be achieved by any of the following measures: the protective metal layer is formed in an island form by adjusting the thickness thereof so as to allow the Ag-base reflective metal layer to expose in the inter-island region; and the protective metal layer is made in a thickness sufficiently thinner than the wavelength of light to be reflected thereon, so as to make the light transmission effect based on tunneling effect becomes more notable.

The protective metal layer shows a particularly distinctive protective effect over the Ag-base reflective metal layer when it is composed of the Au-base metal layer having chemically-stable Au as a major component. Besides the Au-base metal, any other metals can compose the protective metal layer so far as they are more noble than Ag, such as those having Ru, Rh, Re, Os, Ir or Pt as a major component.

The protective metal layer formed to an excessive thickness makes the reflection characteristic of the protective metal layer predominant over that of the Ag-base reflective metal layer, and this may ruin the effects of large reflectivity and small wavelength dependence which are specific to the Ag-base reflective metal layer. On the contrary, too thin protective metal layer may result in only an insufficient effect of protecting the Ag-base reflective metal layer from oxidation or sulfurization. From this point of view, the thickness of the protective metal layer is preferably set to 0.5 nm to 15 nm, both ends inclusive.

The device substrate configured as a conductive substrate allows it to serve as a part of conduction path for driving the light-emitting device, and this simplifies the device structure. Available examples of the conductive substrate not only include metal layer composed of Al, Cu or alloys thereof, but also include Si substrate (polysilicon substrate or single-crystal substrate, where the former is more inexpensive).

For the case where it is difficult to directly bond the reflective metal layer to the device substrate, the reflective metal layer can be bonded to the device substrate while placing the binding-use metal layer in between. The binding-use metal layer is preferably composed of the Au-base metal layer having Au as a major component, because the material is less likely to be affected by oxidation or the like, and can readily ensure a sufficient binding strength with the device substrate. When the device substrate is configured using a Si substrate, the Au-base metal layer used as the binding-use metal layer is successful in generally reducing the contact resistance with the Si substrate. For the case where the Ag-base reflective metal layer is used, the binding-use metal layer composed of the Au-base metal layer can readily be bound to the Ag-base reflective metal layer.

The reflective metal layer in this case can be configured as being bound to the device substrate while placing the binding-use metal layer which is composed of a first Au-base layer and a second Au-base layer disposed in contact with each other in this order as viewed from the reflective metal layer side. A method of fabricating a light-emitting device of the fourth invention is to fabricate the light-emitting device configured as described in the above, and comprises the steps of:

forming the reflective metal layer on a bonding-side main surface of the compound semiconductor layer, the bonding-side main surface being defined as the main surface opposite to that planned for becoming the light extraction surface;

disposing a first Au-base layer having Au as a major component and being a precursor for the binding-use metal layer;

disposing a second Au-base layer, having Au as a major component, on the bonding-side main surface of the device substrate, the bonding-side main surface being defined as the main surface which is planned to be disposed on the light-emitting-layer-portion side; and

bonding the first Au-base layer and the second Au-base layer under a close contact.

According to the method of fourth invention, the first and second Au-base layers are dividedly formed on the compound semiconductor layer side and the device substrate side, and are then bonded with each other under a close contact. Because the Au-base layers can readily be united with each other at relatively low temperatures, only a low annealing temperature during the bonding is enough to obtain a sufficient level of bonding strength, and this facilitates the production of the reflective surface of the metal reflective layer including the Au-base layer, so as to have a desirable condition.

The bonding between the device substrate and the compound semiconductor layer can further be facilitated, and the bonding strength can further be raised if both of the first Au-base layer and the second Au-base layer have a ratio of Au content of 95% by mass or above. The aforementioned effect will more be enhanced if the Au-base layers (more specifically, the first Au-base layer and the second Au-base layer) are composed of pure Au (where, inevitable contamination to as much as 1% by mass permissible).

The effect of lowering the temperature of annealing for bonding in the above-described method, despite the Au-base layers are used, will become more pronounced when the Si substrate is used as the device substrate. Although the Si substrate can react with Au at a low eutectic reaction temperature, mutual bonding between the Au-base layers can proceed at an annealing temperature for bonding still lower than the eutectic reaction temperature, and can ensure a desirable reflectivity and bonding strength. As a combined effect of disposing the diffusion-blocking layer, the lowering of the annealing temperature for bonding is also successful in effectively suppressing the Si diffusion towards the Au-base layer, and in making the reflective surface formed by the finally-obtained reflective metal layer have a desirable reflectivity.

For the case where the compound semiconductor layer is formed using (AlₓGa₁₋ₓ)_{y}In_{1-y}P (where, 0≦x≦1 and 0-≦y≦1), it is preferable to form the AgGeNi contact layer on the bonding-side main surface of the compound semiconductor layer, and to form the Ag-base reflective metal layer so as to cover the AgGeNi contact layer. In this case, the reducing effect of the contact resistance can be enhanced if the annealing for alloying between the AgGeNi contact layer and the compound semiconductor layer is carried out, for example, within a range from 350° C. to 660° C.

(Fifth Invention)

To solve the aforementioned subject, a light-emitting device of the fifth invention is such as fabricating a light-emitting device which comprises:

a compound semiconductor layer having a light-emitting layer portion, being configured so that one main surface of which serves as a light extraction surface; and

a device substrate bonded on the other main surface side of the compound semiconductor layer while placing a metal layer in between, the metal layer having a reflective surface for reflecting light from the light-emitting layer portion back towards the light extraction surface side, and the metal layer being composed of an Au-base layer having Au as a major component at least in a portion thereof including the reflective surface;

the method comprising the steps of:

disposing a first Au-base layer composing the reflective surface on a bonding-side main surface of the compound semiconductor layer, the bonding-side main surface being defined as the main surface opposite to that planned for becoming the light extraction surface;

disposing a second Au-base layer on the bonding-side main surface of the device substrate, the bonding-side main surface being defined as the main surface which is planned to be disposed on the light-emitting-layer-portion side; and

bonding the first Au-base metal layer and the second Au-base metal layer under a close contact.

According to the method of fifth invention, the first and second Au-base layers are dividedly formed on the compound semiconductor layer side and the device substrate side, and are then bonded with each other under a close contact. Because the Au-base layers can readily be united with each other at relatively low temperatures, only a low annealing temperature during the bonding is enough to obtain a sufficient level of bonding strength, and this facilitates the production of the reflective surface of the metal reflective layer including the Au-base layer, so as to have a desirable condition. Because the reflective surface per ce is composed of the Au-base layer excellent in corrosion resistance, the reflective surface successfully exempts from being corroded in depth, even if it is exposed to a highly-corrosive solution in chemical treatment processes for separating the light-emitting-layer-growing substrate or for roughening treatment (so-called frosting) of the light-emitting layer portion, described later, in the process of fabricating the light-emitting element. This is successful in facilitating the fabrication process, and in preventing the surface condition of the reflective surface from being seriously degraded.

The light-emitting layer portion preferably has a peak emission wavelength of 550 nm or longer. It is made clear from the graph in FIG. 4 showing wavelength dependence of reflectivity, that the Au layer indicated by plot “Δ” shows a strong absorption in the visible light region shorter than 550 nm. The peak emission wavelength of the light-emitting layer portion of 550 nm or longer can, therefore, effective suppress the reflectivity from lowering, and can enhance the emission intensity. This is also advantageous in preventing non-conformities such that the resultant light spectrum will be somewhat different from that theoretically expected due to the absorption, or that the emission color tone will tend to vary. In this point of view, desired color tones and correspondent peak emission wavelength can be defined as follows:

yellowish green: 550 nm or longer, and shorter than 580 nm;

yellow: 580 nm or longer, and shorter than 595 nm;

amber: 595 nm or longer, and shorter than 610 nm;

orange: 610 nm or longer, and shorter than 630 nm; and

red: 630 nm or longer, and shorter than 780 nm.

As is obvious from FIG. 4, an improved reflectivity and an enhanced emission intensity can be obtained when the peak emission wavelength of the light-emitting layer portion falls on 580 nm or longer and more preferably 600 nm or longer. In this point of view, the reflectivity ascribable to the Au-base layer can particularly be improved, and the effect of enhancing the emission intensity will be more pronounced when the light-emitting layer portion capable of emitting yellow, amber, orange or red light is adopted.

More specifically, in a method of fabricating the light-emitting device of the fifth invention:

the light-emitting layer portion is first formed by epitaxial growth on a light-emitting-layer-growing substrate composed of a compound semiconductor;

the first Au-base layer is formed on the bonding-side main surface of the light-emitting layer portion in a state of being united with the light-emitting-layer-growing substrate;

the second Au-base layer is formed on the bonding-side main surface of the device substrate;

the first Au-base layer and the second Au-base layer are bonded under a close contact; and

after the bonding, the light-emitting-layer-growing substrate is separated from the light-emitting layer portion by chemical etching.

In the above-described process, the first Au-base layer which is formed on the bonding-side main surface of the light-emitting layer portion in a state of being united with (not separated from) the light-emitting-layer-growing substrate, and the second Au-base layer which is formed on the bonding-side main surface of the device substrate, are bonded. The light-emitting layer portion formed as a thin film can therefore be handled for bonding in a state of being mechanically reinforced by the light-emitting-layer-growing substrate. This is successful in largely reducing probability of generation of nonconformities such as cracking or chipping of the light-emitting layer portion, and the fabrication process can dramatically be simplified, as compared with the case where the light-emitting layer portion is separated before the bonding. The light-emitting-layer-growing substrate in this case is separated after the bonding from the light-emitting layer portion by the chemical etching, where the reflective layer composed of the Au-base layer is extremely less likely to be affected by the chemical etching, and there is no fear of causing separation of the light-emitting layer during the etching.

In an exemplary case where the light-emitting layer portion layer is composed of (AlₓGa₁₋ₓ)_{y}In_{1-y}P (where, 0≦x≦1 and 0≦y≦1), and the light-emitting-layer-growing substrate is composed of a GaAs substrate, the chemical etching can be carried out using an ammonia/hydrogen peroxide mixed solution so as to dissolve the GaAs substrate. The ammonia/hydrogen peroxide mixed solution is excellent in corrosion selectivity of the GaAs substrate over (AlₓGa₁₋ₓ)_{y}In_{1-y}P, and capable of rapidly and extensively separating and removing only the GaAs substrate simply by immersing the light-emitting layer portion into the solution. There is no fear of corroding the Au-base layer for forming the reflective surface. It is to be understood in the fifth invention that removal of the entire portion of the light-emitting-layer-growing substrate by etching is also included in the concept of “separation”.

On the other hand, in an exemplary case where the light-emitting layer portion composed of (AlₓGa₁₋ₓ)_{y}In_{1-y}P (where, 0≦x≦1 and 0≦y≦1) is formed on a GaAs substrate which serves as the light-emitting-layer-growing substrate while placing an AlAs releasing layer in between, the chemical etching can be carried out using a hydrofluoric acid-containing solution so as to dissolve the AlAs releasing layer. The GaAs substrate can readily be separated from the light-emitting layer portion by dissolving the AlAs releasing layer using the hydrofluoric acid-containing solution. There is no fear of corroding the Au-base layer for forming the reflective surface. Since the GaAs substrate separated in this process is not dissolved, and may be recycled typically for the growth of the light-emitting layer portion for the next time.

Next, for the case where the light-emitting layer portion is composed of a Group II-V compound semiconductor, and both of the first Au-base layer and the second Au-base layer are composed of an Au-base metal having a ratio of Au content of 95% by mass or above, the first Au-base layer and the second Au-base layer can be bonded by subjecting them under a close contact to annealing for bonding at a temperature higher than 180° C. and not higher than 360° C. According to this method, the first and second Au-base layers are dividedly formed on the compound semiconductor layer side composed of the Group III-V compound semiconductor and the device substrate side, and are then bonded with each other under a close contact. The first and second Au-base layers, having a ratio of Au content of 95% by mass or above, can readily be united with each other at temperature higher than 180° C. and not higher than 360° C. This is successful in readily achieving a sufficient bonding strength, in preventing the Au-base layer from being affected by the diffusion or reaction ascribable to the substrate side or compound semiconductor layer side during the annealing for bonding, and in readily forming the reflective surface of the metal reflective layer including the Au-base layer, so as to have a desirable condition.

The aforementioned effect will more be enhanced if the Au-base layers (more specifically, the first Au-base layer and the second Au-base layer) are composed of pure Au (where, inevitable contamination to as much as 1% by mass permissible).

In order to suppress influences of the diffusion or reaction ascribable to the substrate side or compound semiconductor layer side with respect to the Au-base layer, the upper limit of the temperature in the annealing for bonding is set to 360° C. It is more preferable to carry out the annealing for bonding at a temperature lower than 300° C. For example, the Si substrate can be used as the device substrate. The Si substrate can readily attain, by doping, a sufficient level of conductivity required for the light-emitting device, and is inexpensive. Si is, however, likely to diffuse into Au, and is likely to proceed the eutectic reaction at relatively low temperatures (eutectic reaction temperature of an Au-Si binary system is 363° C.). Only a small excess of the temperature of the annealing for bonding is therefore highly causative of diffusion of a large amount of Si composing the device substrate into the Au-base layer in the metal reflective layer, or causative of the eutectic reaction, and is very likely to result in a lowered reflectivity. In the fifth invention, however, the bonding is proceeded between the Au-base layers by annealing for bonding at a temperature of 360° C. or below, and more preferably 300° C. or below. This makes it possible to carry out the annealing for bonding at a temperature sufficiently lower than the eutectic temperature, and can ensure a desirable reflectivity and bonding strength.

For the case where the compound semiconductor layer, on which the first Au-base layer is formed, is composed of a Group III-V compound semiconductor, when the first Au-base layer and the second Au-base layer under a close contact are subjected to the annealing for bonding using an external heat source, the first Au-base layer side will have heat transferred thereto through the compound semiconductor layer. The Groups III-V compound semiconductor, however, has only a small heat conductivity as compared with those of other semiconductors including Si, so that the Group III-V compound semiconductor layer inhibits the heat conduction towards the first Au-base layer when the temperature in the annealing for bonding becomes excessively low, and makes it impossible to obtain a strongly bonded status with the second Au-base layer. In the fifth invention, the temperature in the annealing for bonding is therefore set higher than 180° C. so that the first Au-base layer and the second Au-base layer can be bonded with a sufficient strength despite the heat conductivity of the Group III-V compound semiconductor is not so large. The aforementioned effect will more be enhanced if the Group III element in the compound semiconductor layer is composed of at least any one selected from Al, Ga and In, and the Group V element in the same layer is composed of at least either one of P and As.

For the case where the Si substrate is used as the device substrate, it is allowable to form a substrate-side contact layer on the bonding-side main surface of the Si substrate, to form the second Au-base layer so as to cover the substrate-side contact layer, and to carry out the annealing for alloying of the substrate-side contact layer and the Si substrate. When an n-type Si substrate is used, the substrate-side contact layer may be composed of an AuSb alloy or an AuSn alloy. In this case, the suppressive effect on the contact resistance can be raised if the annealing for alloying between the substrate-side contact layer and the Si substrate is proceeded within a temperature range from 250° C. to 500° C.

In the fifth invention, the first Au-base layer can compose the reflective layer. The Au-base layer, which is chemically stable and less likely to cause lowering in the reflectivity due to oxidation or the like, is desirable as a material for composing the reflective layer. In particular for the case where the Si substrate is used, eutectic reaction which possibly proceeds between Au in the first Au-base layer composing the reflective surface and Si in the Si substrate may be highly causative of lowering in the reflectivity. This sort of nonconformity can, however, effectively be suppressed by adopting the fifth invention, and this makes it possible to produce the reflective surface having a desirable reflectivity using the Au-base layer without problems.

In the method of fabricating the light-emitting device of the fifth invention, it is allowable to dispose a light-emitting-layer-portion-side, Au-base contact layer having Au as a major component, so as to be arranged in a discrete manner on the main surface of the Au-base layer, between the Au-base layer and the compound semiconductor layer. The Au-base layer composes a part of current supply route to the light-emitting layer portion. Direct bonding of the Au-base layer to the light-emitting layer portion composed of a compound semiconductor may, however, undesirably lower the emission efficiency due to increased series resistance based on the contact resistance. However, the contact resistance can successfully be reduced by bonding the Au-base layer to the light-emitting layer portion while placing the Au-base contact layer in between. It is, however, necessary for the Au-base contact layer to be added with a relatively large amount of alloying components required for ensuring a desirable contact, and this slightly lowers the reflectivity. One solution for this problem is to form the light-emitting-layer-portion-side contact layer in a discrete manner on the main surface of the Au-base layer, and this is successful in ensuring a large reflectivity ascribable to the Au-base layer, in the non-forming region of the light-emitting-layer-portion-side contact layer.

The light-emitting-layer-portion-side contact layer can specifically be composed of an AuGeNi contact metal layer, and an especially large reducing effect on the contact resistance can be attained when the adjacent compound semiconductor layer is composed of an n-type Group II-V compound semiconductor (e.g., aforementioned (AlₓGa₁₋ₓ)_{y}In_{1-y}P (where, 0≦x≦1 and 0≦y≦1)). In this case, it is allowable to form the AuGeNi contact layer on the bonding-side main surface of the compound semiconductor layer, and to form the first Au-base layer so as to cover the AuGeNi contact layer. The suppressive effect on the contact resistance can be raised if the annealing for alloying between the AuGeNi contact layer and the compound semiconductor layer is proceeded typically within a temperature range from 350° C. to 500° C.

For the purpose of fully enhancing the light extraction efficiency, the ratio of formation area (i.e., a value obtained by dividing the formation area of the light-emitting-layer-portion-side contact layer by the total area of the Au-base layer) of the light-emitting-layer-portion-side contact layer to the Au-base layer (first Au-base layer) preferably falls within a range from 1% to 25%, both ends inclusive. The ratio of formation area of the light-emitting-layer-portion-side contact layer less than 1% will fail in obtaining a sufficient suppressive effect on the contact resistance, and exceeding 25% will result in a lowered reflection intensity.

The reflectivity of the Au-base layer will further be enhanced if the ratio of Au content of the Au-base layer is set larger than that of the light-emitting-layer-portion-side contact layer.

(Sixth Invention)

To solve the aforementioned subject, a light-emitting device of the sixth invention is such as comprising:

a compound semiconductor layer having a light-emitting layer portion, being configured so that a first main surface of which serves as a light extraction surface;

a Si substrate bonded on a second main surface side of the compound semiconductor layer while placing a metal layer in between;

wherein the bonding surface of the metal layer with the compound semiconductor layer forms a reflective layer, and the metal layer has a Si-diffusion-blocking layer having Au or Ag as a major component and also containing a Si-diffusion-blocking component which comprises a single, or two or more elements selected from Sn, Pb, In and Ga, and being planned for inhibiting Si diffused from the Si substrate from depositing on the reflective surface.

A method of fabricating the light-emitting device of the sixth invention is such as fabricating a device which comprises:

a compound semiconductor layer having a light-emitting layer portion, being configured so that a first main surface of which serves as a light extraction surface; and

a Si substrate bonded on a second main surface side of the compound semiconductor layer while placing a metal layer in between, wherein the bonding surface between the metal layer and the compound semiconductor layer configures a reflective layer;

where the method comprises the steps of:

forming the metal layer as having a Si-diffusion-blocking layer which has Au or Ag as a major component and also contains a Si-diffusion-blocking component which comprises a single, or two or more elements selected from Sn, Pb, In and Ga, and being planned for inhibiting Si diffused from the Si substrate from depositing on the reflective surface; and

bonding the Si substrate and the compound semiconductor layer while placing the metal layer in between.

According to the configuration of the light-emitting device of the sixth invention, the Si diffusion from the Si substrate towards the metal layer, which possibly proceeds during the bonding of the Si substrate and the compound semiconductor layer, can be blocked, and thus denaturation of the metal layer induced by the Si diffusion can effectively be obstructed. As a consequence, nonconformities such as lowered reflectivity of the reflective surface formed by the metal layer, and lowered adhesion strength between the metal layer and the compound semiconductor layer can effectively be avoided.

The Si-diffusion-blocking layer is configured as having Au or Ag as a major component and as containing a Si-diffusion-blocking component which comprises a single, or two or more elements selected from Sn, Pb, In and Ga. These four elements composing the Si-diffusion-blocking component produce a strong repulsion potential with respect to Si atom in a solid state, show a solid solubility limit into Si almost close to zero as indicated by the phase diagram, and thus exert a large inhibiting effect on the Si diffusion. Au or Ag in a form of single component suffers from a relatively large diffusion coefficient with respect to Si at the bonding temperature (100° C. to 500° C., both ends inclusive) described later, but addition thereto of an appropriate amount of these Si-diffusion-blocking components can successfully reduce the Si diffusion to a considerable degree.

The bonding strength between the Si substrate and the compound semiconductor layer can be enhanced effectively by stacking the Si substrate and the compound semiconductor layer while placing the metal layer in between, and then by annealing the stack, where disposition of the Si-diffusion-blocking layer is successful in effectively blocking the Si diffusion from the Si substrate towards the metal layer even when this sort of annealing is carried out.

The Si-diffusion-blocking layer preferably has a content of the Si-diffusion-blocking component of 1% by mass to 20% by mass, both ends inclusive. The content of the Si-diffusion-blocking component less than 1% by mass results in only a poor blocking effect on the Si diffusion. The content exceeding 20% by mass results in saturation of the effect, makes the formation of a brittle intermetallic compound more remarkable, and may weaken the bonding strength between the Si substrate and the compound semiconductor layer.

Between the Si-diffusion-blocking layer and the Si substrate, it is allowable to interpose a substrate-side contact alloyed layer for reducing the contact resistance between the Si substrate and the Si-diffusion-blocking layer. In the metal layer, between the compound semiconductor and the Si-diffusion-blocking layer, it is also allowable to dispose a main metal layer having a content of the Si-diffusion-blocking component smaller than that of the Si-diffusion-blocking layer. The Si-diffusion-blocking component herein is aimed at blocking the Si diffusion from the Si substrate, but in some situation it may be more preferable to further reduce the amount of addition of the Si-diffusion-blocking component, in view of ensuring the bonding properties between the silicon substrate and the compound semiconductor layer while placing the metal layer in between, or ensuring the reflectivity of the metal layer. The main metal layer having only a suppressed content of the Si-diffusion-blocking component disposed on the compound-semiconductor-layer side, besides the Si-diffusion-blocking layer, is therefore successful in excluding adverse effects on the bonding strength or the reflectivity caused by the Si-diffusion-blocking component.

For the case where the above-described main metal layer is disposed, it is preferable to adjust the thickness of the Si-diffusion-blocking layer within a range from 50 nm to 5 μm, both ends inclusive. The thickness smaller than 50 nm will result in only an insufficient suppressive effect on the diffusion, and the thickness exceeding 5 μm will result in unnecessary rise in the production cost due to saturation of the suppressive effect.

When the Si-diffusion-blocking layer is configured as having Au as a major component, the main metal layer may be configured as having an Au-base main metal layer which forms the reflective surface and has Au as a major component. Because the Au-base layer is chemically stable and less likely to cause lowering in the reflectivity due to oxidation or the like, it is desirable as a material for composing the reflective layer. Si and Au are, however, likely to cause the eutectic reaction at relatively low temperatures (eutectic reaction temperature of an Au-Si binary system is 363° C., which may further be lowered under the presence of any other alloying components), and Si on the substrate side is likely to diffuse towards the Au-base-layer side during the annealing for bonding. The Au-base layer disposed in the metal reflective layer is therefore very likely to lower the reflectivity due to the Si diffusion. Whereas in the sixth invention, the Si-diffusion-blocking layer is disposed between the Au-base main metal layer composing the reflective surface and the Si substrate, and this is successful in blocking the Si diffusion towards the Au-base main metal layer, and in effectively preventing the reflectivity from being lowered.

On the other hand, it is also allowable to configure the Si-diffusion-blocking layer as having Au as a major component, and to configure the main metal layer as having an Au-base coupling layer which has Au as a major component, in a portion thereof in contact with the Si-diffusion-blocking layer, and as having an Ag-base reflective layer which has Ag as a major component, or an Al-base reflective layer which has Al as a major component, in a portion thereof composing the reflective surface. The Ag-base layer is less expensive as compared with the Au-base layer, and has only a small wavelength dependence of the reflectivity, showing a desirable reflectivity over the almost entire wavelength range of the visible light (350 nm to 700 nm). This makes it possible to achieve a desirable reflection efficiency irrespective of emission wavelength of the device. It is also advantageous that the Ag-base metal is less likely to cause lowering in the reflectivity due to oxide film formation when compared with a metal such as Al.

On the other hand, the metal layer may be configured so that the Si-diffusion-blocking layer composes the reflective surface. The entire configuration of the metal layer and the fabrication process can therefore be simplified to a considerable degree, as compared with the case where the main metal layer is disposed besides the Si-diffusion-blocking layer. In particular, the metal layer having the entire portion of which configured as a single Si-diffusion-blocking layer can achieve more dramatic effects of simplifying the configuration and the fabrication process. Because an excessive content of the Si-diffusion-blocking component in the Si-diffusion-blocking layer results in a serious decrease in the reflectivity of the reflective surface composed by the Si-diffusion-blocking layer, the content of the Si-diffusion-blocking component is preferably limited to as low as 10% by mass or below.

### BRIEF DESCRIPTION OF THE DRAWINGS

FIG. 1 is a schematic drawing showing a stacked structure of one embodiment of the light-emitting device according to the first invention;

FIG. 2 is a drawing showing exemplary process steps of fabricating the light-emitting device of the first invention;

FIG. 3 is a graph of I-V characteristics showing an experimental result which proves ohmic contact between an AgSb electrode and a Si substrate;

FIG. 4 is a graph showing reflectivity of various metals;

FIG. 5 is a schematic drawing showing a stacked structure of one embodiment of the light-emitting device according to the second invention;

FIG. 6 is a drawing showing exemplary process steps of fabricating the light-emitting device of the second invention;

FIG. 7 is a schematic drawing showing a stacked structure of a first embodiment of the light-emitting device according to the third invention;

FIG. 8 is a drawing showing exemplary process steps of fabricating the light-emitting device shown in FIG. 7;

FIG. 9 is a schematic drawing showing a stacked structure of a second embodiment of the light-emitting device according to the third invention;

FIG. 10 is a drawing showing exemplary process steps of fabricating the light-emitting device shown in FIG. 9;

FIG. 11 is a drawing showing modified process steps of fabricating the light-emitting device shown in FIG. 7;

FIG. 12 is a schematic drawing showing a stacked structure of one embodiment of the light-emitting device according to the fourth invention;

FIG. 13 is a drawing showing exemplary process steps of fabricating the light-emitting device of the fourth invention;

FIG. 14 is a drawing for explaining a first modified example of a process step of fabricating the light-emitting device according to the fourth invention, together with an essential portion of the resultant light-emitting device;

FIG. 15 is a drawing for explaining a second modified example of a process step of fabricating the light-emitting device according to the fourth invention, together with an essential portion of the resultant light-emitting device;

FIG. 16 is a drawing for explaining a third modified example of a process step of fabricating the light-emitting device according to the fourth invention, together with an essential portion of the resultant light-emitting device;

FIG. 17 is a drawing for explaining a fourth modified example of a process step of fabricating the light-emitting device according to the fourth invention, together with an essential portion of the resultant light-emitting device;

FIG. 18 is a schematic drawing showing a stacked structure of one modified example of the light-emitting device according to the fourth invention;

FIG. 19 is a drawing showing exemplary process steps of fabricating the light-emitting device shown in FIG. 18;

FIG. 20 is a schematic drawing showing a stacked structure of a first embodiment of the light-emitting device according to the fifth invention;

FIG. 21 is a drawing showing exemplary process steps of fabricating the light-emitting device shown in FIG. 20;

FIG. 22 is a schematic drawing showing a stacked structure of a first embodiment of the light-emitting device according to the sixth invention;

FIG. 23 is a drawing showing exemplary process steps of fabricating the light-emitting device shown in FIG. 22;

FIG. 24 is a schematic drawing showing a stacked structure of a second embodiment of the light-emitting device according to the sixth invention;

FIG. 25 is a schematic drawing showing a stacked structure of a third embodiment of the light-emitting device according to the sixth invention; and

FIG. 26 is a schematic drawing showing a stacked structure of a fourth embodiment of the light-emitting device according to the sixth invention.

### DESCRIPTION OF THE PREFERRED EMBODIMENTS

(First Invention)

The following paragraphs will describe one embodiment of the first invention referring to the attached drawings.

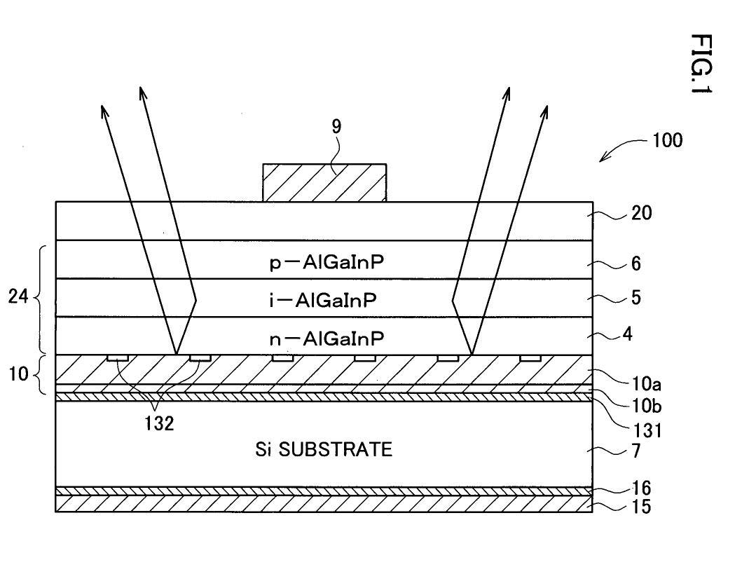

FIG. 1 is a conceptual drawing of a light-emitting device 100 according to one embodiment of the first invention. The light-emitting device 100 comprises a Si substrate 7, which is a conductive device substrate composed of n-type Si (silicon) single crystal, and a light-emitting layer portion 24 bonded on one main surface of the Si substrate 7 while placing an Ag-base reflective metal layer 10 in between.

The light-emitting layer portion 24 is configured so that an active layer 5 composed of a non-doped (AlₓGa₁₋ₓ)_{y}In_{1-y}P (where, 0≦x≦0.55, 0.45≦y≦0.55) alloy is sandwiched by a first-conductivity-type cladding layer, which is a p-type cladding layer 6 composed of p-type (AlₓGa₁₋ₓ)_{y}In_{1-y}P (where, x<z≦1) in this embodiment, and a second-conductivity-type cladding layer different from the first-conductivity-type cladding layer, which is an n-type cladding layer 4 composed of n-type (AlₓGa₁₋ₓ)_{y}In_{1-y}p (where, x<z≦1) in this embodiment, and so as to have an emission wavelength in green to red spectral regions (emission wavelength (peak emission wavelength) of 550 nm to 670 nm) depending on the composition of the active layer 5. In the light-emitting device 100 shown in FIG. 1, the p-type AlGaInP cladding layer 6 is disposed on a metal electrode 9 side, and the n-type AlGaInP cladding layer 4 is disposed on the Ag-base reflective metal layer 10 side. The device thus has positive polarity on the metal electrode 9 side. It is to be noted now that “non-doped” in the context of this patent specification means that “the dopant is not intentionally added”, and is not precluded from being inevitably added with the dopant component during normal fabrication processes (where the upper limit falls in a range from 10¹³ to 10¹⁶/cm³ or around).

The main surface of the light-emitting layer portion 24, which is opposite to the surface facing to the substrate 7, has a current-spreading layer 20 composed of AlGaAs formed thereon, and at around the center of the main surface thereof, a metal electrode (e.g., Au electrode) 9 for supplying emission drive current to the light-emitting layer portion 24 is formed so as to cover a portion of the main surface. The area around the metal electrode 9 on the main surface of the current-spreading layer 20 serves as an extraction area of the light emitted from the light-emitting layer portion 24. On the back surface of the Si single crystal substrate 7, a metal electrode (back electrode, typically composed of Au) 15 is formed so as to cover the entire portion thereof. When the metal electrode 15 is an Au electrode, an AuSb contact layer 16 is interposed between the metal electrode 15 and the Si single crystal substrate 7. It is also allowable to use an AuSn contact layer in place of the AuSb contact layer 16.

The Si single crystal substrate 7 is fabricated by slicing and polishing a Si single crystal ingot, and has a thickness typically within a range from 100 μm to 500 μm. The Si single crystal substrate 7 is bonded to the light-emitting layer portion 24 while placing an Ag-base reflective metal layer 10 in between. Between the Si single crystal substrate 7 and the Ag-base reflective metal layer 10, an AgSb contact layer 131 (typically containing 5% by mass of Sb) is interposed as the substrate-side, Ag-base contact layer. It is also allowable to use an AgSn contact layer in place of the AgSb contact layer 131.

The Ag-base reflective metal layer 10 is composed of a first Ag-base metal layer 10a in contact with the light-emitting layer portion 24 (compound semiconductor layer) and a second Ag-base metal layer 10b in contact with the Si substrate 7, bonded with each other by annealing for diffusion. Between the light-emitting layer portion 24 and the Ag-base reflective metal layer 10, an AgGeNi contact layer 132 (typical composition relates to 15% by mass of Ge, and 10% by mass of Ni) is disposed, contributing reduction in series resistance of the device. The AgGeNi contact layer 132 is formed in a discrete manner on the main surface of the Ag-base reflective metal layer 10, with a ratio of formation area of 1% to 25%, both ends inclusive. As a consequence, the Ag-base reflective metal layer 10, aforementioned AgSb contact layer 131 and the AgGeNi contact layer 132 together compose the Ag-base metal layer, and thus-composed Ag-base metal layer is arranged so as to contact with both of the light-emitting layer portion 24 and the Si substrate 7. In this embodiment, the Ag-base reflective metal layer 10 is composed of pure Ag, or an Ag alloy having a ratio of Ag content of 95% by mass or above.

Light from the light-emitting layer portion 24 can be extracted in a manner such that a component of the light directly emitted towards the light-extraction-surface side is interlaced with a reflected component coming from the Ag-base reflective metal layer 10. The conventional light-emitting device using an Au-base reflective metal layer together with the light-emitting layer portion composed of AlGaInP has been suffering from an increased absorption by the Au-base reflective metal layer when the emission wavelength resides in a range from 550 nm to 670 nm, and has thus been likely to lower the reflectivity. In contrast to this, use of the Ag-base reflective metal layer 10 as in the light-emitting device 100 of this embodiment is successful in preventing the reflectivity from being lowered even when the light-emitting layer portion 24 has the emission wavelength within the above-described range, and in remarkably raise the light extraction efficiency of the device.

The thickness of the Ag-base reflective metal layer 10 is preferably adjusted to 80 nm or above in order to fully secure the reflective effect. Although the upper limit of the thickness is not specifically limited, it is appropriately adjusted so as to keep a reasonable balance with the cost (typically to 1 μm or around) since the reflective effect is saturated.

The following paragraphs will describe a method of fabricating the light-emitting device 100 shown in FIG. 1.

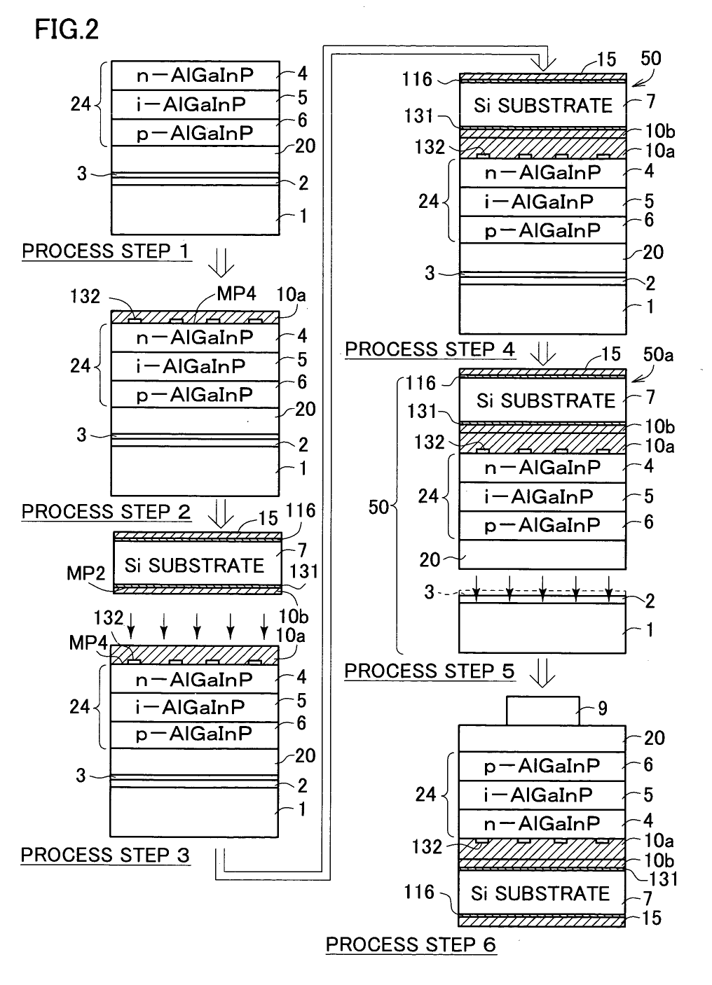

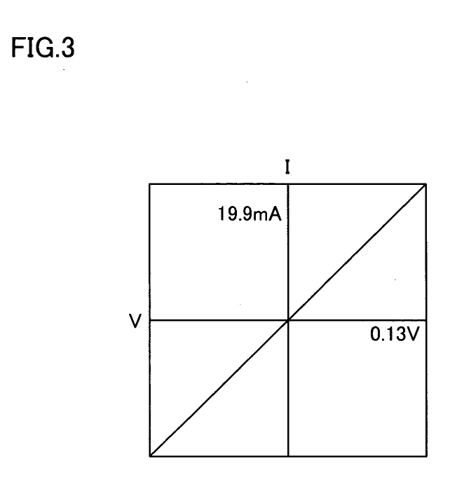

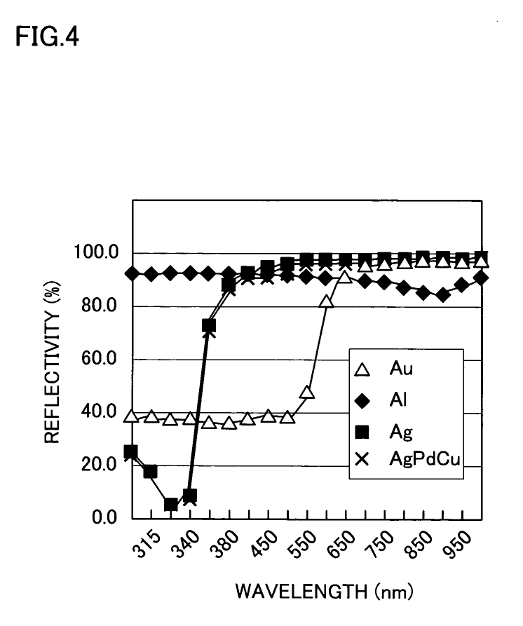

First as shown in process step 1 in FIG. 2, on the main surface of the GaAs single crystal substrate 1 which is a semiconductor single crystal substrate used as the light-emitting-layer-growing substrate, an p-type GaAs buffer layer 2 typically of 0.5 μm thick, a releasing layer 3 composed of AlAs typically of 0.5 μm thick, and the current-spreading layer 20 composed of a p-type AlGaAs typically of 5 μm thick are formed sequentially in this order by epitaxial growth. The light-emitting layer portion 24 is formed further thereon by epitaxially growing the p-type AlGaInP cladding layer 6 of 1 μm thick, the AlGaInP active layer (non-doped) 5 of 0.6 μm thick, and the n-type AlGaInP cladding layer 4 of 1 μm thick in this order.

Next, as shown in process step 2, the AgGeNi contact layer 132 is formed in a discrete manner on the main surface of the light-emitting layer portion 24. After the AgGeNi contact layer 132 is formed, annealing for alloying is carried out in a temperature range from 350° C. to 500° C., and a first Ag-base metal layer 10a is formed so as to cover the AgGeNi contact layer 132. In the annealing for alloying, the light-emitting layer portion 24 and the AgGeNi contact layer 132 are alloyed, to thereby considerably reduce the series resistance. On the other hand, as shown in process step 3, the AgSb contact layers 131, 116 (may be substituted by the AgSn contact layer as described in the above), which are precursors of the substrate-side contact layers, are formed respectively on both main surfaces of the separately-obtained Si single crystal substrate 7 (n-type), and are annealed for alloying in a temperature range from 800° C. to 950° C. Further on the AgSb contact layer 131 and the AgSb contact layer 116, the second Ag-base metal layer 10b and the back electrode layer 15 (typically composed of an Au-base metal) are formed, respectively. In the above process steps, the individual metal layers can typically be formed by sputtering, vacuum evaporation or the like.

Next, as shown in process step 4, the Si single crystal substrate 7 and the light-emitting layer portion 24 are stacked and pressed so as to oppose the second Ag-base metal layer 10b and the first Ag-base metal layer 10a, respectively formed thereon, and then annealed in a temperature range from 100° C. to 840° C., typically at 120° C., so as to produce a substrate stack 50. The Si single crystal substrate 7 is thus bonded to the light-emitting layer portion 24 while placing the first Ag-base metal layer 10a and the second Ag-base metal layer 10b in between. The first Ag-base metal layer 10a and the second Ag-base metal layer 10b herein are united, to thereby produce the Ag-base reflective metal layer 10.

The process then advances to process step 5, where the substrate bond 50 is dipped in an etching solution typically comprising a 10% aqueous hydrofluoric acid solution, so as to selectively etch the AlAs releasing layer 3 formed between the buffer layer 2 and the light-emitting layer portion 24, to thereby separate the GaAs single crystal substrate 1 (opaque to the light from the light-emitting layer portion 24) from the stack 50a which comprises the light-emitting layer portion 24 and the Si single crystal substrate 7 bonded thereto. Another possible process is such that the etching stop layer composed of AlInP is formed in place of the AlAs releasing layer 3, the GaAs single crystal substrate 1 is then etched off together with the GaAs buffer layer 2 using a first etching solution (e.g., ammonia/hydrogen peroxide mixed solution) having an etching selectivity to GaAs, and the etching stop layer is then etched off using a second etching solution (e.g., hydrochloric acid, where addition of hydrofluoric acid for removing Al oxide layer also allowable) having an etching selectivity to AlInP. It is to be understood herein that removal of the entire portion of the light-emitting-layer-growing substrate, as described in the above, is also included in the concept of “separation”.

Next, as shown in process step 6, an electrode 9 for enabling wire bonding (bonding pad: FIG. 1) is formed on the main surface of the current-spreading layer 20, exposed after the separation of the GaAs single crystal substrate 1, so as to cover a part thereof. Thereafter, the dicing is carried out according to the general practice to thereby obtain semiconductor chips, and each chip is then mounted on a support, wire-bonded with lead wires, and molded with a resin to thereby produce a final product form of the light-emitting device.

Although the individual layers (p-type cladding layer 6, active layer 5 and n-type cladding layer 4) composing the light-emitting layer portion 24 in the above-described embodiment were formed using the AlGaInP alloy, it is also allowable to compose these layers using an AlGaInN alloy. In this case, a sapphire substrate (insulating material), or an SiC single crystal substrate, in place of GaAs single crystal substrate, is typically used as the light-emitting-layer-growing substrate on which the light-emitting layer portion 24 is to be grown. This configuration is advantageous in enhancing the improving effect of the reflectivity when the emission wavelength resides in a range from 400 nm to 600 nm, and the Ag-base reflective metal layer 10 is adopted. The above-described embodiment adopts a configuration of the light-emitting layer portion 24 in which the n-type cladding layer 4, the active layer 5 and the p-type cladding layer 6 are stacked in this order as viewed from the substrate side, where it is also allowable to invert this order so as to stack the p-type cladding layer, active layer and the n-type cladding layer in this order as viewed from the substrate side.

(Second Invention)

The following paragraphs will describe embodiments of the second invention referring to the attached drawings.

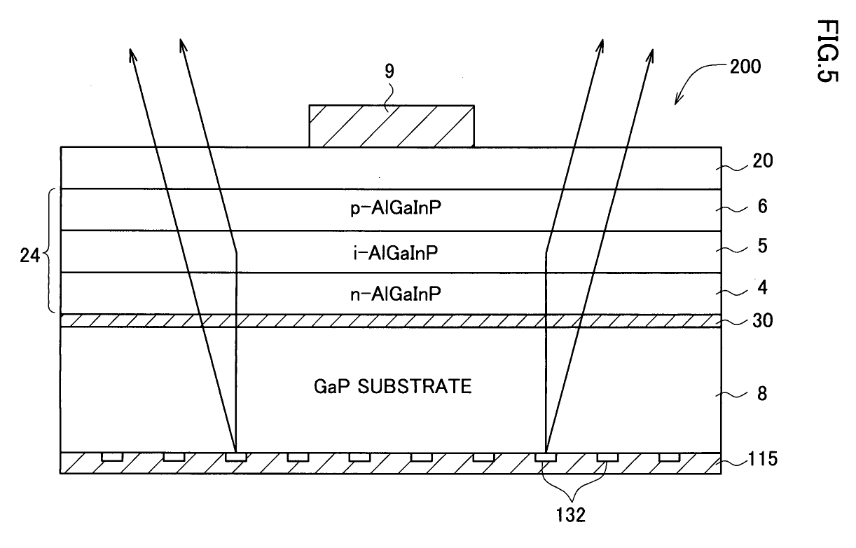

FIG. 5 is a conceptual drawing of a light-emitting device 200 of one embodiment according to the second invention. The light-emitting device 200 comprises a GaP substrate 8, which is composed of n-type GaP single crystal and corresponds to the transparent conductive substrate, and the light-emitting layer portion 24 bonded to the main surface thereof, while placing a transparent conductive layer (typically an ITO (indium-tin oxide) layer) 30 in between.

The GaP substrate 8 is fabricated by slicing and polishing a GaP single crystal ingot, and has a thickness typically within a range from 100 μm to 500 μm. The main back surface of the GaP substrate 8 is covered with an Ag-base reflective metal layer 115 typically composed of an Ag layer. Between the GaP substrate 8 and the Ag-base reflective metal layer 115, an Ag-base contact layer 132 is disposed, contributing reduction in series resistance of the device, where the Ag-base contact layer 132 is produced by alloying between an AgGeNi contact metal (typically containing 15% by mass of Ge and 10% by mass of Ni, where Ag accounts for the residual portion) and the surficial portion of the GaP substrate 8. The Ag-base contact layer 132 configures the ohmic contact structure for the semiconductor device of the second invention together with the Ag-base reflective metal layer 115 composing the electrode layer, and the GaP substrate 8 composing the device body. The AgGeNi contact layer 132 is formed in a discrete manner on the main surface of the Ag-base reflective metal layer 115, in the ratio of formation area thereof between 1% and 25%, both ends inclusive.

The light-emitting layer portion 24 is configured so that an active layer 5 composed of a non-doped (AlₓGa₁₋ₓ)_{y}In_{1-y}P (where, 0≦x≦0.55, 0.45≦y≦0.55) alloy is sandwiched by a first-conductivity-type cladding layer, which is a p-type cladding layer 6 composed of p-type (Al_{z}Ga_{1-z})_{y}In_{1-y}P (where, x<z≦1) in this embodiment, and a second-conductivity-type cladding layer different from the first-conductivity-type cladding layer, which is an n-type cladding layer 4 composed of n-type (Al_{z}Ga_{1-z})_{y}In_{1-y}P (where, x<z≦1) in this embodiment, and so as to have an emission wavelength in green to red spectral regions (emission wavelength (peak emission wavelength) of 550 nm to 670 nm) depending on the composition of the active layer 5, where the peak emission wavelength is adjusted within a range from 550 nm to 580 nm for the case green to yellowish green light emission is desired. In the light-emitting device 200 shown in FIG. 5, the p-type AlGaInP cladding layer 6 is disposed on a metal electrode 9 side, and the n-type AlGaInP cladding layer 4 is disposed on the Ag-base reflective metal layer 115 side. The device thus has positive polarity on the metal electrode 9 side.

On the main surface of the light-emitting layer portion 24, the current-spreading layer 20 composed of AlGaAs is formed, and at around the center of the main surface thereof, the metal electrode (e.g., Au electrode) 9 for supplying emission drive current is formed so as to cover a portion of the main surface. The area around the metal electrode 9 on the main surface of the current-spreading layer 20 serves as an extraction area of the light emitted from the light-emitting layer portion 24. Light from the light-emitting layer portion 24 can be extracted in a manner such that a component of the light directly emitted towards the light-extraction-surface side is interlaced with a reflected component coming from the Ag-base reflective metal layer 115.

The thickness of the Ag-base reflective metal layer 115 is preferably adjusted to 80 nm or above in order to fully secure the reflective effect. Although the upper limit of the thickness is not specifically limited, it is appropriately adjusted so as to keep a reasonable balance with the cost (typically to 1 μm or around).

The following paragraphs will describe a method of fabricating the light-emitting device 200 shown in FIG. 5.

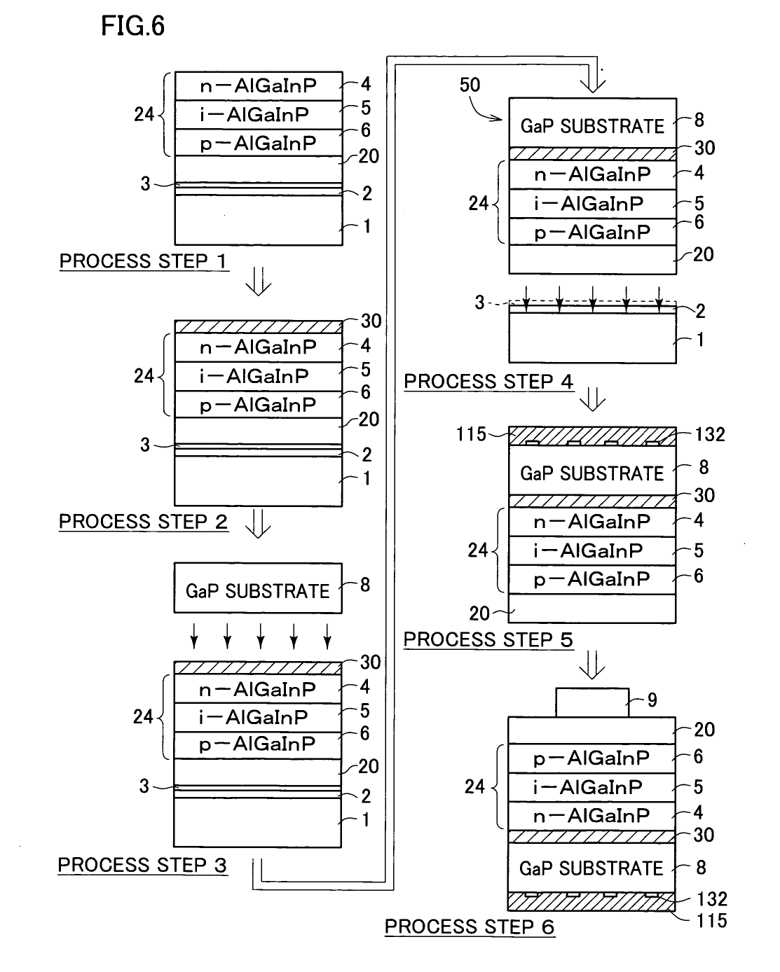

First as shown in process step 1 in FIG. 6, on the main surface of the GaAs single crystal substrate 1 which is a semiconductor single crystal substrate used as the light-emitting-layer-growing substrate, the p-type GaAs buffer layer 2 typically of 0.5 μm thick, the releasing layer 3 composed of AlAs typically of 0.5 μm thick, and the current-spreading layer 20 composed of p-type AlGaAs typically of 5 μm thick are formed sequentially in this order by epitaxial growth. The light-emitting layer portion 24 is formed further thereon by epitaxially growing the p-type AlGaInP cladding layer 6 of 1 μm thick, the AlGaInP active layer (non-doped) 5 of 0.6 μm thick, and the n-type AlGaInP cladding layer 4 of 1 μm thick in this order. Then as shown in process step 2, a transparent conductive layer 30 is formed on the light-emitting-layer portion 24 on the side planned to become the main back surface after the formation thereof.

Next, as shown in process step 3, the separately-obtained GaP substrate 8 and the light-emitting layer portion 24 are stacked and pressed so as to oppose the main surface of the GaP substrate 8 and the transparent conductive layer 30, and then annealed at an appropriate temperature to thereby produce the substrate stack 50. The process then advances to process step 4, where the substrate bond 50 is dipped in an etching solution typically comprising a 10% aqueous hydrofluoric acid solution, so as to selectively etch the AlAs releasing layer 3 formed between the buffer layer 2 and the light-emitting layer portion 24, to thereby separate the GaAs single crystal substrate 1 (opaque to the light from the light-emitting layer portion 24) from the stack 50a which comprises the light-emitting layer portion 24 and the GaP single crystal substrate 8 bonded thereto. Another possible process is such that the etching stop layer composed of AlInP is formed in place of the AlAs releasing layer 3, the GaAs single crystal substrate 1 is then etched off together with the GaAs buffer layer 2 using a first etching solution (e.g., ammonia/hydrogen peroxide mixed solution) having an etching selectivity to GaAs, and the etching stop layer is then etched off using a second etching solution (e.g., hydrochloric acid, where addition of hydrofluoric acid for removing Al oxide layer also allowable) having an etching selectivity to AlInP.

Next, as shown in process step 5, a vacuum-evaporated layer of the AgGeNi contact metal is formed in a discrete manner on the main back surface of the GaP substrate 8, and annealed in a temperature range from 350° C. to 660° C. for alloying, to thereby form the AgGeNi contact layer 132. Thereafter the Ag-base reflective metal layer 115 is formed so as to cover the AgGeNi contact layer 132. The AgGeNi contact layer 132 not only can form a desirable ohmic contact with the GaP substrate 8, but also shows an excellent adhesion property with the Ag-base reflective metal layer 115. In the above process steps, the individual metal layers can typically be formed by sputtering, vacuum evaporation or the like. The annealing for alloying may be carried out after the Ag-base reflective metal layer 115 was formed.

Next, as shown in process step 6, the electrode 9 for enabling wire bonding (bonding pad: FIG. 5) is formed on the main surface of the current-spreading layer 20, exposed after the separation of the GaAs single crystal substrate 1, so as to cover a part thereof. Thereafter, the dicing is carried out according to the general practice to thereby obtain semiconductor chips, and each chip is then mounted on a support, wire-bonded with lead wires, and molded with a resin to thereby produce a final product form of the light-emitting device.

Although the individual layers (p-type cladding layer 6, active layer 5 and n-type cladding layer 4) composing the light-emitting layer portion 24 in the above-described embodiment were formed using the AlGaInP alloy, it is also allowable to compose these layers using an AlGaInN alloy. In this case, a sapphire substrate (insulating material), or an SiC single crystal substrate, in place of GaAs single crystal substrate, is typically used as the light-emitting-layer-growing substrate on which the light-emitting layer portion 24 is to be grown. For the case where the light-emitting layer portion composed of AlGaInN alloy is formed on the sapphire substrate while placing a GaN buffer layer in between, the sapphire substrate can be separated and removed by irradiating excimer laser from the back surface side of the sapphire substrate so as to melt the GaN buffer layer. The configuration using the Ag-base metal layer 115 is advantageous in enhancing the improving effect of the reflectivity of blue-to-green light when the emission wavelength resides of the light-emitting layer portion 24 in a range from 450 nm to 580 nm.

The above-described embodiment adopts a configuration of the light-emitting layer portion 24 in which the n-type cladding layer 4, the active layer 5 and the p-type cladding layer 6 are stacked in this order as viewed from the substrate side, where it is also allowable to invert this order so as to stack the p-type cladding layer, active layer and the n-type cladding layer in this order as viewed from the substrate side.

(Third Invention)

The following paragraphs will describe the third invention referring to the attached drawings.

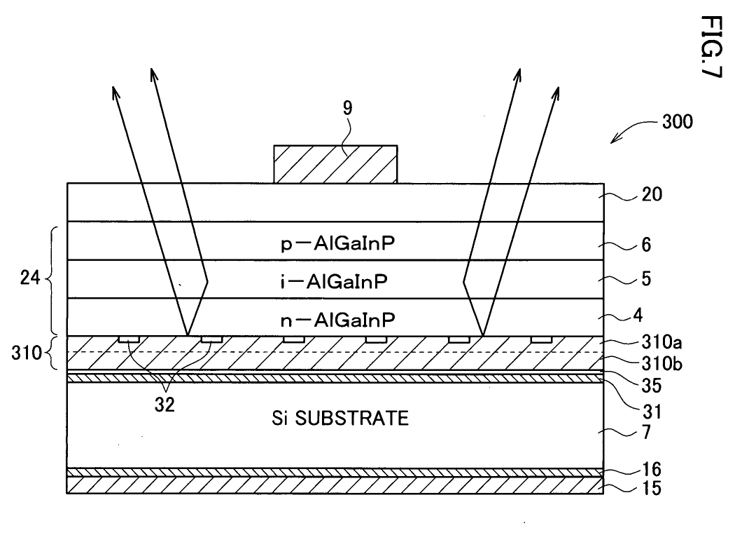

FIG. 7 is a conceptual drawing of a light-emitting device 300 according to one embodiment of the third invention. The light-emitting device 300 comprises the Si substrate 7, which is a conductive device substrate composed of n-type Si (silicon) single crystal, and a light-emitting layer portion 24 bonded on one main surface of the Si substrate 7 while placing a main metal layer 310 in between.

The light-emitting layer portion 24 is configured so that the active layer 5 composed of a non-doped (AlₓGa₁₋ₓ)_{y}In_{1-y}P (where, 0≦x≦0.55, 0.45≦y≦0.55) alloy is sandwiched by a first-conductivity-type cladding layer, which is the p-type cladding layer 6 composed of p-type (AlₓGa₁₋ₓ)_{y}In_{1-y}P (where, x<z≦1) in this embodiment, and the second-conductivity-type cladding layer different from the first-conductivity-type cladding layer, which is the n-type cladding layer 4 composed of n-type (AlₓGa₁₋ₓ)_{y}In_{1-y}P (where, x<z≦1) in this embodiment, and so as to have an emission wavelength in green to red spectral regions (emission wavelength (peak emission wavelength) of 550 nm to 670 nm) depending on the composition of the active layer 5. In the light-emitting device 300, the p-type AlGaInP cladding layer 6 is disposed on the metal electrode 9 side, and the n-type AlGaInP cladding layer 4 is disposed on the main metal layer 310 side. The device thus has positive polarity on the metal electrode 9 side.

The main surface of the light-emitting layer portion 24, which is opposite to the surface facing to the substrate 7, has the current-spreading layer 20 composed of AlGaAs formed thereon, and at around the center of the main surface thereof, the metal electrode (e.g., Au electrode) 9 for supplying emission drive current to the light-emitting layer portion 24 is formed so as to cover a portion of the main surface. The area around the metal electrode 9 on the main surface of the current-spreading layer 20 serves as an extraction area of the light emitted from the light-emitting layer portion 24. On the back surface of the Si single crystal substrate 7, the metal electrode (back electrode, typically composed of Au) 15 is formed so as to cover the entire portion thereof. When the metal electrode 15 is an Au electrode, the AuSb contact metal layer 16 is interposed between the metal electrode 15 and the Si single crystal substrate 7. It is also allowable to use an AuSn contact metal layer as the substrate-side contact metal layer in place of the AuSb contact metal layer 16.

The Si single crystal substrate 7 is fabricated by slicing and polishing a Si single crystal ingot, and has a thickness typically within a range from 100 μm to 500 μm. The Si single crystal substrate 7 is bonded to the light-emitting layer portion 24 while placing the main metal layer 310 in between. The main metal layer 310 is configured as an Au-base layer over the entire portion thereof.

Between the light-emitting layer portion 24 and the main metal layer 310, an AuGeNi contact metal layer 32 (typical composition relates to 15% by mass of Ge, and 10% by mass of Ni) is disposed as the light-emitting-layer-portion side contact metal layer, contributing reduction in series resistance of the device. The AuGeNi contact metal layer 32 is formed in a discrete manner on the main surface of the main metal layer 310, with a ratio of formation area of 1% to 25%, both ends inclusive. On the other hand, between the Si single crystal substrate 7 and the main metal layer 310, an AuSb contact metal layer 31 (typically containing 5% by mass of Sb) is interposed as the substrate-side contact metal layer, so as to contact with the first main surface of the Si single crystal substrate 7. It is also allowable to use an AuSn contact metal layer in place of the AuSb contact metal layer 31.

The entire surface of the AuSb contact metal layer 31 is covered with a Ti (titanium) layer 35 as the diffusion-blocking layer. The thickness of the Ti layer 35 falls within a range from 1 nm and 10 μm (600 nm in this embodiment). The diffusion-blocking layer herein may be configured by an Ni layer, in place of the Ti layer. The main metal layer 310 (Au-base layer) is formed so as to cover the entire surface of the Ti layer 35, and so as to contact therewith. In this embodiment, the Au-base layer is composed of pure Au, or an Au alloy having a ratio of Au content ratio of 95% by mass or above.

Light from the light-emitting layer portion 24 can be extracted in a manner such that a component of the light directly emitted towards the light-extraction-surface side is interlaced with a reflected component coming from the main metal layer 310. The thickness of the main metal layer 310 is preferably adjusted to 80 nm or above in order to fully secure the reflective effect. Although the upper limit of the thickness is not specifically limited, it is appropriately adjusted so as to keep a reasonable balance with the cost (typically to 1 μm or around).

The following paragraphs will describe a method of fabricating the light-emitting device 300 shown in FIG. 7.

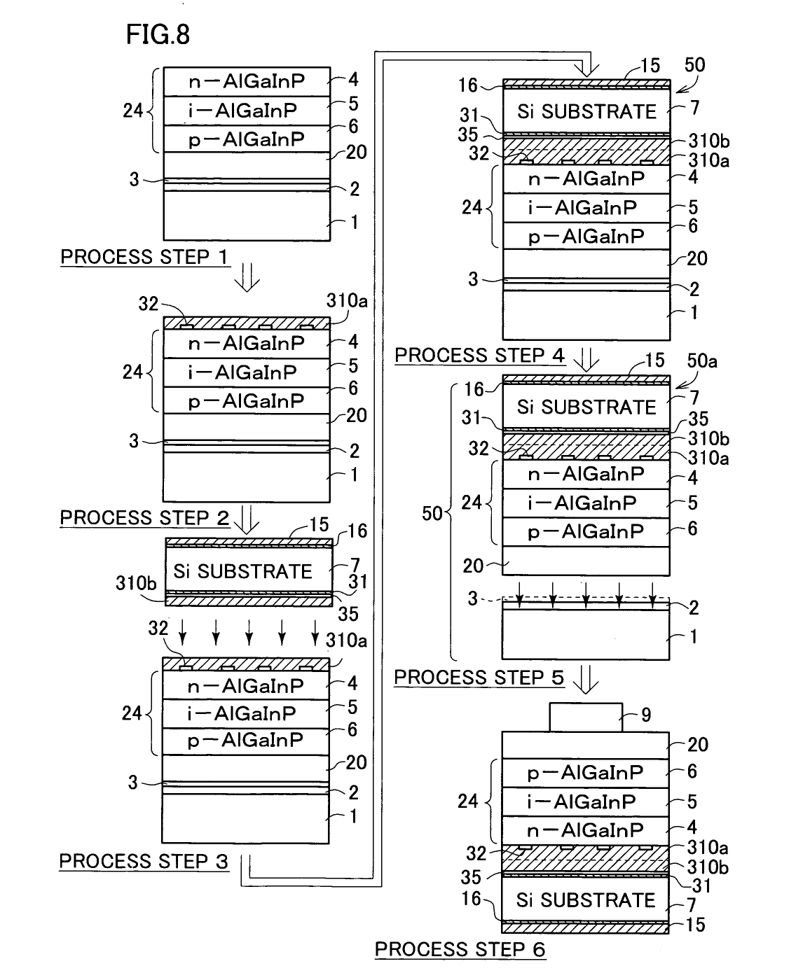

First as shown in process step 1 in FIG. 8, on the main surface of the GaAs single crystal substrate 1 which is a semiconductor single crystal substrate used as the light-emitting-layer-growing substrate, the p-type GaAs buffer layer 2 typically of 0.5 μm thick, the releasing layer 3 composed of AlAs typically of 0.5 μm thick, and the current-spreading layer 20 composed of p-type AlGaAs typically of 5 μm thick are formed sequentially in this order by epitaxial growth. The light-emitting layer portion 24 is formed further thereon by epitaxially growing the p-type AlGaInP cladding layer 6 of 1 μm thick, the AlGaInP active layer (non-doped) 5 of 0.6 μm thick, and the n-type AlGaInP cladding layer 4 of 1 μm thick in this order.

Next, as shown in process step 2, the AuGeNi contact metal layer 32 is formed in a discrete manner on the main surface of the light-emitting layer portion 24. After the AuGeNi contact metal layer 32 is formed, annealing for alloying is carried out in a temperature range from 350° C. to 500° C. A first Au-base layer 310a is formed so as to cover the AuGeNi contact metal layer 32. By the annealing for alloying, an alloyed layer is formed between the light-emitting layer portion 24 and the AuGeNi contact metal layer 32, and this contributes to a considerable reduction in the series resistance. On the other hand, as shown in process step 3, the AuSb contact layers 31, 16 (may be substituted by the AuSn contact layer as described in the above), which are precursors of the substrate-side contact metal layers, are formed respectively on both main surfaces of the separately-obtained Si single crystal substrate 7 (n-type), and are annealed for alloying in a temperature range from 100° C. to 500° C. Further on the AuSb contact layer 31, the Ti layer 35 (typically of 600-nm thick) and the second Au-base layer 310b are formed in this order. On the AuSb contact metal layer 16, the back electrode layer 15 (typically composed of an Au-base metal) is formed. In the above process steps, the individual metal layers can typically be formed by sputtering, vacuum evaporation or the like.

Next, as shown in process step 4, the Si single crystal substrate 7 and the light-emitting layer portion 24 are stacked and pressed so as to oppose the second Au-base metal layer 310b and the first Au-base metal layer 310a, respectively formed thereon, and then annealed in a temperature range from 80° C. to 500° C., typically at 200° C., so as to produce the substrate stack 50. The Si single crystal substrate 7 is thus bonded to the light-emitting layer portion 24 while placing the first Au-base metal layer 310a and the second Au-base metal layer 310b in between. The first Au-base metal layer 310a and the second Au-base metal layer 310b are united by the annealing for bonding, to thereby produce the main metal layer 310. Because both of the first Au-base metal layer 310a and the second Au-base metal layer 310b are composed of Au less likely to be oxidized, the annealing for bonding can be carried out in the air without problems.

Further between the second Au-base metal layer 310b and the Si single crystal substrate 7 (AuSb contact metal layer 31), a Ti layer 35 which functions as the diffusion-blocking layer is interposed. The Ti layer 35 is successful in blocking the diffusion of the Si component from the Si single crystal substrate 7 towards the second Au-base layer 310b during the annealing for bonding, and this also effectively blocks the dripping of the Si component into the second Au-base layer 310b or further into the side of the main metal layer 310 obtained by the bonding in an united form. This successfully suppresses nonconformities such that the reflective surface of the finally-obtained main metal layer 310 (Au-base layer) is disturbed by the Au-Si eutectic reaction, or such that the Au-base layer per se is colored in black due to the Si component, and realizes a desirable reflectivity. This is also advantageous in keeping a large bonding strength of the main metal layer 310 between the Si single crystal substrate 7 and the light-emitting layer portion (compound semiconductor layer) 24.

The process then advances to process step 5, where the substrate bond 50 is dipped in an etching solution typically comprising a 10% aqueous hydrofluoric acid solution, so as to selectively etch the AlAs releasing layer 3 formed between the buffer layer 2 and the light-emitting layer portion 24, to thereby separate the GaAs single crystal substrate 1 (opaque to the light from the light-emitting layer portion 24) from the stack 50a which comprises the light-emitting layer portion 24 and the Si single crystal substrate 7 bonded thereto. Another possible process is such that the etching stop layer composed of AlInP is formed in place of the AlAs releasing layer 3, the GaAs single crystal substrate 1 is then etched off together with the GaAs buffer layer 2 using a first etching solution (e.g., ammonia/hydrogen peroxide mixed solution) having an etching selectivity to GaAs, and the etching stop layer is then etched off using a second etching solution (e.g., hydrochloric acid, where addition of hydrofluoric acid for removing Al oxide layer also allowable) having an etching selectivity to AlInP.

Next, as shown in process step 6, the electrode 9 for enabling wire bonding (bonding pad: FIG. 7) is formed on the main surface of the current-spreading layer 20, exposed after the separation of the GaAs single crystal substrate 1, so as to cover a part thereof. Thereafter, the dicing is carried out according to the general practice to thereby obtain semiconductor chips, and each chip is then mounted on a support, wire-bonded with lead wires, and molded with a resin to thereby produce a final product form of the light-emitting device.

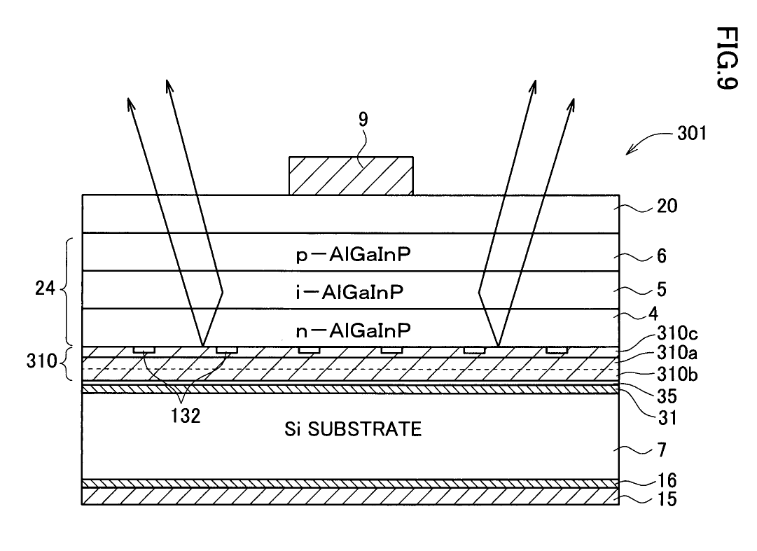

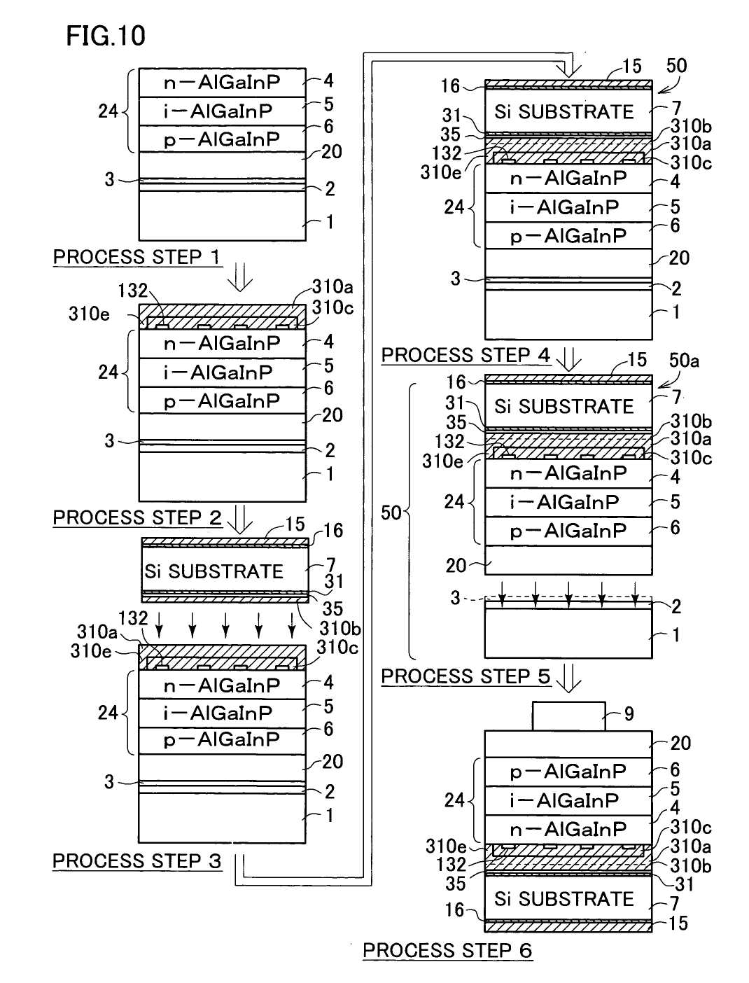

Although the reflective surface was formed by the first Au-based layer 310a in the above embodiment, it is also allowable, as shown in FIG. 9, to dispose Ag-base layer 310c between the first Au-base layer 310a and the light-emitting layer portion 24. The light-emitting-layer-side contact metal layer in this case is configured by the Ag-base contact metal layer 132 composed of AgGeNi (typically containing 15% by mass of Ge and 10% by mass of Ni) and formed in a discrete manner, in place of the Au-base contact metal layer. All other portions are similar to those of the light-emitting device 300 shown in FIG. 7. FIG. 10 shows exemplary process steps of fabricating the light-emitting device 300. The fabrication process differs from those shown in FIG. 8, in that the Ag-base contact metal layer 132 is formed in a discrete manner in process step 2, in place of Au-base contact metal layer 32, that the annealing for alloying is carried out within a temperature range from 350° C. to 660° C., both ends inclusive, and that the Ag-base layer 310c and the first Au-base layer 310a are formed thereafter in this order. All other processes are basically the same as those shown in FIG. 8.

For the case where it is anticipated that the Ag-base layer 310c may be corroded by the etching solution during the etching for separating (removing) the light-emitting-layer-growing substrate, the method described below will be recommendable. As shown in process step 2, the first Au-base layer 310a in contact with the Ag-base layer 310c is formed so that the outer periphery of the first Au-base layer 310a completely surrounds the outer periphery of the Ag-base layer 310c, and so that the first Au-base layer 310a has a larger area than the Ag-base layer 310c has. In this configuration, the Ag-base layer 310c is formed so as to be covered by the first Au-base layer 310a so that the outer peripheral surface of the Ag-base layer 310c is protected by the outer circumferential portion 310e of the first Au-base layer 310a having a higher corrosion resistance, and this makes the Ag-base layer 310c less likely to be adversely affected by the etching of the light-emitting-layer-growing substrate (GaAs single crystal substrate 1) in process step 5. Ag has been very likely to be corroded particularly when the GaAs single crystal substrate 1 was used as the light-emitting-layer-growing substrate and was later dissolved and removed using an ammonia/hydrogen peroxide mixed solution as the etching solution, the above-described configuration makes it possible to dissolve and remove the GaAs single crystal substrate 1 without problems.

It is also allowable to compose the individual layers composing the light-emitting layer portion 24 using an AlGaInN alloy. In this case, a sapphire substrate (insulating material), or an SiC single crystal substrate, in place of GaAs single crystal substrate, is typically used as the light-emitting-layer-growing substrate on which the light-emitting layer portion 24 is to be grown. Although the light-emitting layer portion 24 in the above-described embodiment was configured so that the n-type cladding layer 4, the active layer 5 and the p-type cladding layer 6 are stacked in this order as viewed from the substrate side, where it is also allowable to invert this order so as to stack the p-type cladding layer, active layer and the n-type cladding layer in this order as viewed from the substrate side.

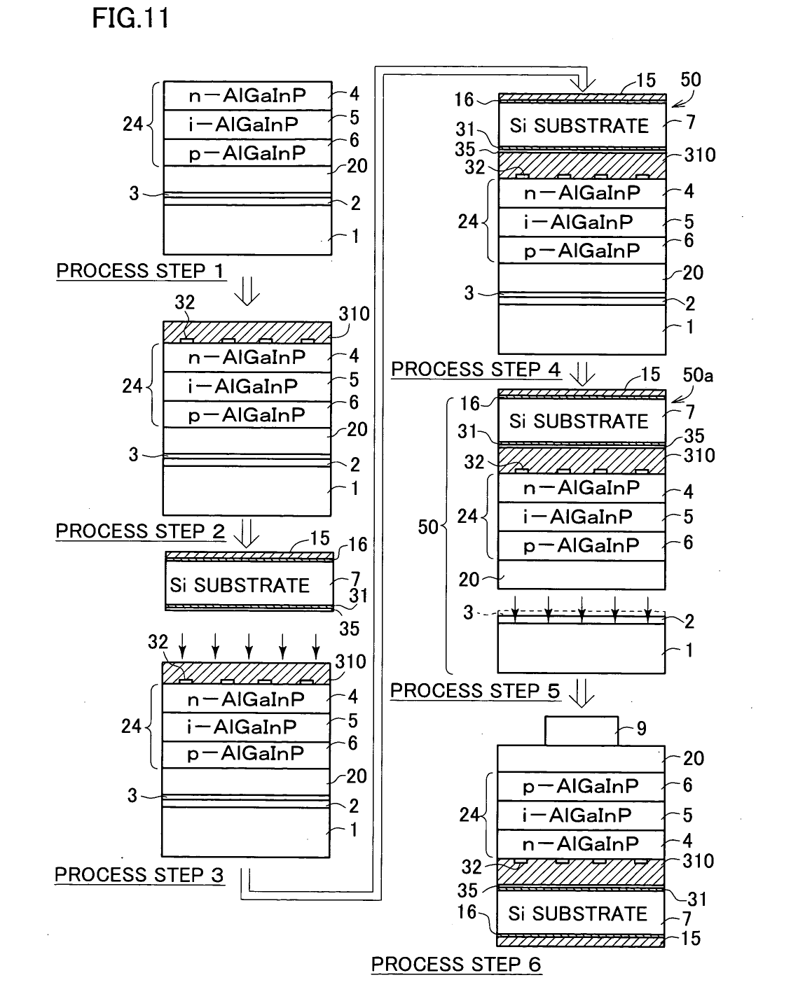

It is also allowable, as shown in FIG. 11 (process step 3), that the Si single crystal substrate (device substrate) 7 and the light-emitting layer portion (compound semiconductor layer) 24 can be bonded after forming the Au-base layer (main metal layer) 310 only on either side of them (FIG. 11 exemplifies the Si single crystal substrate 7 side). The temperature of the bonding for annealing (process step 4) in this case is necessarily be adjusted to 200° C. to 700° C., which is slightly higher than that in the process shown in FIG. 8, where the bonding can be completed without problems by disposing the Ti layer (or Ni layer) 35 as the diffusion-blocking layer so as to fully suppress the Si diffusion towards the Au-base layer (main metal layer) 310.

(Fourth Invention)

The following paragraphs will describe the fourth invention referring to the attached drawings.

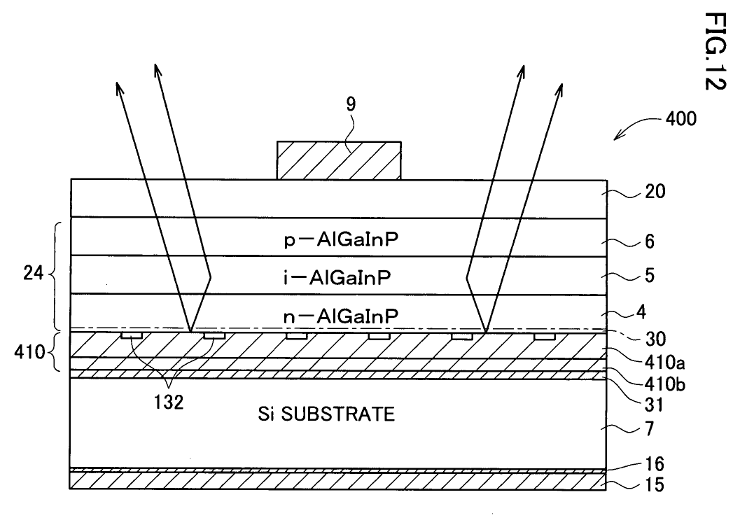

FIG. 12 is a conceptual drawing of a light-emitting device 400 according to one embodiment of the fourth invention. The light-emitting device 400 comprises the Si substrate 7, which is a conductive device substrate composed of n-type Si (silicon) single crystal, and the light-emitting layer portion 24 bonded on one main surface of the Si substrate 7 while placing a metal layer 410 in between.

The light-emitting layer portion 24 is configured so that the active layer 5 composed of a non-doped (AlₓGa₁₋ₓ)_{y}In_{1-y}P (where, 0≦x≦0.55, 0.45≦y≦0.55) alloy is sandwiched by the first-conductivity-type cladding layer, which is the p-type cladding layer 6 composed of p-type (AlₓGa₁₋ₓ)_{y}In_{1-y}P (where, x<z≦1) in this embodiment, and the second-conductivity-type cladding layer different from the first-conductivity-type cladding layer, which is the n-type cladding layer 4 composed of n-type (Al_{z}Ga_{1-z})_{y}In_{1-y}P (where, x<z≦1) in this embodiment, and so as to have an emission wavelength in green to red spectral regions (emission wavelength (peak emission wavelength) of 550 nm to 670 nm) depending on the composition of the active layer 5. In the light-emitting device 400 shown in FIG. 12, the p-type AlGaInP cladding layer 6 is disposed on the metal electrode 9 side, and the n-type AlGaInP cladding layer 4 is disposed on the metal layer 410 side. The device thus has positive polarity on the metal electrode 9 side.

The main surface of the light-emitting layer portion 24, which is opposite to the surface facing to the substrate 7, has the current-spreading layer 20 composed of AlGaAs formed thereon, and at around the center of the main surface thereof, the metal electrode (e.g., Au electrode) 9 for supplying emission drive current to the light-emitting layer portion 24 is formed so as to cover a portion of the main surface. The area around the metal electrode 9 on the main surface of the current-spreading layer 20 serves as an extraction area of the light emitted from the light-emitting layer portion 24. On the back surface of the Si single crystal substrate 7, the AuSb contact layer 16 as the Au-base contact layer is formed so as to cover the entire surface thereof, and further in contact therewith the metal electrode (back electrode) 15 is formed.

The Si single crystal substrate 7 is fabricated by slicing and polishing a Si single crystal ingot, and has a thickness typically within a range from 100 μm to 500 μm. The Si single crystal substrate 7 is bonded to the light-emitting layer portion 24 while placing the metal layer 410 in between.

The metal layer 410 comprises a reflective metal layer 410a on the light-emitting-layer-portion 24 side, and a contact metal layer 410b on the Si-substrate 7 side, where the reflective metal layer 410a and the contact metal layer 410b contact with each other. The reflective metal layer 410a comprises an Ag layer (referred to as Ag-base reflective metal layer 410a, hereinafter), and the contact metal layer 410b comprises an Au layer (referred to as Au-base contact metal layer 410b, hereinafter). Between the light-emitting layer portion 24 and the Ag-base reflective metal layer 410a, the AgGeNi contact layer 132 is formed as the Ag-base contact layer (where, AuGeNi contact layer as the Au-base contact layer also allowable), contributing reduction in series resistance of the device. The AgGeNi contact layer 132 is formed in a discrete manner on the main surface of the Ag-base reflective metal layer 410a, in the ratio of formation area thereof between 1% and 25%, both ends inclusive. Between the Si substrate 7 and the Au-base contact metal layer 410b, the AuSb contact layer 31, which is the Au-base contact layer, is formed.

Light from the light-emitting layer portion 24 can be extracted in a manner such that a component of the light directly emitted towards the light-extraction-surface side is interlaced with a reflected component coming from the Ag-base reflective metal layer 410a. The conventional light-emitting device using an Au-base reflective metal layer together with the light-emitting layer portion composed of AlGaInP has been suffering from an increased absorption by the Au-base reflective metal layer when the emission wavelength resides in a range from 550 nm to 600 nm, particularly in a green-light range up to 580 nm, and has thus been likely to lower the reflectivity. In contrast to this, use of the Ag-base reflective metal layer 410a as in the light-emitting device 400 of this embodiment is successful in preventing the reflectivity from being lowered even when the light-emitting layer portion 24 has the emission wavelength within the above-described range, and in remarkably raise the light extraction efficiency of the device.

The thickness of the Ag-base reflective metal layer 410a is preferably adjusted to 80 nm or above in order to fully secure the reflective effect. Although the upper limit of the thickness is not specifically limited, it is appropriately adjusted so as to keep a reasonable balance with the cost (typically to 1 μm or around).

The following paragraphs will describe a method of fabricating the light-emitting device 400 shown in FIG. 12.

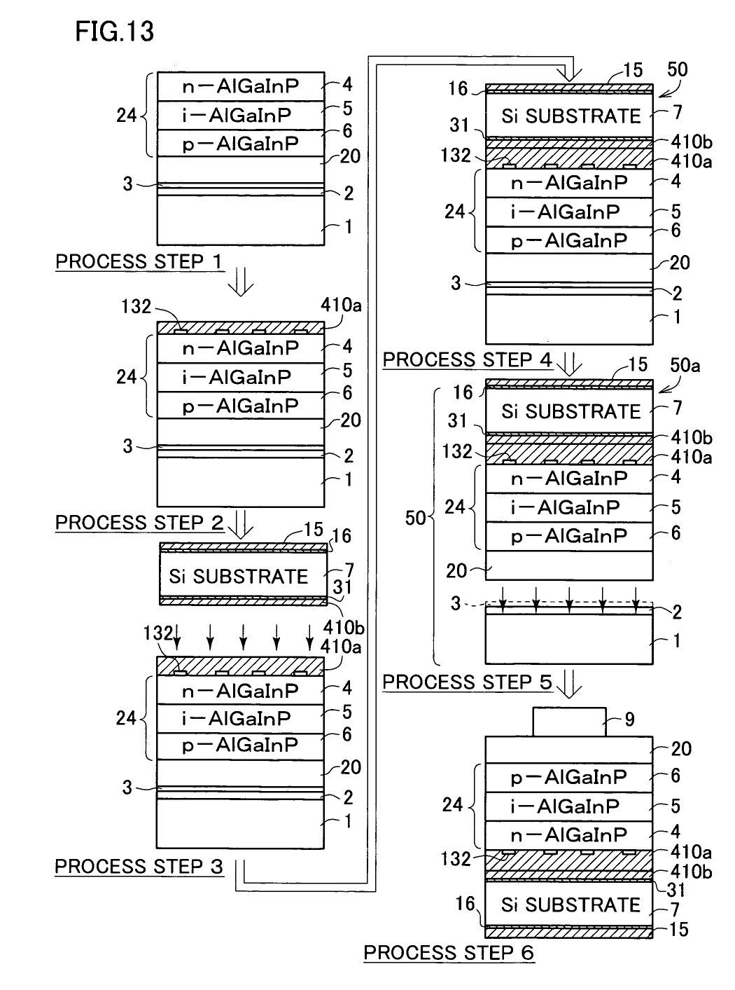

First as shown in process step 1 in FIG. 13, on the main surface of the GaAs single crystal substrate 1 which is a semiconductor single crystal substrate used as the light-emitting-layer-growing substrate, the p-type GaAs buffer layer 2 typically of 0.5 μm thick, the releasing layer 3 composed of AlAs typically of 0.5 μm thick, and the current-spreading layer 20 composed of p-type AlGaAs typically of 5 μm thick are formed sequentially in this order by epitaxial growth. The light-emitting layer portion 24 is formed further thereon by epitaxially growing the p-type AlGaInP cladding layer 6 of 1 μm thick, the AlGaInP active layer (non-doped) 5 of 0.6 μm thick, and the n-type AlGaInP cladding layer 4 of 1 μm thick in this order.

Next, as shown in process step 2, the AgGeNi contact layer 132 is formed in a discrete manner on the main surface of the light-emitting layer portion 24. After the AgGeNi contact layer 132 is formed, sintering is carried out in a temperature range from 350° C. to 500° C. The Ag-base reflective metal layer 410a is formed so as to cover the AgGeNi contact layer 132. By the sintering, an alloyed layer is formed between the light-emitting layer portion 24 and the AgGeNi contact layer 132, where this means formation of ohmic contact, and contributes to a considerable reduction in the series resistance. On the other hand, as shown in process step 3, the AuSb contact layers 31, 16 are formed respectively on both main surfaces of the separately-obtained Si single crystal substrate 7 (n-type), and are sintered in a temperature range from 250° C. to 500° C. Further on the AuSb contact layer 31, the Au-base contact metal layer 410b is formed, and on the AuSb contact metal layer 16, the back electrode layer 15 (typically composed of an Au-base metal) is formed. In the above process steps, the individual metal layers can typically be formed by sputtering, vacuum evaporation or the like. For the case where the Si single crystal substrate used herein has a surface highly doped with an impurity (e.g., Sb), the ohmic contact can be formed without specifically carrying out the sintering, if Au or an Au alloy containing the above-described impurity (e.g., AuSb) is deposited on the surface of the substrate by vacuum evaporation.

Next, as shown in process step 4, the Si single crystal substrate 7 and the light-emitting layer portion 24 are stacked and pressed so as to oppose the Au-base contact metal layer 410b and the Ag-base reflective metal layer 410a, respectively formed thereon, and then annealed so as to produce the substrate stack 50. The Si single crystal substrate 7 is thus bonded to the light-emitting layer portion 24 while placing the Ag-base reflective metal layer 410a and the Au-base contact metal layer 410b in between.

In the above-described bonding step, a three-dimensional eutectic reaction among Au in the Au-base contact metal layer 410b, Ag in the Ag-base reflective metal layer 410a and Si in the Si substrate involves in the annealing. Too high annealing temperature or too thin Ag-base metal reflective layer 410a may excessively produce the eutectic liquid phase, and the eutectic reaction may proceed in the most part of the Ag-base reflective layer 410a to thereby makes it impossible to obtain a desirable reflective surface. In order to avoid the problem, the temperature of the annealing for bonding is preferably adjusted within a range from 50° C. to 360° C. The temperature exceeding 360° C. may result in an excessive formation of the eutectic liquid phase, and may be unsuccessful in obtaining a desirable reflective surface, whereas the temperature less than 50° C. may result in an insufficient bonding strength. To suppress the excessive formation of the eutectic liquid phase, it is preferable to set the thickness of the Au-base contact metal layer 410b smaller (e.g., 1/5 or less) than that of the Ag-base reflective metal layer 410a. In view of obtaining a more reliable bonding strength, the temperature of annealing for bonding is preferably higher than 180° C. but not higher than 360° C.

The process then advances to process step 5, where the substrate bond 50 is dipped in an etching solution typically comprising a 10% aqueous hydrofluoric acid solution, so as to selectively etch the AlAs releasing layer 3 formed between the buffer layer 2 and the light-emitting layer portion 24, to thereby separate the GaAs single crystal substrate 1 (opaque to the light from the light-emitting layer portion 24) from the stack 50a which comprises the light-emitting layer portion 24 and the Si single crystal substrate 7 bonded thereto.

Next, as shown in process step 6, the electrode 9 for enabling wire bonding (bonding pad: FIG. 12) is formed on the main surface of the current-spreading layer 20, exposed after the separation of the GaAs single crystal substrate 1, so as to cover a part thereof. Thereafter, the dicing is carried out according to the general practice to thereby obtain semiconductor chips, and each chip is then mounted on a support, wire-bonded with lead wires, and molded with a resin to thereby produce a final product form of the light-emitting device.

The following paragraphs will describe several modified examples of the fourth invention.

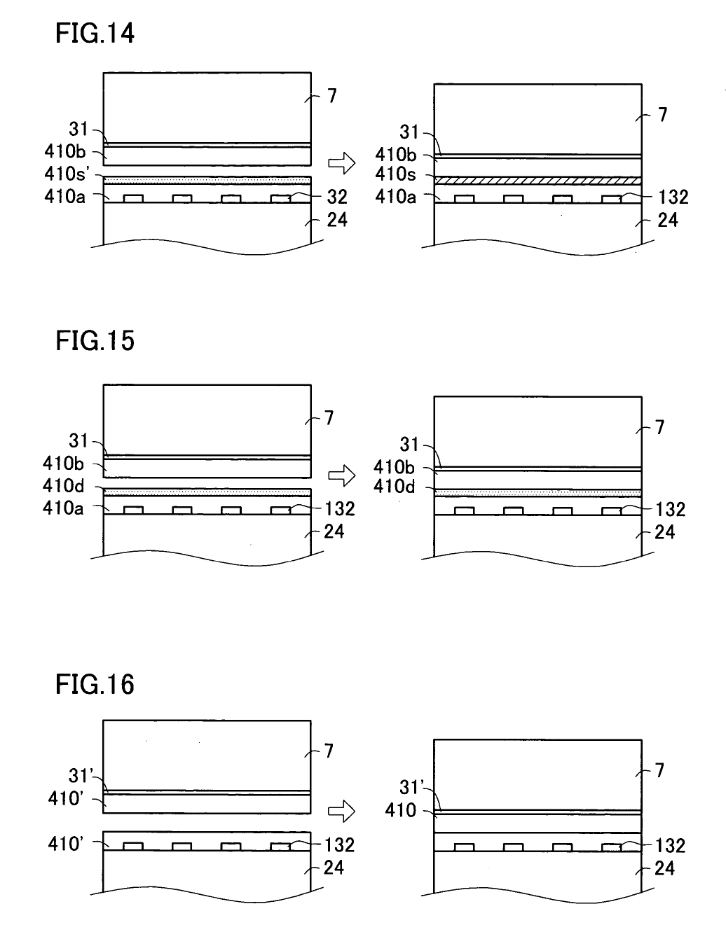

The reflective metal layer 410a (herein an Ag layer) and the contact metal layer 410b (herein an Au layer) can be bonded while placing a braze layer 410s in between, as shown in FIG. 14, rather than bonded directly. The bonding in this case is accomplished by stacking the reflective metal layer 410a and the contact metal layer 410b while placing a braze paste (or braze foil) layer 410s' in between, and by subjecting the stack to annealing for brazing. The braze used herein is a solder, such as of Sn-base or of Sn-Pb-base, having a liquidus temperature of 363° C. or lower. The annealing for brazing carried out at this temperature or lower is successful in bonding the reflective metal layer 410a and the contact metal layer 410b while avoiding the Au—Si eutectic reaction. It is also allowable, as shown in FIG. 15, to bond the reflective metal layer 410a and the contact metal layer 410b while placing a conductive adhesive layer 410d (e.g., such as being formed by coating a conductive adhesive in which a polymer material, a solvent and a conductive powder such as an Ag powder are blended by dispersion) in between. In either case, it is also allowable to form the contact metal layer 410b as an Ag-base metal layer, rather than as an Au layer.

It is still also allowable, as shown in FIG. 16, to form Ag-base metal layers (Ag layers, for example) 410′, 410′ on both of the substrate 7 and the light-emitting layer portion 24, and to directly bond the both by annealing for diffusion. A contact layer 31′ on the substrate 7 side can typically be composed of AgSb. These two Ag-base metal layers in this case unite with each other to thereby produce the metal layer 410 having entire portion of which being composed of the Ag-base reflective metal layer. For the case where the Si substrate is used, the annealing is preferably carried out at a temperature not higher than the Ag—Si eutectic temperature (840° C.), and typically in the same temperature range (250° C. to 500° C.) with that for the annealing for forming the aforementioned alloyed layer. It has been necessary in the conventional process using the Au-base metal layer, rather than the Ag-base metal layer 410′, to carry out the sintering for converting the contact layer 132 shown in FIG. 16 into the alloyed layer, before the Au-base metal layer is formed because the Au—Si eutectic temperature is relatively low. Whereas the use of the Ag-base metal layer 410′ makes it possible to carry out the sintering to a satisfactory degree even after the Ag-base metal layer 410′ is formed, because the Ag—Si eutectic temperature is relatively high. It is still also possible to carry out the annealing for bonding of two Ag-base metal layers 410′, 410′ also as the annealing for sintering.

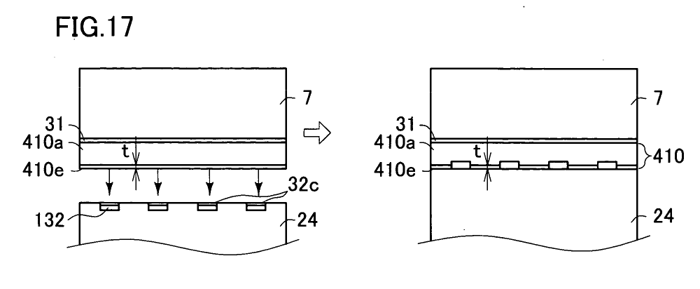

It is still also allowable, as shown in FIG. 17, to bond the Ag-base reflective metal layer 410a with the light-emitting layer portion 24 while placing a protective metal layer 410e in contact with the Ag-base reflective metal layer 410a in between. More specifically, the AgGeNi contact layer 132 is formed on the light-emitting-layer-portion 24 side, and on the other hand, the Ag-base reflective metal layer 410a and the protective metal layer 410e composed of an Au layer are formed in this order on the main surface of the substrate 7. The Ag-base reflective metal layer 410a covered with the protective metal layer 410e is then stacked on the main surface of the light-emitting layer portion 24, and is annealed so as to bond them. For the case where the Si substrate is used, the annealing is preferably carried out at a temperature not higher than the Ag—Si eutectic temperature (840° C.), and may be function as the annealing for forming the alloyed layer using the AgGeNi contact layer 132. If the thickness t of the protective metal layer 410e is limited to as thin as 0.5 nm to 15 nm, the light from the light-emitting layer portion 24 can be reflected by the Ag-base reflective metal layer 410a with a desirable reflectivity despite the interposition of the protective metal layer 410e, causing only a small influence of the absorption by the protective metal layer 410. An extra-thin Au layer 32c, formed as thin as 1 nm to 10 nm on the AgGeNi contact layer 132, successfully raises the bonding strength with the Au-base protective metal layer 410e.

It is also allowable, as indicated by a dashed line shown in FIG. 12, to bond the reflective metal layer 410a and the light-emitting layer portion 24 while placing the transparent conductive oxide layer (e.g., ITO (indium tin oxide) layer) 30 in between. The AgGeNi contact layer 132 in this case can be omissible.

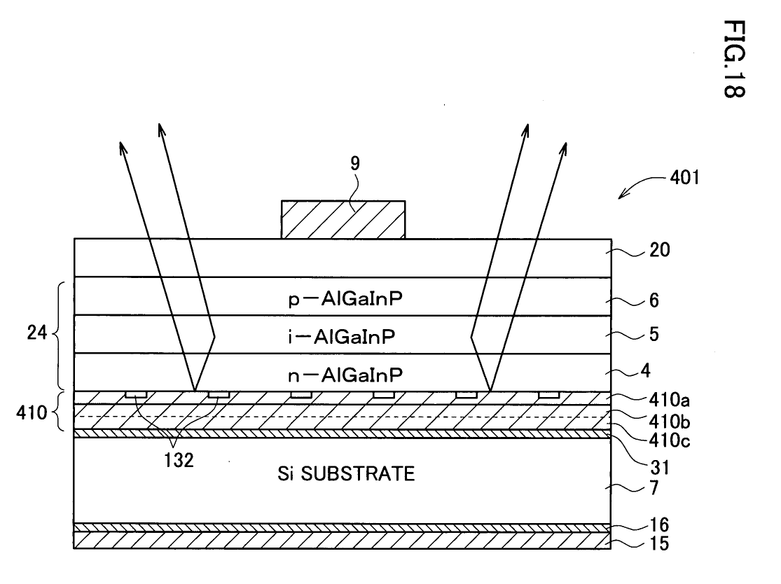

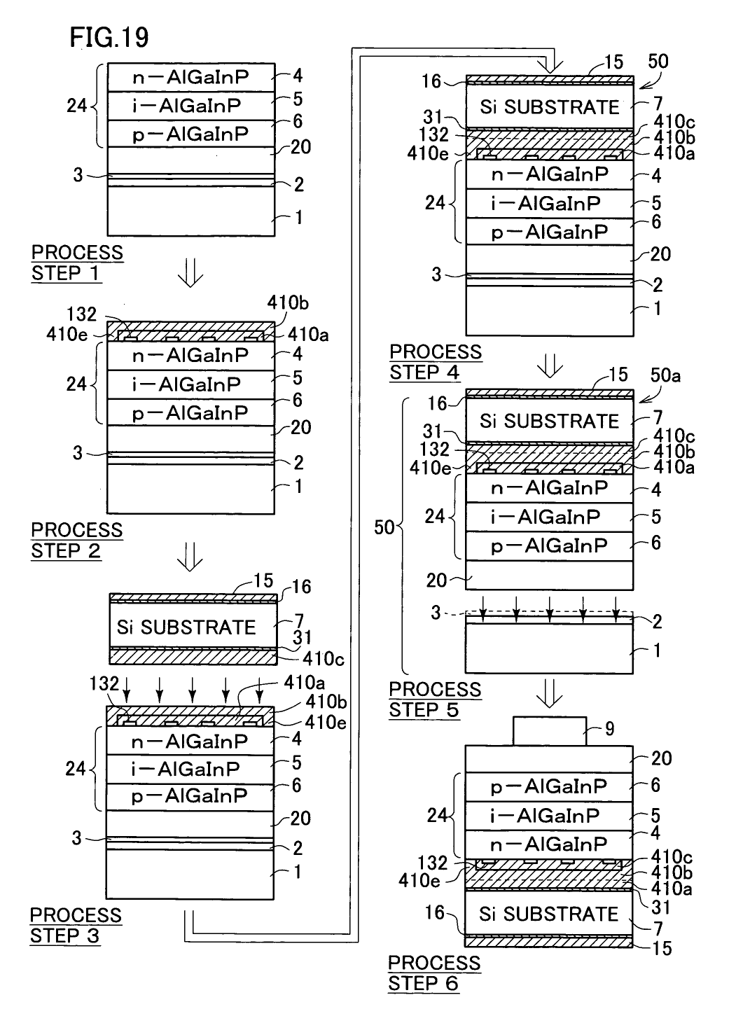

Another possible configuration is shown in FIG. 18, in which the Ag-base reflective metal layer 410a is bonded with the Si substrate (device substrate) 7, while placing in between the first Au-base layer 410b and the second Au-base layer 410c, both comprising the contact metal layer and disposed in contact with each other in this order as viewed from the Ag-base-reflective-metal-layer 410a side. Process steps of fabrication in this case is shown in FIG. 19. Process step 1 is the same as process step 1 in FIG. 13 already described in the above. Next, as shown in process step 2, the AgGeNi contact layer 132 is formed in a discrete manner on the main surface of the light-emitting layer portion 24, annealed for alloying in a temperature range from 350° C. to 660° C., and the Ag-base reflective metal layer 410a is formed so as to cover the AgGeNi contact layer 132. Further on the Ag-base reflective metal layer 410a, the first Au-base layer 410b, which is a precursor of the Au-base contact metal layer, is formed.

On the other hand, as shown in process step 3, the AuSb contact layers 31, 16 (may be substituted by the AuSn contact layer as described in the above), which are precursors of the substrate-side contact metal layers, are formed respectively on both main surfaces of the separately-obtained Si single crystal substrate 7 (n-type), and are annealed for alloying in a temperature range from 250° C. to 359° C. Further on the AuSb contact layer 31, the second Au-base layer 410c, which is a precursor of the Au-base contact metal layer, is formed. On the AuSb contact metal layer 16, the back electrode layer 15 (typically composed of an Au-base metal) is formed. In the above process steps, the individual metal layers can typically be formed by sputtering, vacuum evaporation or the like.

Next, as shown in process step 4, the Si single crystal substrate 7 and the light-emitting layer portion 24 are stacked and pressed so as to oppose the second Au-base layer 410c and the first Au-base layer 410b, respectively formed thereon, and then annealed in a temperature range from 180° C. to 360° C., typically at 250° C., so as to produce the substrate stack 50. The Si single crystal substrate 7 is thus bonded to the light-emitting layer portion 24 while placing the first Au-base layer 410b and the second Au-base layer 410c in between. The first Au-base layer 410b and the second Au-base layer 410c are bonded with a sufficient bonding strength by adopting the above-described annealing for bonding. Because both of the first Au-base layer 410b and the second Au-base layer 410c are composed of Au less likely to be oxidized, the annealing for bonding can be carried out in the air without problems.

Separation of the GaAs single crystal substrate 1 from the substrate stack 50 in succeeding process step 5 can be carried out by the same procedures as in process step 5 in FIG. 13. Another possible process is such that the etching stop layer composed of AlInP is formed in place of the AlAs releasing layer 3, the GaAs single crystal substrate 1 (light-emitting-layer-growing substrate) is then etched off together with the GaAs buffer layer 2 using a first etching solution (e.g., ammonia/hydrogen peroxide mixed solution) having an etching selectivity to GaAs, and the etching stop layer is then etched off using a second etching solution (e.g., hydrochloric acid, where addition of hydrofluoric acid for removing Al oxide layer also allowable) having an etching selectivity to AlInP.

For the case where it is anticipated that the Ag-base reflective metal layer 410a may be corroded by the etching solution during the etching for separating (removing) the light-emitting-layer-growing substrate, the method described below will be recommendable. As shown in process step 2, the first Au-base layer 410b in contact with the Ag-base reflective metal layer 410a is formed so that the outer periphery of the first Au-base layer 410b completely surrounds the outer periphery of the Ag-base reflective metal layer 410a, and so that the first Au-base layer 410b has a larger area than the Ag-base reflective metal layer 410a has. In this configuration, the Ag-base reflective metal layer 410a is formed so as to be covered by the first Au-base layer 410b so that the outer peripheral surface of the Ag-base reflective metal layer 410a is protected by the outer circumferential portion 410e of the first Au-base layer 410b having a higher corrosion resistance, and this makes the Ag-base reflective metal layer 410a less likely to be adversely affected by the etching of the light-emitting-layer-growing substrate (GaAs single crystal substrate 1) in process step 5. Ag has been very likely to be corroded particularly when the GaAs single crystal substrate 1 was used as the light-emitting-layer-growing substrate and was later dissolved and removed using an ammonia/hydrogen peroxide mixed solution as the etching solution, the above-described configuration makes it possible to dissolve and remove the GaAs single crystal substrate 1 without problems.

Although the Ag-base reflective metal layer 410a was used in the above-described embodiment, it is also allowable to form the reflective metal layer containing any one of Ru, Rh, Re, Os, Ir and Pt as a major component (e.g., Pt-base reflective metal layer), in place of the Ag-base reflective metal layer 410a. It is still also allowable to form a transparent conductive oxide layer such as ITO layer, in place of the current-spreading layer 20, and to dispose the electrode 9 (bonding pad) thereon.

Although the individual layers (p-type cladding layer 6, active layer 5 and n-type cladding layer 4) composing the light-emitting layer portion 24 in the above-described embodiment were formed using the AlGaInP alloy, it is also allowable to compose these layers using an AlGaInN alloy in this case, a sapphire substrate (insulating material), in place of GaAs single crystal substrate, is typically used as the light-emitting-layer-growing substrate on which the light-emitting layer portion 24 is to be grown. For the case where the light-emitting layer portion composed of AlGaInN alloy is formed on the sapphire substrate while placing a GaN buffer layer in between, the sapphire substrate can be separated and removed by irradiating excimer laser from the back surface side of the sapphire substrate so as to melt the GaN buffer layer. The configuration using the Ag-base reflective metal layer 410a and the AgGeNi contact layer 132 is advantageous in enhancing the improving effect of the reflectivity of blue-to-green light when the emission wavelength resides of the light-emitting layer portion 24 in a range from 450 nm to 580 nm.

The above-described embodiment adopts a configuration of the light-emitting layer portion 24 in which the n-type cladding layer 4, the active layer 5 and the p-type cladding layer 6 are stacked in this order as viewed from the substrate side, where it is also allowable to invert this order so as to stack the p-type cladding layer, active layer and the n-type cladding layer in this order as viewed from the substrate side.

(Fifth Invention)

The following paragraphs will describe the fifth invention referring to the attached drawings.

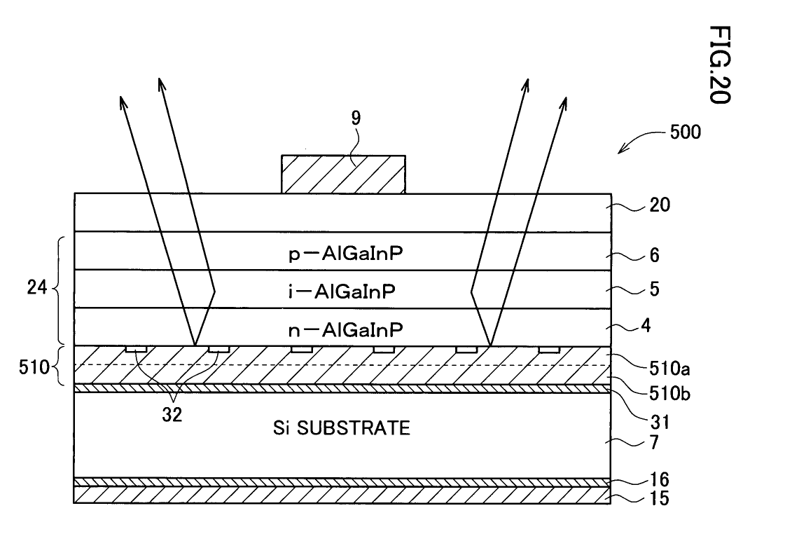

FIG. 20 is a conceptual drawing of a light-emitting device 500 according to one embodiment of the fifth invention. The light-emitting device 500 comprises the Si substrate 7, which is a conductive device substrate composed of n-type Si (silicon) single crystal, and a light-emitting layer portion 24 bonded on one main surface of the Si substrate 7 while placing a metal layer 510 in between.

The light-emitting layer portion 24 is configured so that the active layer 5 composed of a non-doped (AlₓGa₁₋ₓ)_{y}In_{1-y}P (where, 0≦x≦0.55, 0.45≦y≦0.55) alloy is sandwiched by a first-conductivity-type cladding layer, which is the p-type cladding layer 6 composed of p-type (AlₓGa₁₋ₓ)_{y}In_{1-y}P (where, x<z≦1) in this embodiment, and the second-conductivity-type cladding layer different from the first-conductivity-type cladding layer, which is the n-type cladding layer 4 composed of n-type (Al_{z}Ga_{1-z})_{y}In_{1-y}P (where, x<z≦−1) in this embodiment, and so as to have an emission wavelength in green to red spectral regions (emission wavelength (peak emission wavelength) of 550 nm to 670 nm) depending on the composition of the active layer 5. In the light-emitting device 500, the p-type AlGaInP cladding layer 6 is disposed on the metal electrode 9 side, and the n-type AlGaInP cladding layer 4 is disposed on the metal layer 510 side. The device thus has positive polarity on the metal electrode 9 side.

The main surface of the light-emitting layer portion 24, which is opposite to the surface facing to the substrate 7, has the current-spreading layer 20 composed of AlGaAs formed thereon, and at around the center of the main surface thereof, the metal electrode (e.g., Au electrode) 9 for supplying emission drive current to the light-emitting layer portion 24 is formed so as to cover a portion of the main surface. The area around the metal electrode 9 on the main surface of the current-spreading layer 20 serves as an extraction area of the light emitted from the light-emitting layer portion 24. On the back surface of the Si single crystal substrate 7, the metal electrode (back electrode, typically composed of Au) 15 is formed so as to cover the entire portion thereof. When the metal electrode 15 is an Au electrode, the AuSb contact layer 16 is interposed as the substrate-side contact layer between the metal electrode 15 and the Si single crystal substrate 7. It is also allowable to use an AuSn contact layer as the substrate-side contact layer in place of the AuSb contact layer 16.

The Si single crystal substrate 7 is fabricated by slicing and polishing a Si single crystal ingot, and has a thickness typically within a range from 100 μm to 500 μm. The Si single crystal substrate 7 is bonded to the light-emitting layer portion 24 while placing the main metal layer 510 in between. The metal layer 510 is configured as an Au-base layer over the entire portion thereof, and obtained by bonding a first Au-base layer 510a in contact with the light-emitting layer portion 24 (compound semiconductor layer) and a second Au-base layer 510b in contact with the Si substrate 7 through annealing for bonding.

Between the light-emitting layer portion 24 and the first Au-base layer 510a, an AuGeNi contact layer 32 (typical composition relates to 15% by mass of Ge, and 10% by mass of Ni) is disposed as the light-emitting-layer-portion side contact layer, contributing reduction in series resistance of the device. The AuGeNi contact layer 32 is formed in a discrete manner on the main surface of the first Au-base layer 510a, with a ratio of formation area of 1% to 25%, both ends inclusive. On the other hand, between the Si single crystal substrate 7 and the second Au-base layer 510b, the AuSb contact layer 31 (typically containing 5% by mass of Sb) is interposed as the substrate-side contact layer. It is also allowable to use an AuSn contact metal layer in place of the AuSb contact layer 31. The first Au-base layer 510a, second Au-base layer 510b, AuSb contact layer 31 and AuGeNi contact layer 32 compose the metal layer 510, and the metal layer 510 is disposed so as to contact with both of the light-emitting layer portion 24 and the Si substrate 7. The first Au-base layer 510a and the second Au-base layer 510b are composed of pure Au, or an Au alloy having a ratio of Au content ratio of 95% by mass or above.

Light from the light-emitting layer portion 24 can be extracted in a manner such that a component of the light directly emitted towards the light-extraction-surface side is interlaced with a reflected component coming from the metal layer 510. The thickness of the metal layer 510 is preferably adjusted to 80 nm or above in order to fully secure the reflective effect. Although the upper limit of the thickness is not specifically limited, it is appropriately adjusted so as to keep a reasonable balance with the cost (typically to 1 μm or around).

The following paragraphs will describe a method of fabricating the light-emitting device 500 shown in FIG. 20.

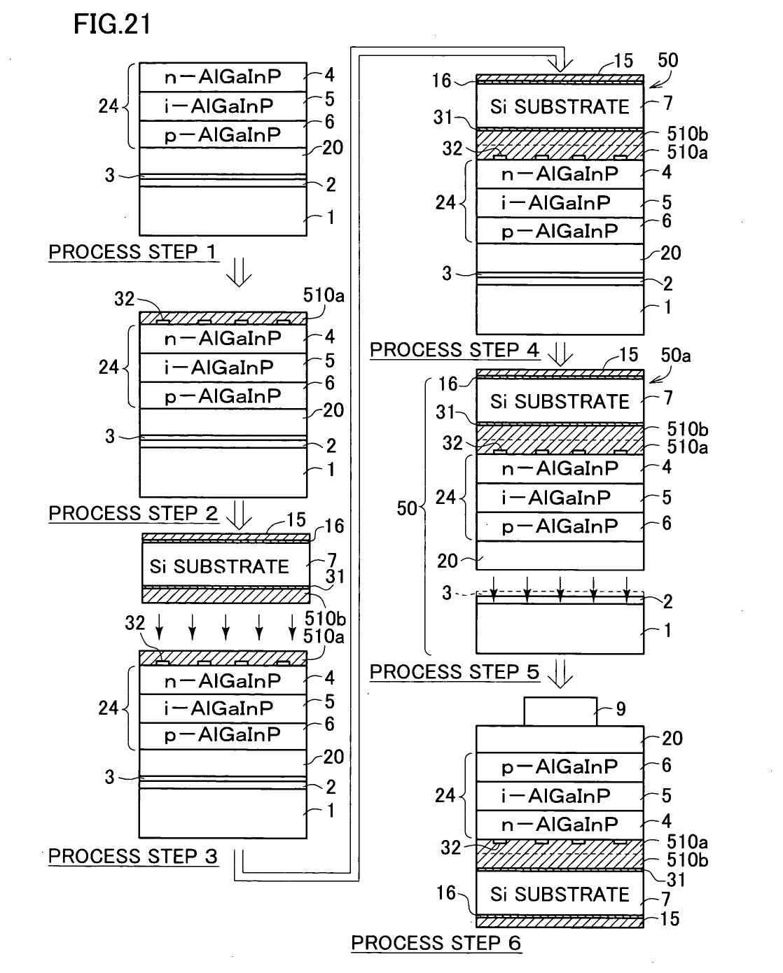

First as shown in process step 1 in FIG. 21, on the main surface of the GaAs single crystal substrate 1 which is a semiconductor single crystal substrate used as the light-emitting-layer-growing substrate, the p-type GaAs buffer layer 2 typically of 0.5 μm thick, the releasing layer 3 composed of AlAs typically of 0.5 μm thick, and the current-spreading layer 20 composed of p-type AlGaAs typically of 5 μm thick are formed sequentially in this order by epitaxial growth. The light-emitting layer portion 24 is formed further thereon by epitaxially growing the p-type AlGaInP cladding layer 6 of 1 μm thick, the AlGaInP active layer (non-doped) 5 of 0.6 μm thick, and the n-type AlGaInP cladding layer 4 of 1 μm thick in this order.

Next, as shown in process step 2, the AuGeNi contact layer 32 is formed in a discrete manner on the main surface of the light-emitting layer portion 24. After the AuGeNi contact layer 32 is formed, annealing for alloying is carried out in a temperature range from 350° C. to 500° C. A first Au-base layer 510a is formed so as to cover the AuGeNi contact layer 32. By the annealing for alloying, an alloyed layer is formed between the light-emitting layer portion 24 and the AuGeNi contact layer 32, and this contributes to a considerable reduction in the series resistance. On the other hand, as shown in process step 3, the AuSb contact layers 31, 16 (may be substituted by the AuSn contact layer as described in the above), which are precursors of the substrate-side contact layers, are formed respectively on both main surfaces of the separately-obtained Si single crystal substrate 7 (n-type), and are annealed for alloying in a temperature range from 250° C. to 359° C. Further on the AuSb contact layer 31, the second Au-base layer 510b is formed. On the AuSb contact metal layer 16, the back electrode layer 15 (typically composed of an Au-base metal) is formed. In the above process steps, the individual metal layers can typically be formed by sputtering, vacuum evaporation or the like.

Next, as shown in process step 4, the Si single crystal substrate 7 and the light-emitting layer portion 24 are stacked and pressed so as to oppose the second Au-base layer 510b and the first Au-base layer 510a, respectively formed thereon, and then annealed in a temperature range from 180° C. to 360° C., typically at 250° C., so as to produce the substrate stack 50. The Si single crystal substrate 7 is thus bonded to the light-emitting layer portion 24 while placing the first Au-base layer 510a and the second Au-base layer 510b in between. The first Au-base layer 510a and the second Au-base layer 510b are united with a sufficient bonding strength by adopting the annealing for bonding, to thereby produce the main metal layer 510 together with the AuSb contact layer 31 and the AuGeNi contact layer 32. Because both of the first Au-base layer 510a and the second Au-base layer 510b are composed of Au less likely to be oxidized, the annealing for bonding can be carried out in the air without problems.

The process then advances to process step 5, where the substrate bond 50 is dipped in an etching solution typically comprising a 10% aqueous hydrofluoric acid solution, so as to selectively etch the AlAs releasing layer 3 formed between the buffer layer 2 and the light-emitting layer portion 24, to thereby separate the GaAs single crystal substrate 1 (opaque to the light from the light-emitting layer portion 24) from the stack 50a which comprises the light-emitting layer portion 24 and the Si single crystal substrate 7 bonded thereto. Another possible process is such that the etching stop layer composed of AlInP is formed in place of the AlAs releasing layer 3, the GaAs single crystal substrate 1 is then etched off together with the GaAs buffer layer 2 using a first etching solution (e.g., ammonia/hydrogen peroxide mixed solution) having an etching selectivity to GaAs, and the etching stop layer is then etched off using a second etching solution (e.g., hydrochloric acid, where addition of hydrofluoric acid for removing Al oxide layer also allowable) having an etching selectivity to AlInP.

Next, as shown in process step 6, the electrode 9 for enabling wire bonding (bonding pad: FIG. 20) is formed on the main surface of the current-spreading layer 20, exposed after the separation of the GaAs single crystal substrate 1, so as to cover a part thereof. Thereafter, the dicing is carried out according to the general practice to thereby obtain semiconductor chips, and each chip is then mounted on a support, wire-bonded with lead wires, and molded with a resin to thereby produce a final product form of the light-emitting device.

The device substrate can be composed not only of the Si substrate, but also of other conductive substrates, which are exemplified by metal substrate such as Al (alloy also included).

It is also allowable to compose the individual layers composing the light-emitting layer portion 24 using an AlGaInN alloy. In this case, a sapphire substrate (insulating material), or an SiC single crystal substrate, in place of GaAs single crystal substrate, is typically used as the light-emitting-layer-growing substrate on which the light-emitting layer portion 24 is to be grown. Although the light-emitting layer portion 24 in the above-described embodiment was configured so that the n-type cladding layer 4, the active layer 5 and the p-type cladding layer 6 are stacked in this order as viewed from the substrate side, where it is also allowable to invert this order so as to stack the p-type cladding layer, active layer and the n-type cladding layer in this order as viewed from the substrate side.

(Sixth Invention)

The following paragraphs will describe the sixth invention referring to the attached drawings.

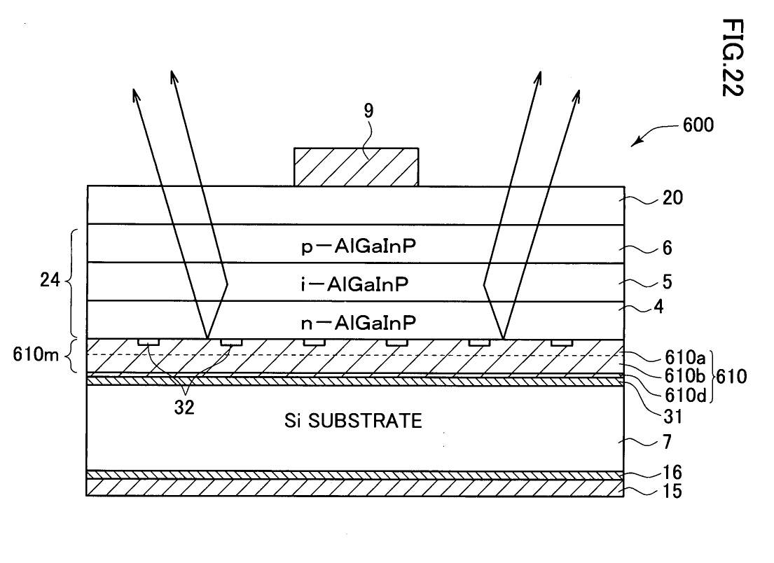

FIG. 22 is a conceptual drawing of a light-emitting device 600 according to one embodiment of the sixth invention. The light-emitting device 600 comprises the Si substrate 7, which is a conductive device substrate composed of n-type Si (silicon) single crystal, and a light-emitting layer portion 24 bonded on one main surface of the Si substrate 7 while placing a metal layer 610 in between.

The light-emitting layer portion 24 is configured so that the active layer 5 composed of a non-doped (AlₓGa₁₋ₓ)_{y}In_{1-y}P (where, 0≦x≦0.55, 0.45≦y≦0.55) alloy is sandwiched by a first-conductivity-type cladding layer, which is the p-type cladding layer 6 composed of p-type (AlₓGa₁₋ₓ)_{y}In_{1-y}P (where, x<z≦1) in this embodiment, and the second-conductivity-type cladding layer different from the first-conductivity-type cladding layer, which is the n-type cladding layer 4 composed of n-type (Al_{z}Ga_{1-z})_{y}In_{1-y}P (where, x<z≦1) in this embodiment, and so as to have an emission wavelength in green to red spectral regions (emission wavelength (peak emission wavelength) of 550 nm to 670 nm) depending on the composition of the active layer 5. In the light-emitting device 600, the p-type AlGaInP cladding layer 6 is disposed on the metal electrode 9 side, and the n-type AlGaInP cladding layer 4 is disposed on the metal layer 610 side.

The main surface of the light-emitting layer portion 24, which is opposite to the surface facing to the substrate 7, has the current-spreading layer 20 composed of AlGaAs formed thereon, and at around the center of the main surface thereof, the metal electrode (e.g., Au electrode) 9 for supplying emission drive current to the light-emitting layer portion 24 is formed so as to cover a portion of the main surface. The area around the metal electrode 9 on the main surface of the current-spreading layer 20 serves as an extraction area of the light emitted from the light-emitting layer portion 24. On the back surface of the Si single crystal substrate 7, the metal electrode (back electrode, typically composed of Au) 15 is formed so as to cover the entire portion thereof. When the metal electrode 15 is an Au electrode, the AuSb contact alloyed layer 16 obtained by alloying the AuSb alloy and Si is interposed as the substrate-side contact alloyed layer between the metal electrode 15 and the Si single crystal substrate 7. Materials for composing the contact alloyed layer are not specifically limited so far as they can reduce the contact resistance through alloying with the Si substrate. For example, it is allowable to use a p-type Si substrate as the Si substrate, where it is preferable to use an AuBe contact alloyed layer or the like. For the case where the n-type Si substrate is used, materials for composing the contact alloyed layer are not limited to the AuSb alloy.

The Si single crystal substrate 7 is fabricated by slicing and polishing a Si single crystal ingot, and has a thickness typically within a range from 100 μm to 500 μm. The Si single crystal substrate 7 is bonded to the light-emitting layer portion 24 while placing the metal layer 610 in between. The metal layer 610 in this embodiment comprises a Si-diffusion-blocking layer 610d and a main metal layer 610m as described later.

Between the light-emitting layer portion 24 and the metal layer 610, an AuGeNi contact alloyed layer 32 (obtained by alloying the AuGeNi contact metal layer comprising 15% by mass of Ge, 10% by mass of Ni, and the residual portion of Au with the compound semiconductor layer on the light-emitting-layer-portion 24 side) is formed as the light-emitting-layer-portion side contact alloyed layer, contributing reduction in series resistance of the device. The AuGeNi contact alloyed layer 32 is formed in a discrete manner on the main surface of the metal layer 610, with a ratio of formation area of 1% to 25%, both ends inclusive. On the other hand, between the Si single crystal substrate 7 and the metal layer 610, the AuSb contact alloyed layer 31 (obtained by alloying the AuSb alloy comprising 5% by mass of Sb and the residual portion of Au with Si composing the substrate 7) is interposed as the substrate-side contact alloyed layer, so as to contact with the first main surface of the Si single crystal substrate 7. Materials for composing the contact alloyed layer are again not limited to the AuSb alloy.

The entire surface of the AuSb contact alloyed layer 31 is covered with a silicon diffusion-blocking layer 610d composing a part of the metal layer 610. The silicon diffusion-blocking layer 610d is an alloy layer containing Au as a major component, also containing a Si-diffusion-blocking component which comprises a single, or two or more elements selected from Sn, Pb, In and Ga in an amount of 1% by mass to 20% by mass, and having a thickness of 50 nm to 5 μm (Au-Sn alloy layer (typically having an Sn content of 5% by mass) and a thickness of 600 nm in this embodiment). The main metal layer 610m (composing a part of the metal layer 610) is formed so as to cover the entire surface of the silicon diffusion-blocking layer 610d, and so as to contact therewith. The main metal layer 610m composes the reflective surface, and the light from the light-emitting layer portion 24 can be extracted in a manner such that a component of the light directly emitted towards the light-extraction-surface side is interlaced with a reflected component coming from the main metal layer 610m. In this embodiment, the main metal layer 610m is composed of pure Au, or an Au alloy having a ratio of Au content ratio of 95% by mass or above. The thickness of the main metal layer 610m is preferably adjusted to 80 nm or above in order to fully secure the reflective effect. Although the upper limit of the thickness is not specifically limited, it is appropriately adjusted so as to keep a reasonable balance with the cost (typically to 10 μm or around).

The material for composing the contact alloyed layers 31, 16 disposed between the Si single crystal substrate 7 and the metal layer 610, and between the Si single crystal substrate 7 and the electrode 15 on the back surface, is not limited to the aforementioned AuSb alloy, and may be an AuSn alloy. In particular for the case where the contact alloyed layer 31 in contact with the metal layer 610 is composed of the AuSn alloy, the contact alloyed layer 31 per se may have a function of suppressing the Si diffusion from the Si-single-crystal-substrate 7 side towards the metal-layer 610 side. In this case, the Si-diffusion-blocking layer 610d composed of AuSn alloy and disposed as described in the above in addition to the contact alloyed layer 31 composed of AuSn alloy is successful in further improving the suppressive effect over the Si diffusion towards the metal-layer 610 side. Whereas for the case where the contact alloyed layer 31 is composed of an Sn-free (and further In-free and Ga-free) alloy such as AuSb alloy, it is essential to additionally dispose the Si-diffusion-blocking layer 610d because the suppressive effect over the Si diffusion cannot be expected for the contact alloyed layer 31 (the Si-diffusion-blocking layer 610d can, of course, be composed of AuSn alloy).

The following paragraphs will describe a method of fabricating the light-emitting device 600 shown in FIG. 22.

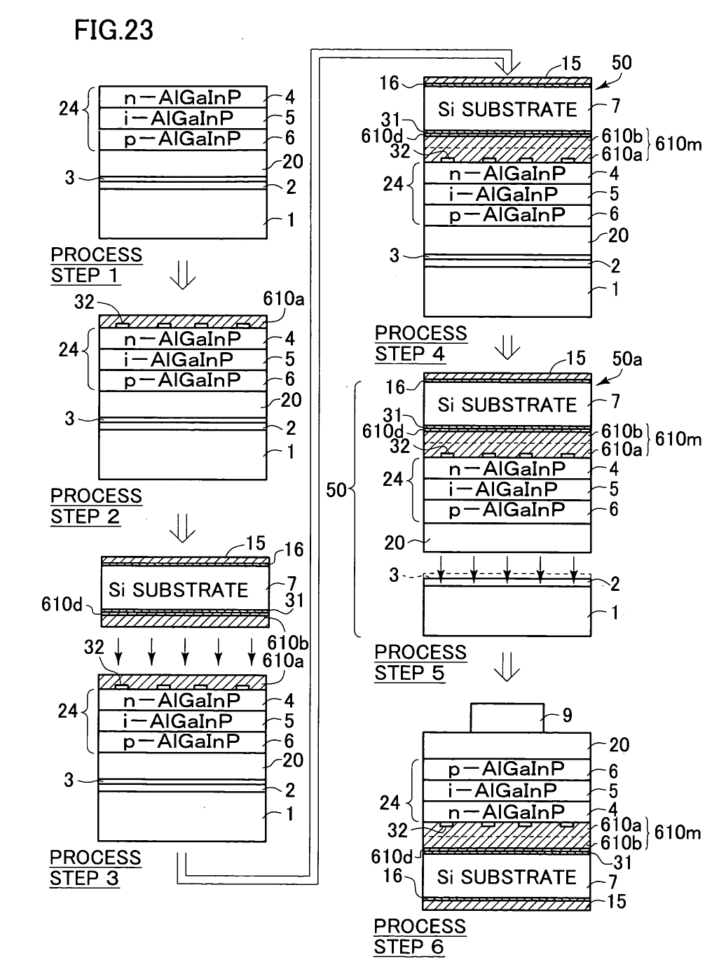

First as shown in process step 1 in FIG. 23, on the main surface of the GaAs single crystal substrate 1 which is a semiconductor single crystal substrate used as the light-emitting-layer-growing substrate, the p-type GaAs buffer layer 2 typically of 0.5 μm thick, the releasing layer 3 composed of AlAs typically of 0.5 μm thick, and the current-spreading layer 20 composed of p-type AlGaAs typically of 5 μm thick are formed sequentially in this order by epitaxial growth. The light-emitting layer portion 24 is formed further thereon by epitaxially growing the p-type AlGaInP cladding layer 6 of 1 μm thick, the AlGaInP active layer (non-doped) 5 of 0.6 μm thick, and the n-type AlGaInP cladding layer 4 of 1 μm thick in this order.

Next, as shown in process step 2, the AuGeNi contact metal layer is formed in a discrete manner on the second main surface of the light-emitting layer portion 24, annealed for alloying in a temperature range from 350° C. to 500° C., to thereby obtain the AuGeNi contact alloyed layer 32. A first Au-base layer 610a is formed so as to cover the AuGeNi contact alloyed layer 32. On the other hand, as shown in process step 3, the AuSb contact alloyed layers, for example, are formed respectively on both main surfaces of the separately-obtained Si single crystal substrate 7 (n-type), and are annealed for alloying in a temperature range from 100° C. to 500° C., to thereby obtain the AuSb contact alloyed layer 31, 16. Further on the AuSb contact alloyed layer 31, the Si diffusion-blocking layer 610d composed of an Au-Sn alloy (typically of 600 nm thick) and the second Au-base layer 610b are formed in this order. On the AuSb contact alloyed layer 16, the back electrode layer 15 (typically composed of an Au-base metal) is formed. In the above process steps, the individual metal layers can typically be formed by sputtering, vacuum evaporation or the like.

Next, as shown in process step 4, the Si single crystal substrate 7 and the light-emitting layer portion 24 are stacked and pressed so as to oppose the second Au-base layer 610b and the first Au-base layer 610a, respectively formed thereon, and then annealed in a temperature range from 180° C. to 360° C., typically at 250° C., so as to produce the substrate stack 50. The Si single crystal substrate 7 is thus bonded to the light-emitting layer portion 24 while placing the first Au-base layer 610a and the second Au-base layer 610b in between. The first Au-base layer 610a and the second Au-base layer 610b are united by the annealing for bonding, to thereby produce the Au-base main metal layer 610m. Because both of the first Au-base layer 610a and the second Au-base layer 610b are composed of Au less likely to be oxidized, the annealing for bonding can be carried out in the air without problems.

Further between the second Au-base layer 610b and the Si single crystal substrate 7 (AuSb contact metal layer 31), a Si diffusion-blocking layer 610d composed of an Au-Sn alloy is interposed. The Si diffusion-blocking layer 610d is successful in blocking the diffusion of the Si component from the Si single crystal substrate 7 towards the second Au-base layer 610b during the annealing for bonding, and this also effectively blocks the dripping of the Si component into the second Au-base layer 610b or further into the side of the Au-base metal layer 610m obtained by the bonding in an united form. This successfully suppresses nonconformities such that the reflective surface of the finally-obtained Au-base metal layer 610m is contaminated by the diffusion of the Si component. The heat history during the forming of the second Au-base layer 610b by evaporation or the like tends to cause Si to diffuse from the Si single crystal substrate 7, penetrates the AuSb bonding alloyed metal layer 31, reaches the second Au-base metal layer 610b to finally deposit on the outermost surface thereof, and that the deposited Si, if oxidized, may seriously interfere the bonding between the second Au-base metal layer 610b and the first Au-base metal layer 610a. In contrast to this, the Si-diffusion-blocking layer 610d disposed as described in the above can successfully suppress the deposition and the subsequent oxidation of Si, and can further enhance the bonding strength between the Si single crystal substrate 7 and the light-emitting layer portion (compound semiconductor layer) 24 while placing both Au-base metal layers 610a, 610b in between.

The process then advances to process step 5, where the substrate bond 50 is dipped in an etching solution typically comprising a 10% aqueous hydrofluoric acid solution, so as to selectively etch the AlAs releasing layer 3 formed between the buffer layer 2 and the light-emitting layer portion 24, to thereby separate the GaAs single crystal substrate 1 (opaque to the light from the light-emitting layer portion 24) from the stack 50a which comprises the light-emitting layer portion 24 and the Si single crystal substrate 7 bonded thereto. Another possible process is such that the etching stop layer composed of AlInP is formed in place of the AlAs releasing layer 3, the GaAs single crystal substrate 1 is then etched off together with the GaAs buffer layer 2 using a first etching solution (e.g., ammonia/hydrogen peroxide mixed solution) having an etching selectivity to GaAs, and the etching stop layer is then etched off using a second etching solution (e.g., hydrochloric acid, where addition of hydrofluoric acid for removing Al oxide layer also allowable) having an etching selectivity to AlInP.

Next, as shown in process step 6, the electrode 9 for enabling wire bonding (bonding pad: FIG. 22) is formed on the main surface of the current-spreading layer 20, exposed after the separation of the GaAs single crystal substrate 1, so as to cover a part thereof. Thereafter, the dicing is carried out according to the general practice to thereby obtain semiconductor chips, and each chip is then mounted on a support, wire-bonded with lead wires, and molded with a resin to thereby produce a final product form of the light-emitting device.

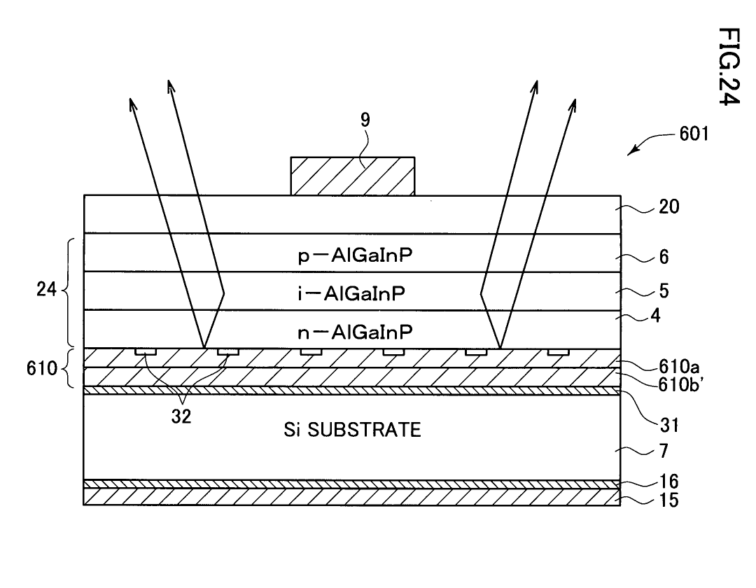

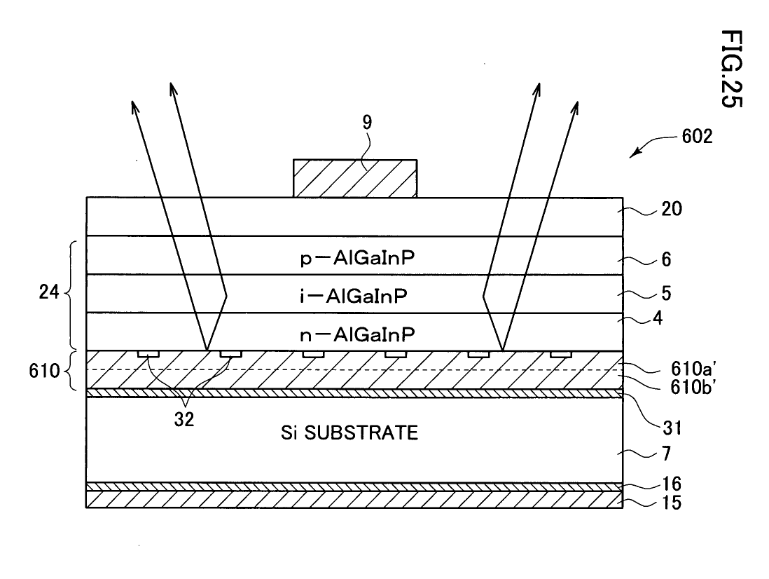

In the above-described embodiment, the bonding was accomplished by the first Au-base layer 610a and the second Au-base layer 610b composing the Au-base metal layer 610m, which was disposed besides the Au-base, Si-diffusion-blocking layer 610d, it is also allowable, as exemplified by a light-emitting device 601 shown in FIG. 24, to compose the entire portion of a second Au-base layer 610b′ as the Au-base, Si-diffusion-blocking layer, and to bond this layer to the first Au-base layer 610a having a content of Si-diffusion-blocking component smaller than that of the second Au-base layer 610b′. In this case, only the first Au-base layer 610a composes the main metal layer. On the other hand, it is also allowable, as exemplified by a light emitting device 602 shown in FIG. 25, to configure also the first Au-base layer 610a′ as the Au-base, Si-diffusion-blocking layer, and to bond this with the second Au-base layer 610b′ configured again as the Au-base, Si-diffusion-blocking layer. In this case, the entire portion of the metal layer 610 is configured as the Au-base, Si-diffusion-blocking layer. For the case where the metal layer 610 is configured using an AuSn alloy composing the Si-diffusion-blocking layer specifically in a portion which includes the reflective surface, and the contact alloyed layer 31 also is composed of the AuSn alloy, the contact alloyed layer 31 side may have a relatively high Sn concentration in view of reducing the contact resistance, and the Si-diffusion-blocking-layer 610d side may have a relatively low Sn concentration in view of suppressing lowering in the reflectivity. In other words, the Sn concentration in the AuSn alloy composing the Si-diffusion-blocking layer 610d, which is also expected to function as the reflective surface, can be set lower than that in the AuSn alloy composing the contact alloyed layer 31. It is also allowable to configure all of the Au-base layers composing the metal layer 610 as Ag-base layers, and the contact alloyed layer in contact therewith may be composed using a contact metal layer having Ag as a major component, in place of Au.

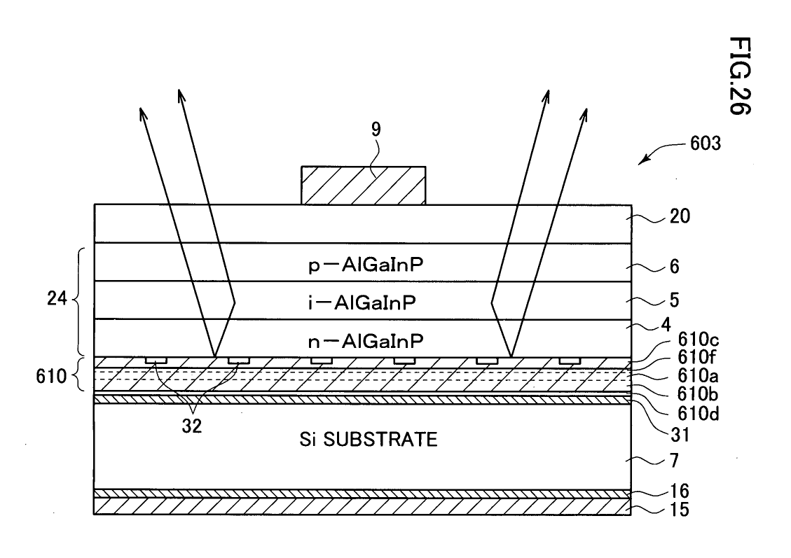

Although the first Au-base layer 610a (610a′) configures the reflective surface in the configurations shown in FIGS. 22, 24 and 25, it is also allowable, as shown in a light-emitting device 603 in FIG. 26, to interpose a reflective layer 610c which is configured as an Ag-base layer or an Al-base layer, and composes a part of the main metal layer 610, between the first Au-base layer 610a and the light-emitting layer portion 24. In this case, the first Au-base layer 610a and the second Au-base layer 610b compose the Au-base coupling layer. The light-emitting-layer-portion-side contact alloyed layer 32 is composed of an Ag-base contact alloyed layer (e.g., such as formed using an AgGeNi contact metal layer), in place of the Au-base contact alloyed layer, for the case where the reflective layer 610c is of Ag-base, and is composed of an Al-base contact alloyed layer (e.g., such as formed using an AlGeNi contact metal layer) for the case where the reflective layer 610c is of Al-base. When the reflective layer 610c is thus configured as the Al-base layer or Ag-base layer, it is preferable to dispose a reflective-layer-side, diffusion-blocking layer 610f having any of Ti, Ni and Cr as a major component between the reflective layer 610c and the first Au-base layer 610a, so as to prevent the reflective surface from being contaminated by Au diffused from the first Au-base layer 610a. It is to be noted that FIGS. 24 to 26 use the same reference numerals for any constituents in common with those of the light-emitting device 600 shown in FIG. 22, while omitting detailed descriptions therefor.

What is claimed is:

1. A light-emitting device comprising:
a compound semiconductor layer having a light-emitting layer portion, being configured so that one main surface of which serves as a light extraction surface;
a device substrate bonded on the other main surface side of the compound semiconductor layer;
and an Ag-base metal layer interposed between the device substrate and the compound semiconductor layer, including an Ag-base reflective metal layer having Ag as a major component over the entire portion thereof, and being intended for reflecting the light from the light-emitting layer portion back towards the light extraction surface side.

2. The light-emitting device as claimed in claim 1, wherein the light-emitting layer portion has a peak emission wavelength within a range from 350 nm to 670 nm, both ends inclusive.

3. The light-emitting device as claimed in claim 2, wherein the light-emitting layer portion is configured as having a double heterostructure in which a first-conductivity-type cladding layer, an active layer and a second-conductivity-type cladding layer, all of these layers being composed of (AlₓGa₁ x)_{y}In_{1-y}P (where, 0≦x≦1 and 0≦y≦1) or InₓGa_{y}Al_{1-x-y}N (where, 0≦x≦1, 0≦y≦1 and x+y≦1), are stacked in this order.

4. The light-emitting device as claimed in claim 1, further comprising a light-emitting-layer-portion-side, Ag-base contact layer having Ag as a major component, which is arranged in a discrete manner on the main surface of the Ag-base reflective metal layer, between the Ag-base reflective metal layer and the compound semiconductor layer.

5. The light-emitting device as claimed in claim 4, wherein the light-emitting-layer-portion-side, Ag-base contact layer is an AgGeNi contact layer.

6. The light-emitting device as claimed in claim 4, wherein the ratio of formation area of the light-emitting-layer-portion-side, Ag-base contact layer to the Ag-base reflective metal layer falls within a range from 1% to 25%, both ends inclusive.

7. The light-emitting device as claimed in claim 4, wherein the Ag-base reflective metal layer has a ratio of Ag content which is set higher than that of the light-emitting-layer-portion-side, Ag-base contact layer.

8. The light-emitting device as claimed in claim 1, wherein the Ag-base reflective metal layer has a ratio of Ag content of 95% by mass or above.

9. The light-emitting device as claimed in claim 8, wherein the Ag-base reflective metal layer is composed of pure Ag.

10. The light-emitting device as claimed in claim 1, wherein the Ag-base reflective metal layer is composed of a Pd-containing Ag alloy.

11. The light-emitting device as claimed in claim 1, wherein the device substrate is a conductive semiconductor substrate, and the device further comprises a substrate-side, Ag-base contact layer which is formed between the device substrate and the Ag-base reflective metal layer, and has Ag as a major component.

12. The light-emitting device as claimed in claim 11, wherein the device substrate is a Si substrate.

13. The light-emitting device as claimed in claim 11, wherein the substrate-side, Ag-base contact layer is an AgSb contact layer or an AgSn contact layer.

14. The light-emitting device as claimed in claim 1, wherein the device substrate is a Si substrate having a sheet resistance of 0.01 Ω/□.

15. A method of fabricating the light-emitting device as claimed in any one of claims 1 to 14, comprising the steps of:
forming an Ag-base metal layer having Ag as a major component on at least either of the main surface of the compound semiconductor layer having a light-emitting layer portion, the main surface being opposite to that planned for becoming the light extraction surface, and the main surface of the device substrate, the main surface being planned to be disposed on the light-emitting-layer-portion side; and
forming a stack of the device substrate and the compound semiconductor layer while placing the Ag-base metal layer in between, and annealing the stack to thereby bond the device substrate with the compound semiconductor layer while placing the Ag-base metal layer in between.

16. The method of fabricating the light-emitting device as claimed in claim 15, further comprising the steps of:
forming a first Ag-base metal layer, having Ag as a major component, on the bonding-side main surface of the compound semiconductor layer having the light-emitting layer portion, the bonding-side main surface being defined as the main surface opposite to that planned for becoming the light extraction surface;
forming a second Ag-base metal layer, having Ag as a major component, on the bonding-side main surface of the device substrate, the bonding-side main surface being defined as the main surface which is planned to be disposed on the light-emitting-layer-portion side; and
bonding the first Ag-base metal layer and the second Ag-base metal layer under a close contact through diffusion annealing, to thereby form the Ag-base reflective metal layer.

17. The method of fabricating the light-emitting device as claimed in claim 16, wherein both of the first Ag-base metal layer and the second-Ag-base metal layer have a ratio of Ag content of 95% by mass or above, and the diffusion annealing is carried out at 100° C. or higher.

18. The method of fabricating the light-emitting device as claimed in claim 16, wherein the compound semiconductor layer is formed using (AlₓGa₁₋ₓ)_{y}In_{1-y}P (where, 0≦x≦1 and 0≦y≦1), further comprises a step of forming an AgGeNi contact layer on the bonding-side main surface of the compound semiconductor layer, the first Ag-base metal layer is formed so as to cover the AgGeNi contact layer, and further comprises a step of annealing the AgGeNi contact layer and the compound semiconductor layer for alloying.

19. The method of fabricating the light-emitting device as claimed in claim 16, wherein the device substrate comprises a Si substrate, further comprises a step of forming an AgSb contact layer on the bonding-side main surface of the Si substrate, the second Ag-base metal layer is formed so as to cover the AgSb contact layer, and further comprises a step of annealing the AgSb contact layer and the Si substrate for alloying.

20. The method of fabricating the light-emitting device as claimed in claim 16, wherein both of the first Ag-base metal layer and the second-Ag-base metal layer have a ratio of Ag content of 95% by mass or above, and the diffusion annealing is carried out at 100° C. or higher and lower than 840° C.

21. A light-emitting device comprising:
a light-emitting layer portion being composed of a first compound semiconductor, having an emission peak wavelength of 450 to 580 nm, and having a light extraction surface on the main surface side thereof;
an Ag-base contact layer formed on the main back surface of the light-emitting layer portion, or formed on the main back surface of an auxiliary compound semiconductor layer composed of a second compound semiconductor, which is transparent with respect to emission light flux and is electrically coupled to the main back surface of the light-emitting layer portion, the Ag-base contact layer comprising an alloyed layer originated from an Ag-base contact metal, having Ag as a major component, and the compound semiconductor composing the main back surface of the compound semiconductor layer; and
an Ag-base reflective metal layer, composed of a metal having Ag as a major component, for reflecting light from the light-emitting layer portion back towards the light extraction surface side, and being formed so as to cover the Ag-base contact layer.

22. The light-emitting device as claimed in claim 21, wherein the light-emitting layer portion is configured as having a double heterostructure in which a first-conductivity-type cladding layer, an active layer and a second-conductivity-type cladding layer, all of these layers being composed of (AlₓGa₁₋ₓ)_{y}In_{1-y}P (where, 0≦x≦1 and 0≦y≦1) or InₓGa_{y}Al_{1-x-y}N (where, 0≦x≦1, 0≦y≦1 and x+y≦1), are stacked in this order.

23. The light-emitting device as claimed in claim 21, wherein the auxiliary compound semiconductor layer is a transparent conductive substrate bonded to a compound semiconductor layer composing the light-emitting layer portion, and the Ag-base reflective metal layer reflects light from the light-emitting layer portion back towards the light extraction surface side through the transparent conductive substrate.

24. The light-emitting device as claimed in claim 23, wherein the Ag-base contact layer is arranged in a discrete manner on the main surface of the Ag-base reflective metal layer, between the Ag-base reflective metal layer and the transparent conductive substrate.

25. The light-emitting device as claimed in claim 24, wherein the Ag-base contact layer is formed in a ratio of formation area of 1% to 25%, both ends inclusive, with respect to the Ag-base reflective metal layer.

26. The light-emitting device as claimed in claim 21, wherein the Ag-base reflective metal layer has a ratio of Ag content larger than that of the Ag-base contact layer.

27. The light-emitting device as claimed in claim 21, wherein the Ag-base reflective metal layer has a ratio of Ag content of 95% by mass or above.

28. The light-emitting device as claimed in claim 27, wherein the Ag-base reflective metal layer is composed of pure Ag.

29. The light-emitting device as claimed in claim 21, wherein the Ag-base reflective metal layer is composed of a Pd-containing Ag alloy.

30. An ohmic electrode structure for a semiconductor device comprising;
an Ag-base contact layer formed on the surface of a device main body composed of a Group II-V compound semiconductor, and comprising an alloyed layer originated from an AgGeNi contact metal having Ag as a major component and including also Ni and Ge, and the Group III-V compound semiconductor; and
an electrode layer formed so as to cover the Ag-base contact layer, and being composed of an Ag-base metal having Ag as a major component.

31. A light-emitting device comprising:
a compound semiconductor layer having a light-emitting layer portion, being configured so that a first main surface of which serves as a light extraction surface; and
a device substrate bonded on a second main surface side of the compound semiconductor layer while placing a main metal layer in between, the main metal layer having a reflective surface for reflecting light from the light-emitting layer portion back towards the light extraction surface side; further comprising:
a diffusion-blocking layer interposed between the device substrate and the main metal layer, being composed of a conductive material, and provided for blocking diffusion of any device-substrate-derived components towards the main metal layer.

32. The light-emitting device as claimed in claim 31, further comprising a substrate-side contact metal layer interposed between the diffusion-blocking layer and the device substrate, intended for reducing contact resistance between the device substrate and the diffusion-blocking layer.

33. The light-emitting device as claimed in claim 31, wherein the main metal layer is composed of an Au-base layer having Au as a major component, at least in a portion including the interface with the diffusion-blocking layer, and the device substrate is a Si substrate.

34. The light-emitting device as claimed in claim 33, wherein the diffusion-blocking layer is a metal layer for blocking diffusion, having either Ti or Ni as a major component.

35. The light-emitting device as claimed in claim 34, wherein the metal layer for blocking diffusion has a thickness of 1 nm to 10 μm, both ends inclusive.

36. The light-emitting device as claimed in claim 33, wherein the device substrate is an n-type Si substrate, and further comprises a substrate-side contact metal layer interposed between the diffusion-blocking layer and the Si substrate, being composed of an AuSb alloy or an AuSn alloy, and being intended for reducing contact resistance between the Si substrate and the diffusion-blocking layer.

37. The light-emitting device as claimed in claim 33, wherein the Au-base layer composes the reflective layer.

38. The light-emitting device as claimed in claim 33, wherein the Ag-base layer interposed between the Au-base layer and the compound semiconductor layer, and having Ag as a major component, composes the reflective layer.

39. A method of fabricating a light-emitting device, the device comprising:
a compound semiconductor layer having a light-emitting layer portion, being configured so that a first main surface of which serves as a light extraction surface; and
a device substrate bonded on a second main surface side of the compound semiconductor layer while placing a main metal layer in between, the main metal layer having a reflective surface for reflecting light from the light-emitting layer portion back towards the light extraction surface side;
the method comprising the steps of:
forming a diffusion-blocking layer on the main surface of the device substrate on the side the compound semiconductor layer is to be bonded, being composed of a conductive material and planned for blocking diffusion of any device-substrate-derived components towards the main metal layer;
forming the main metal layer on at least either one of the second main surface of the compound semiconductor layer, and the main surface of the diffusion-blocking layer formed on the device substrate; and
bonding the device substrate and the compound semiconductor layer while placing the diffusion-blocking layer and the main metal layer in between.

40. The method of fabricating a light-emitting device as claimed in claim 39, wherein the device substrate and the compound semiconductor layer are bonded by stacking the device substrate and the compound semiconductor layer while placing the diffusion-blocking layer and the main metal layer in between, and then annealing the stack.

41. The method of fabricating a light-emitting device as claimed in claim 39, further comprising a step of forming a substrate-side contact metal layer on the main surface of the device substrate, intended for reducing contact resistance between the device substrate and the diffusion-blocking layer, and the diffusion-blocking layer is formed on the substrate-side contact metal layer.

42. The method of fabricating a light-emitting device as claimed in claim 39, wherein the main metal layer is composed of an Au-base layer having Au as a major component, at least in a portion including the interface with the diffusion-blocking layer, and the device substrate is a Si substrate.

43. The method of fabricating a light-emitting device as claimed in claim 42, wherein the diffusion-blocking layer is a metal layer for blocking diffusion, having either Ti or Ni as a major component.

44. The method of fabricating a light-emitting device as claimed in claim 43, wherein the metal layer for blocking diffusion has a thickness of 1 nm to 10 μm, both ends inclusive.

45. The method of fabricating a light-emitting device as claimed in claim 42, wherein the device substrate is an n-type Si substrate, and further comprises a substrate-side contact metal layer interposed between the diffusion-blocking layer and the Si substrate, being composed of an AuSb alloy or an AuSn alloy, and being intended for reducing contact resistance between the Si substrate and the diffusion-blocking layer.

46. The method of fabricating a light-emitting device as claimed in claim 39, further comprising the steps of:
disposing a first Au-base layer planned for becoming the main metal layer and having Au as a major component, on the bonding-side main surface of the compound semiconductor layer, the bonding-side main surface being defined as the main surface opposite to that planned for becoming the light extraction surface;
disposing a second Au-base layer planned for becoming the main metal layer and having Au as a major component, on a bonding-side main surface of the device substrate, the bonding-side main surface being defined as the main surface planned to be disposed on the light-emitting-layer-portion side; and
bonding the first Au-base layer and the second Au-base layer under close contact.

47. The method of fabricating a light-emitting device as claimed in claim 46, wherein the device substrate is a Si substrate.

48. The method of fabricating a light-emitting device as claimed in claim 46, wherein the reflective surface is composed of the first Au-base layer.

49. A light-emitting device comprising:
a compound semiconductor layer having a light-emitting layer portion, being configured so that one main surface of which serves as a light extraction surface;
a device substrate bonded on the other main surface side of the light-emitting layer portion;
and a reflective metal layer interposed between the device substrate and the light-emitting layer portion, having any one of Ag, Ru, Rh, Re, Os, Ir and Pt as a major component, and being intended for reflecting the light from the light-emitting layer portion back towards the light extraction surface side.

50. The light-emitting device as claimed in claim 49, wherein the light-emitting layer portion has a peak emission wavelength of 670 nm or shorter.

51. The light-emitting device as claimed in claim 49, wherein the reflective metal layer is an Ag-base reflective metal layer having Ag as a major component.

52. The light-emitting device as claimed in claim 51, wherein the light-emitting layer portion has a peak emission wavelength within a range from 350 nm to 670 nm, both ends inclusive.

53. The light-emitting device as claimed in claim 52, wherein the light-emitting layer portion has a peak emission wavelength within a range from 450 nm to 580 nm, both ends inclusive.

54. The light-emitting device as claimed in claim 53, wherein the light-emitting layer portion is configured as having a double heterostructure in which a first-conductivity-type cladding layer, an active layer and a second-conductivity-type cladding layer, all of these layers being composed of (AlₓGa₁₋ₓ)_{y}In_{1-y}P (where, 0≦x≦1 and 0≦y≦1) or InₓGa_{y}Al_{1-x-y}N (where, 0≦x≦1, 0≦y≦1 and x+y≦1), are stacked in this order.

55. The light-emitting device as claimed in claim 51, wherein the Ag-base reflective metal layer is bonded to the light-emitting layer portion while placing an AuGeNi contact layer in between.

56. The light-emitting device as claimed in claim 55, wherein the AuGeNi contact layer is formed on the main surface of the Ag-base reflective metal layer in a discrete manner.

57. The light-emitting device as claimed in claim 56, wherein the AuGeNi contact layer is formed in a ratio of formation area of 1% to 25%, both ends inclusive, with respect to the Ag-base reflective metal layer.

58. The light-emitting device as claimed in claim 51, wherein the Ag-base reflective metal layer is bonded to the light-emitting layer portion while placing an Ag-base contact layer having Ag as a major component in between.

59. The light-emitting device as claimed in claim 58, wherein the Ag-base contact layer is formed on the main surface of the Ag-base reflective metal layer in a discrete manner.

60. The light-emitting device as claimed in claim 59, wherein the Ag-base contact layer is formed in a ratio of formation area of 1% to 25%, both ends inclusive, with respect to the Ag-base reflective metal layer.

61. The light-emitting device as claimed in claim 58, wherein the Ag-base reflective metal layer has a ratio of Ag content which is set higher than that of the Ag-base contact layer.

62. The light-emitting device as claimed in claim 55, wherein the Ag-base contact layer is composed of an AgGeNi alloy having Ag as a major component and including also Ni and Ge.

63. The light-emitting device as claimed in claim 51, wherein the Ag-base reflective metal layer is bonded to the light-emitting layer portion while placing a protective metal layer in contact with the Ag-base reflective metal layer in between.

64. The light-emitting device as claimed in claim 63, wherein the protective metal layer is an Au-base metal layer having Au as a major component.

65. The light-emitting device as claimed in claim 63, wherein the protective metal layer has a thickness of 0.5 nm to 15 nm, both ends inclusive.

66. The light-emitting device as claimed in claim 49, wherein the reflective metal layer is bonded to the device substrate while placing a binding-use metal layer in between.

67. The light-emitting device as claimed in claim 66, wherein the binding-use metal layer is an Au-base metal layer having Au as a major component.

68. The light-emitting device as claimed in claim 67, wherein the reflective metal layer is bound to the device substrate while placing the binding-use metal layer which is composed of a first Au-base layer and a second Au-base layer disposed in contact with each other in this order as viewed from the reflective metal layer side.

69. A method of fabricating the light-emitting device as claimed in claim 68, comprising the steps of:
forming the reflective metal layer on a bonding-side main surface of the compound semiconductor layer, the bonding-side main surface being defined as the main surface opposite to that planned for becoming the light extraction surface;
disposing a first Au-base layer having Au as a major component and being a precursor for the binding-use metal layer;
disposing a second Au-base layer, having Au as a major component, on the bonding-side main surface of the device substrate, the bonding-side main surface being defined as the main surface which is planned to be disposed on the light-emitting-layer-portion side; and
bonding the first Au-base layer and the second Au-base layer under a close contact.

70. A method of fabricating a light-emitting device, the device comprising:
a compound semiconductor layer having a light-emitting layer portion, being configured so that one main surface of which serves as a light extraction surface; and
a device substrate bonded on the other main surface side of the compound semiconductor layer while placing a metal layer in between, the metal layer having a reflective surface for reflecting light from the light-emitting layer portion back towards the light extraction surface side, and the metal layer being composed of an Au-base layer having Au as a major component at least in a portion thereof including the reflective surface;
the method comprising the steps of:
disposing a first Au-base layer on a bonding-side main surface of the compound semiconductor layer, the bonding-side main surface being defined as the main surface opposite to that planned for becoming the light extraction surface;
disposing a second Au-base layer on the bonding-side main surface of the device substrate, the bonding-side main surface being defined as the main surface which is planned to be disposed on the light-emitting-layer-portion side; and
bonding the first Au-base metal layer and the second Au-base metal layer under a close contact.

71. The method of fabricating a light-emitting device as claimed in claim 70, wherein the light-emitting layer portion is configured to emit light having a peak emission wavelength of 550 nm or longer.

72. The method of fabricating a light-emitting device as claimed in claim 70, wherein:
the light-emitting layer portion is first formed by epitaxial growth on a light-emitting-layer-growing substrate composed of a compound semiconductor;
the first Au-base layer is formed on the bonding-side main surface of the light-emitting layer portion in a state of being united with the light-emitting-layer-growing substrate;
the second Au-base layer is formed on the bonding-side main surface of the device substrate;
the first Au-base layer and the second Au-base layer are bonded under a close contact; and
after the bonding, the light-emitting-layer-growing substrate is separated from the light-emitting layer portion by chemical etching.

73. The method of fabricating a light-emitting device as claimed in claim 72, wherein the light-emitting layer portion is composed of (AlₓGa₁₋ₓ)_{y}In_{1-y}P (where, 0≦x≦1 and 0≦y≦1), the light-emitting-layer-growing substrate is composed of a GaAs substrate, and
the chemical etching is carried out using an ammonia/hydrogen peroxide mixed solution so as to dissolve the GaAs substrate.

74. The method of fabricating a light-emitting device as claimed in claim 72, wherein the light-emitting layer portion composed of (AlₓGa₁₋ₓ)_{y}In_{1-y}P (where, 0≦x≦1 and 0≦y≦1) is formed on a GaAs substrate which serves as the light-emitting-layer-growing substrate while placing an AlAs releasing layer in between, and the chemical etching is carried out using a hydrofluoric acid-containing solution so as to dissolve the AlAs releasing layer.

75. The method of fabricating a light-emitting device as claimed in claim 70, wherein:
the light-emitting layer portion is composed of a Group III-V compound semiconductor;
both of the first Au-base layer and the second Au-base layer are composed of an Au-base metal having a ratio of Au content of 95% by mass or above, and
the first Au-base layer and the second Au-base layer are bonded by subjecting them under a close contact to annealing for bonding at a temperature higher than 180° C. and not higher than 360° C.

76. The method of fabricating a light-emitting device as claimed in claim 75, wherein the annealing for bonding is carried out at a temperature lower than 300° C.

77. The method of fabricating a light-emitting device as claimed in claim 75, wherein the Group III element in the compound semiconductor layer is composed of at least any one selected from Al, Ga and In, and the Group V element in the same layer is composed of at least either one of P and As.

78. The method of fabricating a light-emitting device as claimed in claim 70, wherein the device substrate is configured by using a Si substrate.

79. The method of fabricating a light-emitting device as claimed in claim 70, further comprising a step of forming a substrate-side contact layer on the bonding-side main surface of the device substrate composed of a Si substrate, the second Au-based layer is formed so as to cover the substrate-side contact layer, and further comprising a step of annealing the substrate-side contact layer and the Si substrate for alloying.

80. The method of fabricating a light-emitting device as claimed in claim 70, further comprising a step of forming a light-emitting-layer-portion-side contact layer having Au as a major component, in a discrete manner on the main surface of the first Au-base layer, between the first Au-base layer and the compound semiconductor layer.

81. A light-emitting device comprising:
a compound semiconductor layer having a light-emitting layer portion, being configured so that a first main surface of which serves as a light extraction surface;
a Si substrate bonded on a second main surface side of the compound semiconductor layer while placing a metal layer in between;
wherein the bonding surface of the metal layer with the compound semiconductor layer forms a reflective layer, and the metal layer has a Si-diffusion-blocking layer having Au or Ag as a major component and also containing a Si-diffusion-blocking component which comprises a single, or two or more elements selected from Sn, Pb, In and Ga, and being planned for inhibiting Si diffused from the Si substrate from depositing on the reflective surface.

82. The light-emitting device as claimed in claim 81, wherein the Si-diffusion-blocking layer has a content of the Si-diffusion-blocking component of 1% by mass to 20% by mass, both ends inclusive.

83. The light-emitting device as claimed in claim 81, further comprising a substrate-side contact alloyed layer interposed between the Si-diffusion-blocking layer and the Si substrate, and being intended for reducing contact resistance between the Si substrate and the Si-diffusion-blocking layer.

84. The light-emitting device as claimed in claim 81, wherein the metal layer has a main metal layer between the compound semiconductor layer and the Si-diffusion-blocking layer, the main metal layer having a content of the Si-diffusion-blocking component smaller than that of the Si-diffusion-blocking layer.

85. The light-emitting device as claimed in claim 84, wherein the Si-diffusion blocking layer has a thickness of 50 nm or above and 5 μm or less.

86. The light-emitting device as claimed in claim 84, wherein the Si-diffusion-blocking layer has Au as a major component; and
the main metal layer comprises an Au-base main metal layer which forms the reflective surface and has Au as a major component.

87. The light-emitting device as claimed in claim 84, wherein
the Si-diffusion-blocking layer has Au as a major component; and
the main metal layer is composed of an Au-base coupling layer having Au as a major component, in a portion thereof in contact with the Si-diffusion-blocking layer, and is composed of an Ag-base reflective layer having Ag as a major component or an Al-base reflective layer having Al as a major component, in a portion thereof composing the reflective surface.

88. The light-emitting device as claimed in claim 81, wherein the reflective surface is configured by the Si-diffusion-blocking layer.

89. A method of fabricating the light emitting device, the device comprising:
a compound semiconductor layer having a light-emitting layer portion, being configured so that a first main surface of which serves as a light extraction surface; and
a Si substrate bonded on a second main surface side of the compound semiconductor layer while placing a metal layer in between, wherein the bonding surface between the metal layer and the compound semiconductor layer configures a reflective layer;
the method comprising the steps of:
forming the metal layer as having a Si-diffusion-blocking layer which has Au or Ag as a major component and also contains a Si-diffusion-blocking component which comprises a single, or two or more elements selected from Sn, Pb, In and Ga, and being planned for inhibiting Si diffused from the Si substrate from depositing on the reflective surface; and
bonding the Si substrate and the compound semiconductor layer while placing the metal layer in between.

90. The method of fabricating the light emitting device as claimed in claim 89, wherein the Si substrate and the compound semiconductor layer are bonded by stacking the Si substrate and the compound semiconductor layer while placing the metal layer in between, and then annealing the stack.
